(19) United States
(12) Patent Application Publication
(10) Pub. No.: US 2022/0400553 A1
(43) Pub. Date: Dec. 15, 2022

(54) MANUFACTURING METHOD FOR SUBSTRATE HAVING CONDUCTIVE PATTERN, MANUFACTURING METHOD FOR ELECTRONIC DEVICE, SUBSTRATE HAVING CONDUCTIVE PATTERN, AND PROTECTIVE FILM FOR METAL NANOBODY

(71) Applicant: FUJIFILM Corporation, Tokyo (JP)

(72) Inventors: Akio KATAYAMA, Shizuoka (JP); Morimasa SATO, Shizuoka (JP)

(73) Assignee: FUJIFILM Corporation, Tokyo (JP)

(21) Appl. No.: 17/751,817

(22) Filed: May 24, 2022

(30) Foreign Application Priority Data
May 31, 2021 (JP) 2021-091063
Mar. 14, 2022 (JP) 2022-039586

(51) Int. Cl. H05K 3/06; G03F 7/40; G03F 7/20

(52) U.S. Cl. CPC H05K 3/06; G03F 7/40; G03F 7/70666

(57) ABSTRACT

There are provided a manufacturing method for a substrate having a conductive pattern, a manufacturing method for an electronic device, and a substrate having a conductive pattern, which are excellent in the dimensional stability of the conductive pattern after applying an electric current, as well as a protective film for a metal nanobody.

Provided are the manufacturing method for a substrate having a conductive pattern, comprising a step 1a of forming a conductive layer a containing a metal nanobody and a resin 1 on a substrate; a step 1b of forming a resin layer b containing a resin 2 on the conductive layer a; a step 2a of forming a photosensitive resin layer c on the resin layer b; a step 3 of obtaining a resin pattern c′ of the photosensitive resin layer by exposure and development treatment on the photosensitive resin layer c; a step 4 of removing the metal nanobody in the conductive layer a by etching to form a conductive pattern d; and a step 5a of softening or swelling at least one of the resin 1 or the resin 2, the manufacturing method for an electronic device, the substrate having a conductive pattern, and the protective film for a metal nanobody.

### CROSS-REFERENCE TO RELATED APPLICATIONS

This application is a Continuation of Japanese Patent Application No. 2021-091063 filed on May 31, 2021 and Japanese Patent Application No. 2022-039586 filed on Mar. 14, 2022. The entire contents of these applications are incorporated herein by reference.

### BACKGROUND OF THE INVENTION

### 1. Field of the Invention

The present disclosure relates to a manufacturing method for a substrate having a conductive pattern, a manufacturing method for an electronic device, a substrate having a conductive pattern, and a protective film for a metal nanobody.

### 2. Description of the Related Art

In a display device (an organic electroluminescence (EL) display device, a liquid crystal display device, or the like) that includes a touch panel such as a capacitive input device, an electrode pattern corresponding to a sensor of a visual recognition part and a conductive pattern of a wire or the like of a peripheral wiring portion or a lead-out wiring portion are provided inside the touch panel.

Generally, in the formation of a patterned layer, a method in which a layer of a photosensitive resin composition provided on any substrate by using a photosensitive transfer material is exposed through a mask having a desired pattern and then developed has been widely used since the number of steps required for obtaining a necessary pattern shape is small.

Further, in the related art, the conductive patterns obtained by printing has been widely used in various fields, as various sensors such as a pressure sensor and a biosensor, a printed circuit board, a solar cell, a condenser, an electromagnetic wave shield, a touch panel, an antenna.

Further, as a method of forming a conductive pattern in the related art, the one disclosed in WO2016/051695A or TW2016-29992A is known.

WO2016/051695A discloses a film attached with a transparent conductive film, including a film-shaped transparent base material having a first surface and a second surface on a side opposite to the first surface, a metal nanowire, and a transparent binder containing a water-repellent additive, where a transparent conductive film formed on at least one of the first surface or the second surface of the transparent base material is provided, a part of the metal nanowire is exposed on the surface of the transparent conductive film, and a contact angle on the surface of the transparent conductive film is 80 degrees or more and 125 degrees or less.

Furthermore, TW2016-29992A discloses a method of etching a metal nanowire layer to form a conductive pattern.

### SUMMARY OF THE INVENTION

An object to be achieved by one embodiment of the present invention is to provide a manufacturing method for a substrate having a conductive pattern, which is excellent in the dimensional stability of the conductive pattern after applying an electric current.

In addition, an object to be achieved by another embodiment of the present invention is to provide a manufacturing method for an electronic device that includes a substrate having a conductive pattern, the substrate being obtained by the manufacturing method for a substrate having a conductive pattern.

Further, an object to be achieved by still another embodiment of the present invention is to provide a substrate having a conductive pattern or a protective film for a metal nanobody, which is excellent in the dimensional stability of the conductive pattern after applying an electric current.

The means for achieving the above objects include the following aspects.

<1> A manufacturing method for a substrate having a conductive pattern, comprising a step 1a of forming a conductive layer a containing a metal nanobody and a resin 1 on a substrate; a step 1b of forming a resin layer b containing a resin 2 on the conductive layer a; a step 2a of forming a photosensitive resin layer c on the resin layer b; a step 3 of obtaining a resin pattern c′ of the photosensitive resin layer by exposure and development treatment on the photosensitive resin layer c; a step 4 of removing the metal nanobody in the conductive layer a by etching to form a conductive pattern d; and a step 5a of softening or swelling at least one of the resin 1 or the resin 2.

<2> A manufacturing method for a substrate having a conductive pattern, comprising a step 1a of forming a conductive layer a containing a metal nanobody and a resin 1 on a substrate; a step 2b of forming a photosensitive resin layer c on the conductive layer a; a step 3 of obtaining a resin pattern c′ of the photosensitive resin layer by exposure and development treatment on the photosensitive resin layer c; a step 4 of removing the metal nanobody in the conductive layer a by etching to form a conductive pattern d; and a step 5b of softening or swelling the resin 1.

<3> The manufacturing method for a substrate having a conductive pattern according to <1> or <2>, in which at least one surface of the obtained substrate having a conductive pattern has a first compartment in which the conductive pattern d is formed and a second compartment in which the conductive pattern d is not formed, and in a case where the second compartment is observed in a thickness direction of the substrate with a scanning electron microscope, an area where voids are observed is 10% or less with respect to a total area of the second compartment.

<4> The manufacturing method for a substrate having a conductive pattern according to <3>, in which in a case where the second compartment is observed in the thickness direction of the substrate with the scanning electron microscope, the area where voids are observed is 8% or less with respect to the total area of the second compartment.

<5> The manufacturing method for a substrate having a conductive pattern according to <4>, in which in a case where the second compartment is observed in the thickness direction of the substrate with the scanning electron microscope, the area where voids are observed is 5% or less with respect to the total area of the second compartment.

<6> The manufacturing method for a substrate having a conductive pattern according to any one of <1> to <5>, in which the conductive layer a has a light transmittance of 70% or more with respect to light having a wavelength of 380 nm to 780 nm.

<7> The manufacturing method for a substrate having a conductive pattern according to any one of <1> to <6>, in which the metal nanobody is a metal nanowire.

<8> The manufacturing method for a substrate having a conductive pattern according to any one of <1> to <7>, in which the metal nanobody is a nanoparticle having an aspect ratio of 1:1 to 1:10 and a sphere equivalent diameter of 1 nm to 200 nm.

<9> The manufacturing method for a substrate having a conductive pattern according to any one of <1> to <8>, in which the metal nanobody is a silver nanobody or a silver compound nanobody.

<10> The manufacturing method for a substrate having a conductive pattern according to any one of <1> to <9>, in which a conductive pattern d′ is further formed on a surface of the substrate opposite to a surface on which the conductive layer a is provided.

<11> The manufacturing method for a substrate having a conductive pattern according to <1>, in which the resin layer b has a compound e that can be bonded or coordinated to a metal contained in the metal nanobody.

<12> The manufacturing method for a substrate having a conductive pattern according to <11>, in which the compound e is a compound having an unshared electron pair.

<13> The manufacturing method for a substrate having a conductive pattern according to <12>, in which the compound e is at least one compound selected from the group consisting of a nitrogen-containing compound having an unshared electron pair and a sulfur-containing compound having an unshared electron pair.

<14> The manufacturing method for a substrate having a conductive pattern according to any one of <1> to <13>, in which the photosensitive resin layer c contains an alkali-soluble resin, a polymerizable compound, and a photopolymerization initiator.

<15> The manufacturing method for a substrate having a conductive pattern according to any one of <1> to <13>, in which the photosensitive resin layer c contains a resin of which polarity changes under action of an acid, and a photoacid generator.

<16> The manufacturing method for a substrate having a conductive pattern according to any one of <1> to <13>, in which the photosensitive resin layer c contains a resin having a constitutional unit having a phenolic hydroxyl group, and a quinone diazide compound.

<17> The manufacturing method for a substrate having a conductive pattern according to any one of <1> to <16>, in which the photosensitive resin layer c is formed from a photosensitive transfer material.

<18> The manufacturing method for a substrate having a conductive pattern according to any one of <1> to <17>, in which an interlayer is further provided on the photosensitive resin layer c.

<19> The manufacturing method for a substrate having a conductive pattern according to <1>, in which the step 5a is a step of softening at least one of the resin 1 or the resin 2 by a heating treatment and filling, by the etching, voids generated by removing the metal nanobody.

<20> The manufacturing method for a substrate having a conductive pattern according to <19>, in which the heating treatment in the step 5a is carried out at a heating temperature that satisfies Tgp<Th<Tgb, where Th indicates a maximum temperature (° C.) during the heating treatment in the step 5a, Tgp indicates a lower glass transition temperature (° C.) between a glass transition temperature of the resin 1 and a glass transition temperature of the resin 2, and Tgb indicates a glass transition temperature (° C.) of the substrate.

<21> The manufacturing method for a substrate having a conductive pattern according to <2>, in which the step 5b is a step of softening the resin 1 by a heating treatment and filling, by the etching, voids generated by removing the metal nanobody.

<22> The manufacturing method for a substrate having a conductive pattern according to <1>, in which the step 5a is a step of swelling at least one of the resin 1 or the resin 2 and filling, by the etching, voids generated by removing the metal nanobody, during the step 4 or after the step 4.

<23> The manufacturing method for a substrate having a conductive pattern according to <2>, in which the step 5b is a step of swelling the resin 1 and filling, by the etching, voids generated by removing the metal nanobody, during the step 4 or after the step 4.

<24> A manufacturing method for an electronic device, in which the electronic device includes a substrate having a conductive pattern, the substrate being obtained by the manufacturing method for a substrate having a conductive pattern according to any one of <1> to <23>.

<25> A substrate having a conductive pattern, comprising a substrate and a first compartment in which a conductive pattern d containing a metal nanobody and a resin 1 is formed and a second compartment in which the conductive pattern d is not formed, on at least one surface of the substrate, in which in a case where the second compartment is observed in a thickness direction of the substrate with a scanning electron microscope, an area where voids are observed is 10% or less with respect to a total area of the second compartment.

<26> The substrate having a conductive pattern according to <25>, in which the resin 1 is present in the second compartment.

<27> The substrate having a conductive pattern according to <26>, in which in a case where a layer thickness of the first compartment from a surface of the substrate is denoted by H1 and a layer thickness of the second compartment from the surface of the substrate is denoted by H2, 0.90<H1/H2<1.11 is satisfied.

<28> The substrate having a conductive pattern according to <26> or <27>, in which the number of recessed parts having a depth of 10 nm or more and present in the second compartment is 10 pieces/100 μm² or less.

<29> A protective film for a metal nanobody, comprising a resin layer that contains a resin having a glass transition temperature of 150° C. or lower.

<30> The protective film for a metal nanobody according to <29>, in which the resin having a glass transition temperature of 150° C. or lower contains at least one resin selected from the group consisting of an acrylic resin, a polyester resin, a polyvinyl acetal resin, and a phenol resin.

<31> The protective film for a metal nanobody according to <29> or <30>, in which the resin layer further contains at least one polymerization initiator selected from the group consisting of an oxime ester-based photopolymerization initiator, a biimidazole-based photopolymerization initiator, an alkyl phenone-based photopolymerization initiator, an acetophenone-based photopolymerization initiator, and an acylphosphine oxide-based photopolymerization initiator.

<32> The protective film for a metal nanobody according to any one of <29> to <31>, in which the resin layer further contains a bifunctional or higher functional polymerizable compound.

According to one embodiment of the present invention, it is possible to provide a manufacturing method for a substrate having a conductive pattern, which is excellent in the dimensional stability of the conductive pattern after applying an electric current.

According to another embodiment of the present invention, it is possible to provide a manufacturing method for an electronic device having a substrate having a conductive pattern obtained by the manufacturing method for a substrate having a conductive pattern.

According to still another embodiment of the present invention, it is possible to provide a substrate having a conductive pattern or a protective film for a metal nanobody, which is excellent in the dimensional stability of the conductive pattern after applying an electric current.

### BRIEF DESCRIPTION OF THE DRAWINGS

FIG. 1 is a schematic view illustrating one example of a configuration of a photosensitive transfer material.

FIG. 2 is a schematic plan view illustrating a pattern A.

FIG. 3 is a schematic plan view illustrating a pattern B.

### DESCRIPTION OF THE PREFERRED EMBODIMENTS

The details of the present disclosure will be described below. It is noted that although the description will be made with reference numeral to the accompanying drawings, the references may be omitted.

In addition, in the present specification, the numerical value range indicated by using “to” means a range including the numerical values before and after “to” as the lower limit value and the upper limit value, respectively.

In addition, in the present specification, “(meth)acryl” indicates either or both of acryl and methacryl, “(meth)acrylate” indicates either or both of acrylate and methacrylate, and “(meth)acryloyl” indicates either or both of acryloyl and methacryloyl.

In addition, in the present specification, in a case where there are a plurality of substances corresponding to each component in the composition, the amount of each component in the composition means the total amount of the plurality of corresponding substances present in the composition unless otherwise specified.

In the present specification, the term “step” includes not only an independent step but also a step that cannot be clearly distinguished from the other steps, as long as the intended purpose of the step is achieved.

In addition, in describing a group (atomic group) in the present specification, the description which does not indicate substituted or unsubstituted includes not only a group having no substituent but also a group having a substituent. For example, the “alkyl group” includes not only an alkyl group having no substituent (an unsubstituted alkyl group) but also an alkyl group having a substituent (a substituted alkyl group).

In the present specification, the “exposure” includes not only exposure using light but also drawing with particle beams such as electron beams and ion beams, unless otherwise specified. In addition, examples of the light that is used for exposure generally include a bright line spectrum of a mercury lamp, a far ultraviolet ray represented by an excimer laser, and an actinic ray (an active energy ray) such as an extreme ultraviolet ray (EUV light), an X-ray, or an electron beam.

In addition, the chemical structural formula in the present specification may be described by a simplified structural formula in which a hydrogen atom is omitted.

In the present disclosure, “% by mass” is synonymous with “% by weight”, and “parts by mass” is synonymous with “parts by weight”.

In addition, in the present disclosure, a combination of two or more preferred aspects is a more preferred aspect.

In the present specification, “transparent” means that the average light transmittance of visible light having a wavelength of 400 nm to 700 nm is 80% or more, which is preferably 90% or more.

In the present specification, the average light transmittance of visible light is a value measured by using a spectrophotometer, and it can be measured by, for example, a spectrophotometer U-3310 manufactured by Hitachi, Ltd.

Unless otherwise specified, the weight-average molecular weight (Mw) and the number-average molecular weight (Mn) in the present disclosure are molecular weights converted using polystyrene as a standard substance, which are obtained by measuring with a gel permeation chromatography (GPC) analytical apparatus using TSKgel GMHxL, TSKgel G4000HxL, and TSKgel G2000HxL (product names, all manufactured by TOSOH CORPORATION) as columns, tetrahydrofuran (THF) as a solvent, and a differential refractometer as a detector.

In the present specification, the “total solid content” refers to a total mass of components excluding the solvent from the total composition content of the composition. In addition, the “solid content” refers to a component excluding the solvent as described above, and it may be, for example, a solid or a liquid at 25° C.

Manufacturing Method for Substrate Having Conductive Pattern

The first embodiment of a manufacturing method for a substrate having a conductive pattern according to the present disclosure includes a step 1a of forming a conductive layer a containing a metal nanobody and a resin 1 on a substrate; a step 1b of forming a resin layer b containing a resin 2 on the conductive layer a; a step 2a of forming a photosensitive resin layer c on the resin layer b; a step 3 of obtaining a resin pattern c′ of the photosensitive resin layer by exposure and development treatment on the photosensitive resin layer c; a step 4 of removing the metal nanobody in the conductive layer a by etching to form a conductive pattern d; and a step 5a of softening or swelling at least one of the resin 1 or the resin 2.

The second embodiment of the manufacturing method for a substrate having a conductive pattern according to the present disclosure includes a step 1a of forming a conductive layer a containing a metal nanobody and a resin 1 on a substrate; a step 2b of forming a photosensitive resin layer c on the conductive layer a; a step 3 of obtaining a resin pattern c′ of the photosensitive resin layer by exposure and development treatment on the photosensitive resin layer c; a step 4 of removing the metal nanobody in the conductive layer a by etching to form a conductive pattern d; and a step 5b of softening or swelling the resin 1.

It is noted that in the present specification, in a case where “manufacturing method for a substrate having a conductive pattern according to the present disclosure” is simply mentioned, this shall refer to all of the above-described first embodiment and the above-described second embodiment unless otherwise specified. Furthermore, in a case where the “step 1a” or the like is simply mentioned, this shall refer to the step 1a or the like of both the first embodiment and the second embodiment unless otherwise specified.

A transparent wire formed from a metal oxide (an indium tin oxide (ITO), an indium zinc oxide (IZO), or the like), which has been used in the related art in the visual recognition part of the touch panel substrate, is inferior in flexibility, and thus it has a problem, for example, in a case of being applied to a wiring board for a foldable touch panel device. Further, from the viewpoint of low power consumption, it is desired to replace these metal oxide wires.

As one means for solving such a problem of flexibility, a technique for forming a wire by using, as a conductive layer, a metal nanobody, particularly a structure body in which metal nanowires are dispersed in a resin has been developed in recent years. In such a structure body, metal nanobodies dispersed in the resin have a large number of mutual contact points to exhibit conductivity, and thus it is unlikely that the metal nanobodies themselves are broken and that the entire large number of mutual contact points of metal nanobodies are broken at the same time in a case where the structure body is deformed. As a result, the resistance change is extremely small. In particular, in a case where a metal nanowire is used as the metal nanobody, an extremely low resistance value and deformation resistance can be obtained, and it has properties suitable as the wiring material.

However, in a case where a conductive pattern is formed by a conductive layer in the related art containing metal nanobodies and a resin, only the metal nanobodies are dissolved at the time of etching due to the fact that the metal nanobodies are in a state of being dispersed in a resin or the like, and the resin portion often remains as it is. This is because the resin that is used for dispersing metal nanobodies is often hydrophobic from the viewpoints of the dispersion stability, the prevention of oxidation of the metal nanobodies, and the like, thus it is incompatible with an aqueous solution that is used for etching.

In this case, in the etched portion, the dissolved portion of the metal nanobody remains as a void, and it becomes an insulated portion in which nanobodies are substantially not present.

The void in the present disclosure is a trace that remains after removing the metal nanobody. As a result, the depth of the recess of the void is, in many cases, larger than the depth of the recess present in the portion where the metal nanobody of the conductive layer a or resin layer b is not present.

Specifically, in a case where a maximum valley depth Rv1 of the portion where the metal nanobody of the conductive layer a or resin layer b is not present and a maximum valley depth Rv2 of the resin portion that remains after etching the conductive layer a are measured using an atomic force microscope (AFM), Rv2>Rv1 is satisfied in many cases. The void may include a void in a state where a part of the resin portion in terms of thickness which remains after etching the conductive layer a is recessed and a void in a state where it has penetrated to the base material. For example, in a case where the average thickness of the conductive layer a is 10 nm and Rv1 is 1 nm, the depth of the void is larger than 1 nm and 10 nm or less in many cases.

It is noted that since the void in the present disclosure is a trace that remains after removing the metal nanobody which has been present with being dispersed in the conductive layer, the recess generated by patterning the conductive layer itself (for example, in a case of forming through holes in the conductive layer) is not regarded as the void.

In addition, the void can take various forms depending on the shape of the metal nanobody. The void caused by a spherical nanoparticle has a circular shape, and the void caused by the rod-like or thread-like nanowire is has a groove shape.

In a case where electric current is applied to a substrate having a conductive pattern with such a void part remaining, a phenomenon in which the metal nanobody in the conductive pattern is oxidized due to water contamination in the void part, etching residue, and the like, and the ionized metal diffuses into the inside of the voids may occur. The diffused metal is reduced at another portion of the circuit and precipitated as a metal. The inventors of the present invention have found that this metal migration phenomenon causes problems such as a decrease in circuit width and metal precipitation, which result in a problem in the dimensional stability of the conductive pattern after applying an electric current.

The manufacturing method for a substrate having a conductive pattern according to the present disclosure is excellent in the dimensional stability of the conductive pattern after applying an electric current, even in a case where a conductive layer containing a metal nanobody and a resin is used, a resin pattern is formed on the conductive layer, and the conductive layer in a portion where the resin pattern is not formed is removed by etching.

Hereinafter, the manufacturing method for a substrate having a conductive pattern according to the present disclosure will be described in detail.

Void

In the manufacturing method for a substrate having a conductive pattern according to the present disclosure, it is preferable that at least one surface of the obtained substrate having a conductive pattern has a first compartment in which the conductive pattern d is formed and a second compartment in which the conductive pattern d is not formed. In a case where the second compartment is observed in a thickness direction of the substrate with a scanning electron microscope, the area where voids are observed is more preferably 10% or less with respect to the total area of the second compartment, the area where voids are observed is still more preferably 8% or less with respect to the total area of the second compartment, the area where voids are observed is particularly preferably κ% or less with respect to the total area of the second compartment, and the area where voids are observed is most preferably 0% or more and 3% or less with respect to the total area of the second compartment, from the viewpoint of the dimensional stability of the conductive pattern after applying an electric current.

The method of measuring the area where voids are observed in the second compartment of the substrate having a conductive pattern is as follows.

In the portion of the substrate having a conductive pattern, in which the conductive pattern is not present (the second compartment), voids that are present in a 100 μm square are observed with a scanning electron microscope in a direction perpendicular to the surface direction of the substrate. The void portion of the observed image is binarized and the ratio of the number of pixels to the visual field of observation is defined as the void ratio (the ratio of the area where voids are observed). Observations are carried out at three different locations on the sample, and the average value is taken as the void ratio of the sample.

Step 1a

The manufacturing method for a substrate having a conductive pattern according to the present disclosure includes a step 1a of forming a conductive layer a containing a metal nanobody and a resin 1 on a substrate.

As the material of the metal nanobody contained in the conductive layer a, it is possible to use copper, silver, zinc, iron, chromium, molybdenum, nickel, aluminum, gold, platinum, palladium, and an alloy of two or more thereof, as well as indium tin oxide (ITO), indium zinc oxide (IZO), conductive silica. However, from the viewpoints of resistance value, cost, sintering temperature, and the like, it is preferably copper, silver, nickel, aluminum, gold, platinum, palladium, or an alloy thereof, it is more preferably silver, copper, or an alloy thereof, and particularly from the viewpoint of sintering temperature and oxidation suppression, it is still more preferably silver or a silver alloy and particularly preferably silver. That is, the metal nanobody is particularly preferably a silver nanobody or a silver compound nanobody.

The shape of the metal nanobody is not particularly limited and may be any known shape; however, the metal nanobody is preferably a metal nanoparticle or a metal nanowire, and more preferably a metal nanowire.

Examples of the shape of the metal nanowire include a cylindrical shape, a rectangular parallelepiped shape, and a columnar shape having a polygonal cross section. The metal nanowire preferably has at least one shape of a cylindrical shape or a columnar shape having a polygonal cross section in use applications where high transparency is required.

The cross-sectional shape of the metal nanowire can be observed using, for example, a transmission electron microscope (TEM).

The diameter (so-called a minor axis length) of the metal nanowire is not particularly limited; however, it is, for example, preferably 50 nm or less, more preferably 35 nm or less, and still more preferably 20 nm or less, from the viewpoint of transparency.

From the viewpoint of oxidation resistance and durability, the lower limit of the diameter of the metal nanowire is preferably, for example, 5 nm or more.

The length (so-called a major axis length) of the metal nanowire is not particularly limited; however, it is, for example, preferably 5 μm or more, more preferably 10 μm or more, and still more preferably 30 μm or more, from the viewpoint of conductivity.

From the viewpoint of suppressing the formation of aggregates in the manufacturing process, the upper limit of the length of the metal nanowire is preferably, for example, 1 mm or less.

The diameter and length of the metal nanowire can be measured using, for example, a transmission electron microscope (TEM) or an optical microscope.

Specifically, the diameter and length of randomly selected 300 metal nanowires are measured from the metal nanowire magnified and observed using a transmission electron microscope (TEM) or an optical microscope. Values obtained by arithmetically averaging the measured values are defined as the diameter and length of the metal nanowire.

The metal nanoparticle may be a spherical particle, a flat plate particle, or an irregularly shaped particle.

The average primary particle diameter of the metal nanoparticles is preferably 0.1 nm to 500 nm, more preferably 1 nm to 200 nm, and particularly preferably 1 nm to 100 nm from the viewpoint of stability and fusion welding temperature.

The average primary particle diameter of the metal nanoparticles in the present disclosure can be obtained by taking a scanning electron microscope micrograph (an SEM image) of 100 particles with a scanning electron microscope (for example, S-3700N, manufactured by Hitachi High-Tech Corporation), measuring the particle diameters thereof using an image processing and measuring device (LUZEX AP; manufactured by NIRECO CORPORATION), and determining an arithmetic average value. That is, the particle diameter referred to in the present disclosure indicates a diameter in a case where a projected shape of a particle is circular, and it indicates a diameter of a circle having an area identical to that of a projected area of a particle in a case where the particle has an irregular shape other than the spherical shape.

From the viewpoint of conductivity, the metal nanoparticle preferably contains a metal nobler than silver, and in such a case, it is more preferable to contain a flat particle at least a part of which is coated with gold. Here, “a metal nobler than silver” means “a metal having a standard electrode potential higher than the standard electrode potential of silver”.

In the above metal nanoparticle, the rate of the metal nobler than silver with respect to silver is preferably 0.01% by atom to 5% by atom, more preferably 0.1% by atom to 2% by atom, and still more preferably 0.2% by atom to 0.5% by atom.

The content of the metal nobler than silver can be measured by, for example, high frequency inductively coupled plasma (ICP) emission spectroscopic analysis after dissolving a sample with an acid or the like.

Further, the metal nanobody is preferably a nanoparticle having an aspect ratio of 1:1 to 1:10 and a sphere equivalent diameter of 1 nm to 200 nm from the viewpoint of dispersibility and conductivity.

As the metal nanobody in the conductive layer a, only one kind may be used, or two or more kinds may be used in combination.

The content of the metal nanobody is preferably 1% by mass to 99% by mass, more preferably 1% by mass to 95% by mass, and still more preferably 1% by mass to 90% by mass with respect to the total mass of the conductive layer a, from the viewpoints of conductivity and dispersion stability.

The resin 1 that is contained in the conductive layer a is preferably a binder polymer from the viewpoint of durability.

Examples of the resin 1 include an acrylic resin [for example, poly(methyl methacrylate)], a polyester resin [for example, polyethylene terephthalate (PET)], a polycarbonate resin, a polyimide resin, a polyamide resin, a polyolefin (for example, polypropylene), a polynorbornene, a cellulose resin, polyvinyl alcohol (PVA), and polyvinylpyrrolidone.

Examples of the cellulose resin include hydroxypropylmethyl cellulose (HPMC), hydroxyethyl cellulose (HEC), methyl cellulose (MC), hydroxypropyl cellulose (HPC), carboxymethyl cellulose (CMC), and cellulose.

Further, the resin 1 may be a conductive polymer material.

Examples of the conductive polymer material include polyaniline and polythiophene.

Among them, the resin 1 is preferably at least one resin selected from the group consisting of a cellulose resin, polyvinyl alcohol, and polyvinylpyrrolidone, and more preferably a cellulose resin, from the viewpoints of the dispersibility of the metal nanobody and the dimensional stability of the conductive pattern after applying an electric current.

The glass transition temperature (Tg) of the resin 1 is preferably 180° C. or lower, more preferably 40° C. to 160° C., and particularly preferably 60° C. to 150° C., from the viewpoint of the dimensional stability of the conductive pattern after applying an electric current.

In the present disclosure, the glass transition temperature of a resin can be measured by differential scanning calorimetry (DSC).

Specifically, the glass transition temperature is measured according to the method described in JIS K 7121 (1987) or JIS K 6240 (2011). As the glass transition temperature in the present specification, an extrapolated glass transition initiation temperature (hereinafter, may be referred to as Tig) is used.

The method of measuring the glass transition temperature will be described in more detail.

In a case of determining the glass transition temperature, the device is kept at a temperature approximately 50° C. lower than the expected Tg of the resin until the device stabilizes. Then, the resin is heated at a heating rate of 20° C./min to a temperature approximately 30° C. higher than the temperature at which the glass transition ends, and a differential thermal analysis (DTA) curve or a DSC curve is plotted.

The extrapolated glass transition initiation temperature (Tig), that is, the glass transition temperature Tg in the present specification is determined as a temperature at an intersection point between a straight line that is obtained by extending the baseline of a low temperature side in the DTA curve or the DSC curve to a high temperature side and a tangent line that is drawn at a point where the slope of the curve of a portion in which the glass transition changes stepwisely is maximum.

As the resin 1 in the conductive layer a, only one kind may be used, or two or more kinds may be used in combination.

The content of the resin 1 is preferably 1% by mass to 90% by mass, more preferably 10% by mass to 80% by mass, and particularly preferably 20% by mass to 70% by mass with respect to the total mass of the conductive layer a, from the viewpoints of metal film forming properties at the time of sintering and conductivity.

The conductive layer a may further contain another additive.

Examples of the other additive include known an additive such as a surfactant.

Examples of the surfactant include RAPISOL A-90 (manufactured by NOF Corporation, concentration of solid contents: 1%) and NAROACTY CL-95 (manufactured by Sanyo Chemical Industries, Ltd., concentration of solid contents: 1%).

Further, the conductive layer a may contain inorganic particles.

Examples of the inorganic particle include silica, mullite, and alumina.

The conductive layer a preferably has high transparency, and the light transmittance with respect to light having a wavelength of 380 nm to 780 nm is preferably 60% or more, and more preferably 70% or more.

The thickness of the conductive layer a is not limited. The average thickness of the conductive layer a is preferably 0.001 μm to 1,000 μm, more preferably 0.005 μm to 15 μm, and particularly preferably 0.01 μm to 10 μm, from the viewpoints of conductivity and film-forming properties.

The average thickness of each layer and substrate in the present disclosure shall be an average value of thicknesses at 10 points, which are measured by observing a cross section perpendicular to the in-plane direction using a scanning electron microscope (SEM).

The method of forming the conductive layer a is not particularly limited; however, it is preferable to form the conductive layer a by applying a material obtained by dispersing a conductive material containing the metal nanobody in a liquid, that is, a conductive ink.

In addition, the method of applying the conductive ink is not particularly limited; however, examples thereof include an inkjet method, a spray method, a roll coating method, a bar coating method, a curtain coating method, and a die coating method (that is, a slit coating method).

The conductive ink that is used in the present disclosure may be a curable type, for example, a thermosetting type, a photocurable type, or a thermosetting and photocurable type.

The conductive ink contains a metal nanomaterial and a resin, and it may further contain at least any one of a solvent or the other additive.

As the solvent contained in the conductive ink, water or an organic solvent can be used.

The organic solvent is preferably hydrocarbons such as toluene, dodecane, tetradecane, cyclododecene, n-heptane, or n-undecane, or alcohols such as ethanol and isopropyl alcohol.

As necessary, the method of forming the conductive layer a may include, after coating, steps such as drying and sintering.

Further, it is preferable that the conductive layer a is formed in a shape larger than the shape of the desired conductive pattern.

As the substrate that is used in the manufacturing method for a substrate having a conductive pattern according to the present disclosure, a known substrate may be used, and as necessary, any layer other than the conductive layer may be provided.

Examples of the substrate include a resin substrate, a glass substrate, and a semiconductor substrate.

Examples of the preferred aspect of the substrate include, for example, those described in paragraph 0140 of WO2018/155193A, the content of which is incorporated in the present specification.

Examples of the base material that constitutes the substrate include glass, silicon, and a film.

The base material that constitutes the substrate is preferably transparent.

Examples of the transparent glass substrate include reinforced glass represented by Gorilla Glass manufactured by Corning Incorporated. Further, as the transparent glass substrate, the materials used in JP2010-86684A, JP2010-152809A, and JP2010-257492A can be used.

In a case where a film substrate is used as the substrate, it is preferable to use a film substrate having low optical distortion and/or high transparency. Examples of such a film substrate include polyethylene terephthalate (PET), polyethylene naphthalate, polycarbonate, triacetyl cellulose, polyimide, and a cycloolefin polymer.

The substrate is preferably a film substrate in a case of being manufactured by a roll-to-roll method. Further, in a case where a circuit wire for a touch panel is manufactured by a roll-to-roll method, it is preferable that the substrate is a sheet-shaped resin composition.

The substrate may have one conductive layer a alone or may have two or more conductive layers a. In a case of having two or more conductive layers a, it is preferable to have conductive layers made of different materials.

Further, the substrate may have the conductive layer a on only one surface or may have the conductive layer a on both surfaces.

Further, the substrate may be a substrate further having a lead wire. The above-described substrate can be suitably used as a substrate for a touch panel.

As the material of the lead wire, metal is preferable.

Examples of the metal which is the material of the lead wire include gold, silver, copper, molybdenum, aluminum, titanium, chromium, zinc, manganese, and an alloy consisting of two or more kinds of these metal elements. The material of the lead wire is preferably copper, molybdenum, aluminum, or titanium, and particularly preferably copper.

Step 1b

The first embodiment of the manufacturing method for a substrate having a conductive pattern according to the present disclosure includes a step 1b of forming a resin layer b (also referred to as a “protective layer”) containing the resin 2 on the conductive layer a.

Preferred examples of the resin 2 include an acrylic resin (for example, DIANAL series manufactured by Mitsubishi Chemical Corporation, or ACRYSET series manufactured by Nippon Shokubai Co., Ltd.), a polyester resin (for example, ELITEL series manufactured by UNITIKA Ltd., or Nichigo-POLYESTER series manufactured by Mitsubishi Chemical Corporation), a polyvinyl alcohol resin (for example, Poval series manufactured by Kuraray Co., Ltd.), a polyvinyl acetal resin (for example, S-LEC series manufactured by Sekisui Chemical Company, Limited), and a phenol resin (for example, PHENOLITE series manufactured by DIC Corporation).

Among them, the resin 2 preferably contains at least one resin selected from the group consisting of an acrylic resin, a polyester resin, a polyvinyl acetal resin, and a phenol resin, and it is more preferably contains at least one resin selected from the group consisting of a polymer having a constitutional unit derived from benzyl (meth)acrylate and a polyester resin, from the viewpoint of the dimensional stability of the conductive pattern after applying an electric current.

The glass transition temperature (Tg) of the resin 2 is preferably 150° C. or lower, more preferably 30° C. to 140° C., still more preferably 40° C. to 130° C., and particularly preferably 40° C. to 120° C., from the viewpoint of the dimensional stability of the conductive pattern after applying an electric current.

The acid value of the resin 2 is preferably 0 mgKOH/g to 60 mgKOH/g, preferably 0 mgKOH/g to 50 mgKOH/g, and particularly preferably 0 mgKOH/g to 40 mgKOH/g, from the viewpoints of the etching resistance and the dimensional stability of the conductive pattern after applying an electric current.

The acid value of the resin 2 can be measured by the measuring method described later.

As the resin 2 in the resin layer b, only one kind may be used, or two or more kinds may be used in combination.

The content of the resin 2 is preferably 40% by mass to 100% by mass, more preferably 50% by mass to 95% by mass, and particularly preferably 55% by mass to 90% by mass with respect to the total mass of the resin layer b, from the viewpoints of metal film forming properties at the time of sintering and conductivity.

The resin layer b may contain a polymerizable compound.

In a case where the resin layer b contains a polymerizable compound, the resin layer b preferably contains a polymerizable compound and a polymerization initiator.

The polymerizable compound is preferably an ethylenically unsaturated compound and more preferably a (meth)acrylate compound from the viewpoint of curing properties.

Further, the polymerizable compound preferably contains a bifunctional or higher functional polymerizable compound, more preferably contains a trifunctional to decafunctional polymerizable compound, and particularly preferably contains a tetrafunctional to octafunctional polymerizable compound, from the viewpoints of the curing properties and the hardness of the resin layer b.

Further, the polymerizable compound preferably contains a bifunctional or higher functional ethylenically unsaturated compound, and more preferably contains a bifunctional or higher functional (meth)acrylate compound, from the viewpoint of the curing properties and the hardness of the resin layer b.

Further, as the polymerizable compound, a polymerizable compound that is used for the photosensitive resin layer described later can also be suitably used.

As the polymerizable compound in the resin layer b, only one kind may be used, or two or more kinds may be used in combination.

The content of the polymerizable compound is preferably 5% by mass to 55% by mass, more preferably 10% by mass to 50% by mass, and particularly preferably 20% by mass to 45% by mass with respect to the total mass of the resin layer b, from the viewpoint of the hardness of the resin layer b.

The polymerization initiator is preferably a photopolymerization initiator.

The photopolymerization initiator is not particularly limited, and a known photopolymerization initiator can be used.

Examples of the photopolymerization initiator include a photopolymerization initiator having an oxime ester structure (hereinafter, also referred to as an “oxime-based photopolymerization initiator”), a photopolymerization initiator having an α-aminoalkyl phenone structure (hereinafter, also referred to as an “α-aminoalkyl phenone-based photopolymerization initiator”), a photopolymerization initiator having an α-hydroxyalkyl phenone structure (hereinafter, also referred to as an “α-hydroxyalkyl phenone-based polymerization initiator”), a photopolymerization initiator having an acylphosphine oxide structure (hereinafter, also referred to as an “acylphosphine oxide-based photopolymerization initiator”), and a photopolymerization initiator having an N-phenyl glycine structure (hereinafter, also referred to as an “N-phenyl glycine-based photopolymerization initiator”).

Among them, from the viewpoint of curing properties, the resin layer b preferably contains at least one polymerization initiator selected from the group consisting of an oxime ester-based photopolymerization initiator, a biimidazole-based photopolymerization initiator, an alkyl phenone-based photopolymerization initiator, an acetophenone-based photopolymerization initiator, and an acylphosphine oxide-based photopolymerization initiator, and more preferably contains an oxime ester-based photopolymerization initiator.

As the polymerization initiator in the resin layer b, only one kind may be used, or two or more kinds may be used in combination.

The content of the polymerization initiator is preferably 0.1% by mass to 20% by mass, more preferably 0.2% by mass to 10% by mass, and particularly preferably 0.5% by mass to 5% by mass with respect to the total mass of the resin layer b, from the viewpoint of the hardness of the resin layer b.

The resin layer b preferably has a compound e that can be bonded or coordinated to the metal contained in the metal nanobody from the viewpoints of the adhesiveness to the conductive layer a and the dimensional stability of the conductive pattern after applying an electric current.

The compound e is preferably a compound having an unshared electron pair, more preferably at least one compound selected from the group consisting of a nitrogen-containing compound having an unshared electron pair and a sulfur-containing compound having an unshared electron pair, and particularly preferably a nitrogen-containing compound having an unshared electron pair, from the viewpoints of the coordination property and the dimensional stability of the conductive pattern after applying an electric current.

Further, the compound e is preferably a heterocyclic compound, more preferably a nitrogen-containing heterocyclic compound, a sulfur-containing heterocyclic compound, or a nitrogen-containing and sulfur-containing heterocyclic compound, and particularly preferably a nitrogen-containing heterocyclic compound, from the viewpoints of the coordination property and the dimensional stability of the conductive pattern after applying an electric current.

Further, the nitrogen-containing heterocyclic compound preferably has a heterocyclic ring having two or more nitrogen atoms, more preferably has a heterocyclic ring having three or more nitrogen atoms, and particularly preferably has a heterocyclic ring having three or four nitrogen atoms, from the viewpoints of the coordination property and the dimensional stability of the conductive pattern after applying an electric current.

The heterocyclic ring contained in the heterocyclic compound may be any one of a monocyclic heterocyclic ring or a polycyclic heterocyclic ring.

Examples of the heteroatom contained in the heterocyclic compound include an oxygen atom, a nitrogen atom, and a sulfur atom. The heterocyclic compound preferably has at least one atom selected from the group consisting of a nitrogen atom, an oxygen atom, and a sulfur atom, and it is more preferably has a nitrogen atom.

Preferred examples of the heterocyclic compound include a triazole compound, a benzotriazole compound, a tetrazole compound, a thiadiazole compound, a triazine compound, a rhodanine compound, a thiazole compound, a benzothiazole compound, a benzimidazole compound, a benzoxazole compound, and a pyrimidine compound. Among them, from the viewpoint of the adhesiveness to the conductive layer a, the heterocyclic compound is preferably at least one compound selected from the group consisting of a triazole compound, a benzotriazole compound, a tetrazole compound, a thiadiazole compound, a triazine compound, a rhodanine compound, a thiazole compound, a benzimidazole compound, and a benzoxazole compound, more preferably at least one compound selected from the group consisting of a triazole compound, a benzotriazole compound, a tetrazole compound, a thiadiazole compound, a thiazole compound, a benzothiazole compound, a benzimidazole compound, and a benzoxazole compound, still more preferably at least one compound selected from the group consisting of a triazole compound and a tetrazole compound, and particularly preferably a triazole compound.

Preferred specific examples of the heterocyclic compound are shown below. Examples of the triazole compound and the benzotriazole compound include the following compounds.

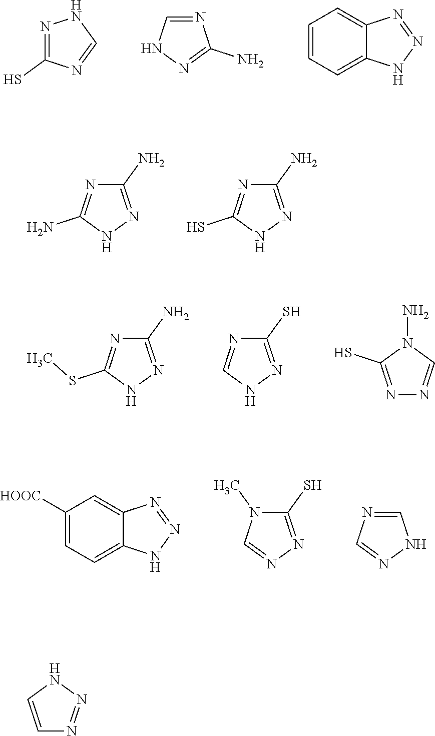

Examples of the tetrazole compound include the following compounds.

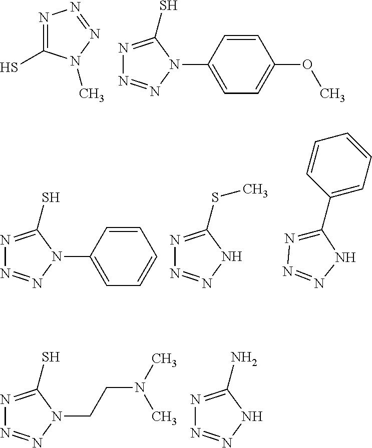

Examples of the thiadiazole compound include the following compounds.

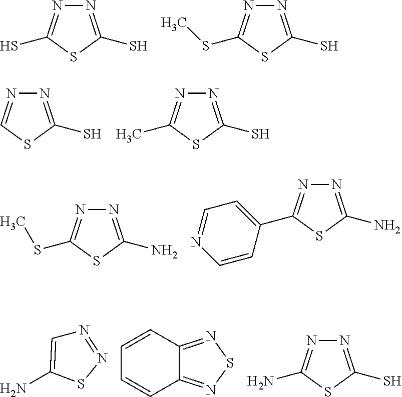

Examples of the triazine compound include the following compounds.

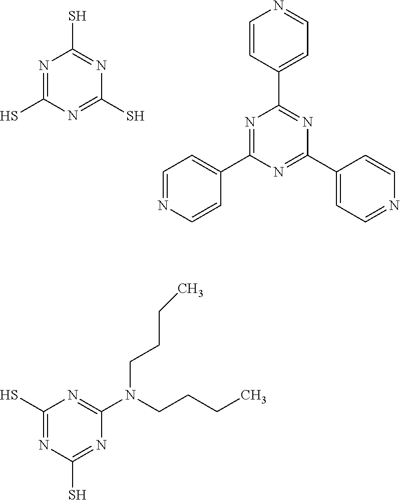 [SMILES: Sc1nc(S)nc(S)n1 ; c1cc(-c2nc(-c3ccncc3)nc(-c3ccncc3)n2)ccn1 ; CCCCN(CCCC)c1nc(S)nc(S)n1]

Examples of the rhodanine compound include the following compounds.

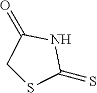

Examples of the thiazole compound include the following compounds.

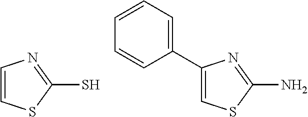

Examples of the benzothiazole compound include the following compounds.

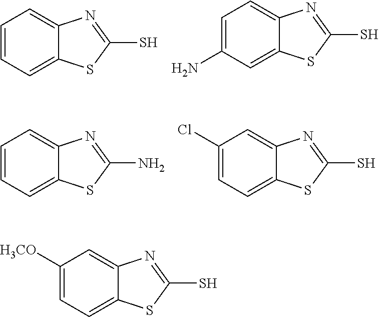 [SMILES: Sc1nc2ccccc2s1 ; Nc1ccc2nc(S)sc2c1 ; Nc1nc2ccccc2s1 ; Sc1nc2cc(Cl)ccc2s1 ; COc1ccc2sc(S)nc2c1]

Examples of the benzimidazole compound include the following compounds.

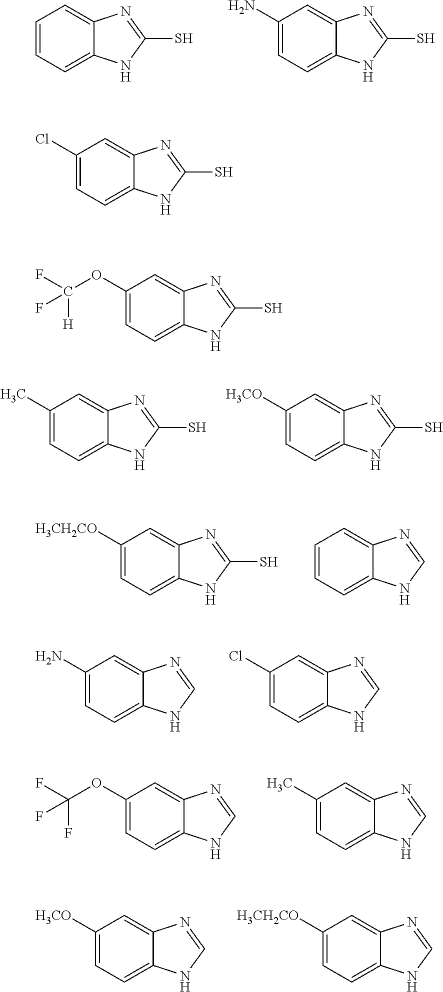

Examples of the benzoxazole compound include the following compounds.

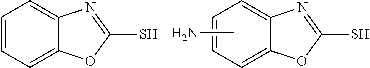

Preferred examples of the sulfur-containing compound include a thiol compound and a disulfide compound.

Preferred examples of the thiol compound include an aliphatic thiol compound. As the aliphatic thiol compound, a monofunctional aliphatic thiol compound or a polyfunctional aliphatic thiol compound (that is, bifunctional or higher functional aliphatic thiol compound) is suitably used.

Examples of the polyfunctional aliphatic thiol compound include trimethylolpropane tris(3-mercaptobutyrate), 1,4-bis(3-mercaptobutyryloxy)butane, pentaerythritol tetrakis (3-mercaptobutyrate), 1,3,5-tris(3-mercaptobutyryloxyethyl)-1,3,5-triazine-2,4,6(1H,3H,5H)-trione, trimethylolethane tris(3-mercaptobutyrate), tris[(3-mercaptopropionyloxy)ethyl] isocyanurate, trimethylolpropane tris(3-mercaptopropionate), pentaerythritol tetrakis(3-mercaptopropionate), tetraethylene glycol bis(3-mercaptopropionate), dipentaerythritol hexakis(3-mercaptopropionate), ethylene glycol bisthiopropionate, 1,4-bis (3-mercaptobutyryloxy)butane, 1,2-ethanedithiol, 1,3-propanedithiol, 1,6-hexamethylenedithiol, 2,2′-(ethylenedithio)diethanethiol, meso-2,3-dimercaptosuccinic acid, and di(mercaptoethyl) ether.

Examples of the monofunctional aliphatic thiol compound include 1-octanethiol, 1-dodecanethiol, β-mercaptopropionic acid, methyl-3-mercaptopropionate, 2-ethylhexyl-3-mercaptopropionate, n-octyl-3-mercaptopropionate, methoxybutyl-3-mercaptopropionate, and stearyl-3-mercaptopropionate.

Examples of the disulfide compound include 2-(4′-morpholinodithio)benzthiazole, 2,2′-benzthiazoyl disulfide, bis(2-benzamidephenyl)disulfide, 1,1-thiobis(2-naphthol), bis(2,4,5-trichlorophenyl)disulfide, 4,4′-dithiomorpholine, tetraethylthiuram disulfide, dibenzyl disulfide, bis(2,4-dinitrophenyl)disulfide, 4,4′-diaminodiphenyl disulfide, diallyl disulfide, di-tert-butyl disulfide, bis(6-hydroxy-2-naphthyl)disulfide, dicyclohexyl disulfide, o-isobutyroylthiamine disulfide, and diphenyl disulfide.

The molecular weight of the compound e is preferably less than 1,000, more preferably 50 to 500, still more preferably 50 to 200, and particularly preferably 50 to 150, from the viewpoint of the adhesiveness to the conductive layer a.

As the compound e in the resin layer b, only one kind may be used, or two or more kinds may be used in combination.

From the viewpoint of the adhesiveness to the conductive layer a, the content of the compound e is preferably 0.01% by mass to 20% by mass, more preferably 0.1% by mass to 10% by mass, still more preferably 0.3% by mass to 8% by mass, and particularly preferably 0.5% by mass to 5% by mass, with respect to the total mass of the resin layer b.

In addition, the resin layer b may contain another known additive.

The average thickness of the resin layer b is not particularly limited; however, it is preferably 1 nm to 200 nm, more preferably 5 nm to 100 nm, and particularly preferably 15 nm to 50 nm, from the viewpoint of the dimensional stability of the conductive pattern after applying an electric current.

The total thickness of the layer obtained by combining the layer a and layer b after forming the resin layer b on the conductive layer a is preferably 15 nm to 100 nm, more preferably 15 nm to 90 nm, and particularly preferably 15 nm to 60 nm. Here, the total thickness of the layer obtained by combining the layer a and layer b may be or may not be equal to the sum of the layer thicknesses in a case where the respective layers are formed independently. For example, in a case where the compatibility between the resins contained in the layer a and the layer b is high, a layer in which the materials of the layer a and the layer b are partially mixed is formed, and thus in this case, the total thickness of the layer obtained by combining the layer a and layer b is not equal to the sum of the layer thicknesses in a case where the respective layers are formed independently.

Step 2a and step 2b

The first embodiment of the manufacturing method for a substrate having a conductive pattern according to the present disclosure includes a step 2a of forming a photosensitive resin layer c on the resin layer b.

The second embodiment of the manufacturing method for a substrate having a conductive pattern according to the present disclosure includes a step 2b of forming the photosensitive resin layer c on the conductive layer a.

The method of forming the photosensitive resin layer c on the conductive layer a or the resin layer b is not particularly limited, and a known resist forming method can be used. Among the above, the step 2a and the step 2b are preferably a step of bringing a photosensitive transfer material into contact with the conductive layer a or the resin layer b to be transferred thereon, thereby forming the photosensitive resin layer c.

Further, it is preferable that the step 2a and the step 2b are a step of forming the photosensitive resin layer c and an interlayer in this order on the conductive layer a or the resin layer b, and it is more preferable that the interlayer is a water-soluble resin layer and a thermoplastic resin layer.

The method of transferring the photosensitive resin layer c on the conductive layer a or the resin layer b by using a photosensitive transfer material is preferably bringing the conductive layer a or the resin layer b into contact with the photosensitive resin layer c in the photosensitive transfer material, and subjecting the photosensitive transfer material to pressure bonding to the conductive layer a or the resin layer b. In the above aspect, since the adhesiveness between the photosensitive resin layer c and the conductive layer a or the resin layer b in the photosensitive transfer material is improved, the exposed and developed photosensitive resin layer c having a pattern formed thereon can be suitably used as an etching resist in a case of etching the conductive layer.

The preferred aspect of the photosensitive transfer material that is used in the manufacturing method for a substrate having a conductive pattern according to the present disclosure will be collectively described later.

The photosensitive resin layer c may be a positive type photosensitive resin layer or may be a negative type photosensitive resin layer.

Any one of the following aspects is preferably mentioned as an aspect of the photosensitive resin layer c.

An aspect in which the photosensitive resin layer c contains an alkali-soluble resin, a polymerizable compound, and a photopolymerization initiator

An aspect in which the photosensitive resin layer c contains a resin of which the polarity changes under the action of an acid (preferably, the resin is an acid-decomposable resin, that is, a polymer having a constitutional unit having an acid group protected by an acid-decomposable group) and photoacid generator

An aspect in which the photosensitive resin layer c contains a resin having a constitutional unit having a phenolic hydroxyl group, and a quinone diazide compound

The method of subjecting the conductive layer a or the resin layer b to pressure bonding to the photosensitive transfer material is not particularly limited, and a known transfer method or laminating method can be used.

The bonding of the photosensitive transfer material to the conductive layer a or the resin layer b is preferably carried out by superposing the outermost layer from the temporary support on a side of the photosensitive resin layer c in the photosensitive transfer material and the conductive layer a or the resin layer b and subjecting them to pressurization and heating by using means such as a roll. For bonding, it is possible to use a known laminator such as a laminator, a vacuum laminator, or an auto-cut laminator capable of further improving productivity.

The laminating temperature is not particularly limited; however, it is, for example, preferably 70° C. to 130° C.

The manufacturing method for a substrate having a conductive pattern according to the present disclosure is preferably carried out by a roll-to-roll method.

Hereinafter, the roll-to-roll method will be described.

The roll-to-roll method refers to a method that includes, in a case of using a substrate capable of being wound backward and wound forward as the substrate, a step (also referred to as a “forward winding step”) of winding forward the substrate or a substrate having the conductive layer or the like before any one of the steps included in the manufacturing method for a substrate having a conductive pattern according to the present disclosure, and a step (also referred to as a “backward winding step”) of winding backward the substrate having the conductive layer or the like after any one of the above steps, and at least any one of the steps (preferably all steps or all steps other than the heating step) is carried out while transporting the substrate or the substrate having the conductive layer or the like.

The forward winding method in the forward winding step and the backward winding method in the backward winding step are not particularly limited, and known methods may be used in the manufacturing method to which the roll-to-roll method is applied.

Further, in a case where the photosensitive transfer material has a protective film, the manufacturing method for a substrate having a conductive pattern according to the present disclosure preferably includes a protective film peeling step of peeling the protective film before the step 2a or the step 2b.

The method of peeling the protective film is not limited, and a known method can be applied.

Further, in a case where the photosensitive transfer material is used, the manufacturing method for a substrate having a conductive pattern according to the present disclosure preferably includes a temporary support peeling step of peeling the temporary support between the step 2a or the step 2b and the step 3, or between the exposure and the development treatment in the step 3.

The method of peeling the temporary support is not particularly limited, and a mechanism similar to the cover film peeling mechanism described in paragraphs 0161 to 0162 of JP2010-072589A can be used.

Step 3

The manufacturing method for a substrate having a conductive pattern according to the present disclosure includes a step 3 of obtaining, on the substrate, a resin pattern c′ of the photosensitive resin layer by exposure and development treatment on the photosensitive resin layer c;

The exposure in the step 3 is a pattern-shaped exposure treatment (also referred to as “pattern exposure”), that is, an exposure treatment in which an exposed portion and a non-exposed portion are present.

The positional relationship between the exposed area and the unexposed area in the pattern exposure is not particularly limited, and it is appropriately adjusted.

The detailed arrangement and the specific size of the pattern in the pattern exposure are not particularly limited. For example, at least a part of the pattern (preferably, a portion of the electrode pattern and/or lead-out wire of the touch panel) preferably contains a thin wire having a width of 20 μm or less and more preferably contains a thin wire having a width of 10 μm or less so that the display quality of the display device (for example, a touch panel) including an input device having a circuit wire manufactured by an etching method is improved and the area occupied by the lead-out wire is reduced.

Further, the resin pattern to be obtained preferably has a resin pattern having a line width of 20 μm or less, more preferably has a resin pattern having a line width of 10 μm or less, still more preferably has a resin pattern having a line width of 8 μm or less, and particularly preferably has a resin pattern having a line width of 5 μm or less, from the viewpoint of further exhibiting the effects in the present disclosure.

The light source that is used for exposure can be appropriately selected and used as long as it is a light source that emits light having a wavelength (for example, 365 nm, 405 nm, or 436 nm) with which the photosensitive resin layer c can be exposed. Specific examples thereof include an ultra-high pressure mercury lamp, a high pressure mercury lamp, a metal halide lamp, and a light emitting diode (LED).

The exposure amount is preferably 5 mJ/cm² to 200 mJ/cm² and more preferably 10 mJ/cm² to 100 mJ/cm².

Examples of the preferred aspect of the light source, the exposure amount, and the exposure method, which are used for exposure, include those described in paragraphs 0146 to 0147 of WO2018/155193A, the content of which is incorporated in the present specification.

In a case where a photosensitive transfer material is used, in the step 3, the pattern exposure may be carried out after the temporary support is peeled off from the transfer layer (the photosensitive resin layer c and the interlayer), or the pattern exposure may be carried out through the temporary support before the temporary support is peeled off, and then the temporary support may be peeled off. In a case where the temporary support is peeled off before exposure, the mask may be exposed in a state of being brought into contact with the transfer layer or may be exposed in a state of being in close proximity without being brought into contact with the transfer layer. In a case where the temporary support is exposed without peeling, the mask may be exposed in a state of being brought into contact with the temporary support or may be exposed in a state of being in close proximity without being brought into contact with the temporary support. In order to prevent mask contamination due to contact between the transfer layer and the mask and to avoid the influence of foreign substances adhered to the mask on the exposure, it is preferable to carry out pattern exposure without peeling off the temporary support. The exposure method can be carried out by appropriately selecting and using a contact exposure method in a case of contact exposure, and in a case of a non-contact exposure method, a proximity exposure method, a lens-based or mirror-based projection exposure method, a direct exposure (direct drawing exposure) method using an exposure laser or the like. In a case of the lens-based or mirror-based projection exposure, an exposure machine having a proper numerical aperture (NA) of a lens in response to the required resolving power and the focal depth can be used. In a case of the direct exposure method, drawing may be carried out directly on the photosensitive resin layer c, or reduced projection exposure may be carried out on the photosensitive resin layer c through a lens. Further, the exposure may be carried out not only in the atmospheric air but also under reduced pressure or vacuum, or the exposure may be carried out by interposing a liquid such as water between the light source and the transfer layer.

From the viewpoint of resolution, the exposure in the step 3 is preferably carried out by contact exposure in which the transfer layer is brought into contact with a mask.

Further, the exposure in the step 3 is preferably carried out by direct drawing exposure or projection exposure from the viewpoint of reducing the influence on the mask and the photosensitive resin layer.

The development treatment in the step 3 is preferably carried out with a developer.

The developer is not particularly limited as long as it can remove the non-image area (the unnecessary portion) of the photosensitive resin layer c, and it is possible to use a known developer, for example, the developer described in the publication of JP1993-72724A (JP-H5-72724A).

The developer is preferably an alkaline aqueous solution-based developer containing a compound having pKa=7 to 13 at a concentration of 0.05 mol/liter (L) to 5 mol/L. The developer may contain a water-soluble organic solvent and/or a surfactant.

Examples of the alkaline compound that can be contained in the alkaline aqueous solution include sodium hydroxide, potassium hydroxide, sodium carbonate, potassium carbonate, sodium hydrogen carbonate, potassium hydrogen carbonate, tetramethylammonium hydroxide, tetraethylammonium hydroxide, tetrapropylammonium hydroxide, tetrabutylammonium hydroxide, and choline (2-hydroxyethyltrimethylammoniumhydroxide).

Preferred examples of the developer also include the developers described in paragraph 0194 of WO2015/093271A. Examples of the development method to be suitably used include the development method described in paragraph 0195 of WO2015/093271A.

The development method is not particularly limited, and it may be any of puddle development, shower development, shower, and spin development, and dip development. The shower development is a development treatment of removing the non-image area by spraying a developer onto the photosensitive resin layer after exposure with a shower.

After the development step, it is preferable to spray a cleaning agent with a shower to remove the development residue.

The liquid temperature of the developer is not particularly limited; however, it is preferably 20° C. to 40° C.

Step 4

The manufacturing method for a substrate having a conductive pattern according to the present disclosure includes a step 4 of removing the metal nanobody in the conductive layer a by etching to form a conductive pattern d.

In the step 4, the resin pattern c′ formed from the photosensitive resin layer c is used as an etching resist to carry out an etching treatment of the conductive layer a.

As the method of etching treatment, a known method can be applied, and examples thereof include the methods described in paragraph 0209 to paragraph 0210 of JP2017-120435A and paragraph 0048 to paragraph 0054 of JP2010-152155A, a wet etching method in which immersion in an etchant is carried out, and a dry etching method such as plasma etching.

Further, the removal of the conductive layer a in the step 4 is preferably carried out by wet etching from the viewpoint of further exhibiting the effects in the present disclosure.

As the etchant that is used for wet etching, an acidic or alkaline etchant may be appropriately selected according to the etching target.

Examples of the acidic etchant include an aqueous solution of an acidic component alone selected from hydrochloric acid, sulfuric acid, nitric acid, acetic acid, hydrofluoric acid, oxalic acid, and phosphoric acid, and a mixed aqueous solution of an acidic component with a salt selected from iron (II) chloride, iron chloride (III), iron (II) nitrate, iron (III) nitrate, iron (II) sulfate, iron (III) sulfate, ammonium fluoride, or potassium permanganate. The acidic component may be a component in which a plurality of acidic components are combined.

Examples of the alkaline etchant include an aqueous solution of an alkaline component alone selected from sodium hydroxide, potassium hydroxide, ammonia, an organic amine, and a salt of an organic amine (tetramethylammonium hydroxide or the like), and a mixed aqueous solution of an alkaline component with a salt (potassium permanganate or the like). The alkaline component may be a component in which a plurality of alkaline components are combined.

Among them, the etchant preferably contains at least one selected from the group consisting of iron nitrate and iron sulfate.

Further, in order to control the etching rate and the shape of the material to be etched, it is also preferable to combine another acid, an organic solvent, a surfactant, an amine, and an inorganic salt agent.

Step 5a and step 5b

The first embodiment of the manufacturing method for a substrate having a conductive pattern according to the present disclosure includes a step 5a of softening or swelling at least one of the resin 1 or the resin 2.

The second embodiment of the manufacturing method for a substrate having a conductive pattern according to the present disclosure includes a step 5b of softening or swelling the resin 1.

It is presumed that the manufacturing method for a substrate having a conductive pattern according to the present disclosure suppresses the above-described metal migration phenomenon or the like and thus is excellent in the dimensional stability of the conductive pattern after applying an electric current due to including the step 5a or the step 5b, whereby voids generated by removing the metal nanobody in the step 4 are filled and eliminated or made small by softening or swelling at least one of the resin 1 or the resin 2.

From the viewpoint of the dimensional stability of the conductive pattern after applying an electric current, the step 5a is preferably a step of softening at least one of the resin 1 or the resin 2, more preferably a step of softening at least one of the resin 1 or the resin 2 by a heating treatment, and particularly preferably a step of softening at least one of the resin 1 or the resin 2 by a heating treatment and filling, by the etching, the voids generated by removing the metal nanobody.

Further, from the viewpoint of the dimensional stability of the conductive pattern after applying an electric current, it is preferable to at least soften or swell the resin 2 in the step 5a.

From the viewpoint of the dimensional stability of the conductive pattern after applying an electric current, the step 5b is preferably a step of softening the resin 1, more preferably a step of softening the resin 1 by a heating treatment, and particularly preferably a step of softening the resin 1 by a heating treatment and filling, by the etching, the voids generated by removing the metal nanobody.

In a case where the step 5a or the step 5b is a step of softening a resin, the step 5a or the step 5b may be carried out after the step 4 or may be carried out at the same time as the step 4, that is, during the step 4; however, it is preferably carried out after the step 4.

In a case where a heating treatment is carried out in the step 5a or the step 5b, the heating temperature may be any temperature as long as it is a temperature at which at least one of the resin 1 or the resin 2 is softened; however, it is preferably 40° C. to 200° C., more preferably 60° C. to 180° C., and particularly preferably 100° C. to 160° C.

The heating time is not particularly limited; however, it is preferably 1 minute to 24 hours, more preferably 5 minutes to 6 hours, and particularly preferably 10 minutes to 60 minutes.

Further, the heating temperature is preferably higher than the lower glass transition temperature between the glass transition temperature of the resin 1 and the glass transition temperature of the resin 2, from the viewpoint of the dimensional stability of the conductive pattern after applying an electric current.

Further, the heating treatment in the step 5a is particularly preferably carried out at a heating temperature satisfying Tgp<Th<Tgb from the viewpoint of the dimensional stability of the conductive pattern after applying an electric current.

It is noted that Th indicates a maximum temperature (° C.) during the heating treatment in the step 5a, Tgp indicates a lower glass transition temperature (° C.) between a glass transition temperature of the resin 1 and a glass transition temperature of the resin 2, and Tgb indicates a glass transition temperature (° C.) of the substrate.

The heating means that is used for the heating treatment in the step 5a or the step 5b is not particularly limited, and a known heating means can be used, for example, a heater, a hot plate, a convection oven (a hot air circulation type dryer), or a high frequency heater.

Further, the step 5a is preferably a step of swelling at least one of the resin 1 or the resin 2 during the step 4 or after the step 4, and more preferably a step of swelling at least one of the resin 1 or the resin 2 and filling, by the etching, the voids generated by removing the metal nanobody, during the step 4 or after the step 4.

The step 5b is preferably a step of swelling the resin 1 during the step 4 or after the step 4, and more preferably a step of swelling the resin 1 and filling, by the etching, the voids generated by removing the metal nanobody, during the step 4 or after the step 4.

The swelling can be suitably carried out by bringing a known solvent such as water or an organic solvent into contact with the resin 1 or the resin 2.

Among the above, the swelling is preferably carried out by with etchant in the step 4. The temperature at the time of swelling and the time of contact with the solvent are not particularly limited and can be appropriately selected.

Resin Pattern Removal Step

In the manufacturing method for a substrate having a conductive pattern according to the present disclosure, it is preferable to carry out a step of removing the remaining resin pattern c′ (a resin pattern removal step). The removal of the resin pattern may be carried out before or after the step 5a or the step 5b; however, it is preferably carried out before the step 5a or the step 5b.

The method of removing the remaining resin pattern c′ is not particularly limited; however, examples thereof include a method of carrying out removal by a chemical treatment, and a method of carrying out removal with a removing liquid is preferable.

Examples of the method of removing the resin pattern c′ include a method in which a substrate having the remaining resin pattern c′ is immersed in a removing liquid under stirring, having a liquid temperature of preferably 30° C. to 80° C. and more preferably 40° C. to 80° C. for 1 to 30 minutes.

Examples of the removing liquid include a removing liquid in which an inorganic alkaline component or an organic alkaline component is dissolved in water, dimethyl sulfoxide, N-methylpyrrolidone, or a mixed solution thereof. Examples of the inorganic alkaline component include sodium hydroxide and potassium hydroxide. Examples of the organic alkaline component include a primary amine compound, a secondary amine compound, a tertiary amine compound, and a quaternary ammonium salt compound.

Further, a removing liquid may be used and then removed by a known method such as a spray method, a shower method, or a puddle method.

Another Step

The manufacturing method for a substrate having a conductive pattern according to the present disclosure may include any step (another step) other than the above-described steps. Examples thereof include the following steps, which are not limited to these steps.

Further, examples of the exposure step, the development step, and the other step, which are applicable to the manufacturing method for a substrate having a conductive pattern according to the present disclosure, include the steps described in paragraphs 0035 to 0051 of JP2006-23696A.

Further, examples of the other step include a step of reducing a visible light reflectivity described in paragraph 0172 of WO2019/022089A and a step of forming a new conductive layer on an insulating film described in paragraph 0172 of WO2019/022089A, which are not limited to these steps.

Step of Reducing Visible Light Reflectivity

The manufacturing method for a substrate having a conductive pattern according to the present disclosure may include a step of carrying out a treatment of reducing the visible light reflectivity of a part or the whole of the conductive layer.

Examples of the treatment of reducing the visible light reflectivity include an oxidation treatment. In a case where the conductive layer containing copper is provided, the visible light reflectivity of the conductive layer can be reduced by subjecting copper to the oxidation treatment to obtain copper oxide and then blackening the conductive layer.

The treatment of reducing the visible light reflectivity is described in paragraphs 0017 to 0025 of JP2014-150118A and paragraph 0041, paragraph 0042, paragraph 0048, and paragraph 0058 of JP2013-206315A, and the contents described in these publications are incorporated in the present specification.

Step of Forming Insulating Film and Step of Forming New Conductive Layer on Surface of Insulating Film

The manufacturing method for a substrate having a conductive pattern according to the present disclosure preferably includes a step of forming an insulating film on the surface of the conductive pattern and a step of forming a new conductive layer on the surface of the insulating film.

These steps make it possible to form a second electrode pattern insulated from the first electrode pattern.

The step of forming an insulating film is not particularly limited, and examples thereof include a known method of forming a permanent film. Further, an insulating film having a desired pattern may be formed by photolithography using a photosensitive material having an insulating property.

The step of forming a new conductive layer on the insulating film is not particularly limited, and a new conductive layer having a desired pattern may be formed by, for example, photolithography using a photosensitive material having conductivity.

In the manufacturing method for a substrate having a conductive pattern according to the present disclosure, it is also preferable that a substrate having a plurality of conductive layers on both surfaces of the substrate is used, and a conductive pattern is formed sequentially or simultaneously on the conductive layers formed on both surfaces of the substrate. With such a configuration, it is possible to form a circuit wire for a touch panel in which the first conductive pattern is formed on one surface of the substrate and the second conductive pattern is formed on the other surface thereof. It is also preferable to form a circuit wire for a touch panel, having such a configuration, from both surfaces of the support in a roll-to-roll manner.

That is, in the manufacturing method for a substrate having a conductive pattern according to the present disclosure, it is preferable that the conductive pattern d′ is further formed on the surface of the substrate opposite to the surface on which the conductive layer a is provided.

Use Application

The substrate having a conductive pattern, manufactured by the manufacturing method for a substrate having a conductive pattern according to the present disclosure, can be applied to various devices. Examples of the device including the substrate having a conductive pattern include an input device, where a touch panel is preferable, and a capacitive touch panel is more preferable. Further, the input device can be applied to display devices such as an organic electroluminescence display device and a liquid crystal display device.

Further, the substrate having a conductive pattern, manufactured by the manufacturing method for a substrate having a conductive pattern according to the present disclosure, can be suitably applied to a flexible display device, particularly a flexible touch panel.

Photosensitive Transfer Material

The photosensitive transfer material that is used in the manufacturing method for a substrate having a conductive pattern according to the present disclosure preferably has a temporary support and a transfer layer including a photosensitive resin layer (which forms the photosensitive resin layer c) and more preferably has a temporary support, a transfer layer including a photosensitive resin layer, and a protective film in this order.

Further, the photosensitive transfer material that is used in the present disclosure may have another layer, for example, between the temporary support and the photosensitive resin layer, or between the photosensitive resin layer and the protective film.

Further, the photosensitive transfer material that is used in the present disclosure preferably further has a thermoplastic resin layer and a water-soluble resin layer between the temporary support and the photosensitive resin layer.

Further, the transfer layer preferably further includes a thermoplastic resin layer and a water-soluble resin layer.

The photosensitive transfer material that is used in the present disclosure is preferably a roll-shaped photosensitive transfer material from the viewpoint of further exhibiting the effects in the present disclosure.

One example of the aspect of the photosensitive transfer material that is used in the present disclosure is described below, which is not limited thereto.

(1) “Temporary support/photosensitive resin layer/refractive index adjusting layer/protective film”

(2) “Temporary support/photosensitive resin layer/protective film”

(3) “Temporary support/water-soluble resin layer/photosensitive resin layer/protective film”

(4) “Temporary support/thermoplastic resin layer/water-soluble resin layer/photosensitive resin layer/protective film”

In each of the above configurations, the photosensitive resin layer may be a positive type photosensitive resin layer or a negative type photosensitive resin layer, and it is preferably a negative type photosensitive resin layer. In addition, it is also preferable that the photosensitive resin layer is a colored resin layer.

Among them, the configuration of the photosensitive transfer material is preferably, for example, the configuration of (2) to (4) described above.

In a case of a configuration of the photosensitive transfer material, in which another layer is provided on a side of the photosensitive resin layer opposite to the temporary support side, the total thickness of the other layer arranged on the side of the photosensitive resin layer opposite to the temporary support side is preferably 0.1% to 30% and more preferably 0.1% to 20% with respect to the layer thickness of the photosensitive resin layer.

Hereinafter, the photosensitive transfer material that is used in the present disclosure will be described with reference to one example of a specific embodiment.

Hereinafter, the photosensitive transfer material will be described with reference to one example.

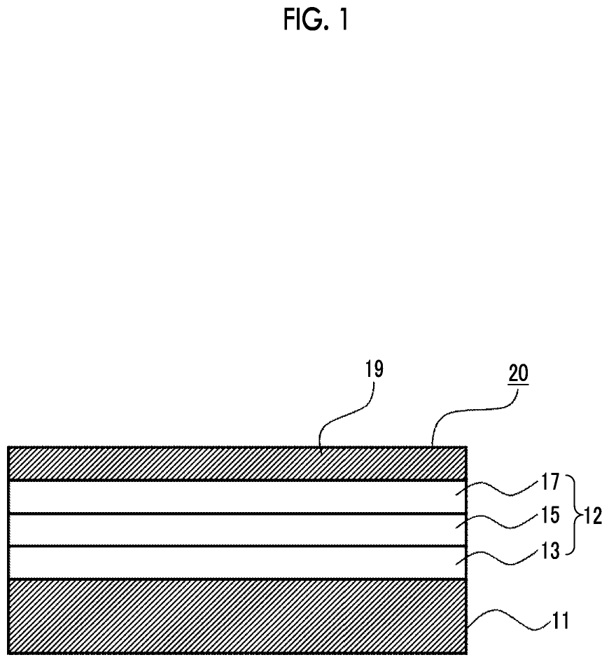

A photosensitive transfer material 20 illustrated in FIG. 1 has, in the following order, a temporary support 11, a transfer layer 12 including a thermoplastic resin layer 13, a water-soluble resin layer 15, a photosensitive resin layer 17, and a protective film 19.

Here, although the photosensitive transfer material 20 illustrated in FIG. 1 has a form in which the thermoplastic resin layer 13 and the water-soluble resin layer 15 are arranged, the thermoplastic resin layer 13 and the water-soluble resin layer 15 may not be arranged.

Hereinafter, each element that constitutes the photosensitive transfer material will be described.

Temporary Support

The photosensitive transfer material that is used in the present disclosure preferably has a temporary support.

The temporary support is a support that supports the photosensitive resin layer or the laminate including the photosensitive resin layer and can be peeled off

The temporary support preferably has light transmittance from the viewpoint that the photosensitive resin layer is capable of being exposed through the temporary support in a case where the photosensitive resin layer is subjected to pattern exposure. In addition, in this specification, “having light transmittance” means that the light transmittance at the wavelength used for pattern exposure is 50% or more.

From the viewpoint of improving the exposure sensitivity of the photosensitive resin layer, the temporary support preferably has a light transmittance of 60% or more and more preferably 70% or more at the wavelength (more preferably 365 nm) used for pattern exposure.

The light transmittance of the layer included in the photosensitive transfer material is a rate of the intensity of the emitted light that has emitted and passed through a layer with respect to the intensity of the incident light in a case where the light is incident in a direction perpendicular to the main surface of the layer (the thickness direction), and it is measured by using MCPD Series manufactured by Otsuka Electronics Co., Ltd.

Examples of the material that constitutes the temporary support include a glass substrate, a resin film, and paper, and a resin film is preferable from the viewpoints of hardness, flexibility, and light transmittance.

Examples of the resin film include a polyethylene terephthalate (PET) film, a cellulose triacetate film, a polystyrene film, and a polycarbonate film. Among them, a PET film is preferable, and a biaxially stretched PET film is more preferable.

The thickness (the layer thickness) of the temporary support is not particularly limited, and it may be selected depending on the material from the viewpoints of the hardness as a support, the flexibility required for bonding to a substrate, and the light transmittance required in the step 3.

The thickness of the temporary support is preferably in a range of 5 μm to 100 μm, more preferably in a range of 10 μm to 50 μm, still more preferably in a range of 10 μm to 20 μm, and particularly preferably in a range of 10 μm to 16 μm, from the viewpoints of ease of handling and general-purpose property.

In addition, the thickness of the temporary support is preferably 50 μm or less, more preferably 25 μm or less, still more preferably 20 μm or less, and particularly preferably 16 μm or less, from the viewpoints of defect suppressibility, resolution, and linearity of the resin pattern.

In addition, it is preferable that the film to be used as the temporary support does not have deformation such as wrinkles, scratches, and defects.

From the viewpoint of pattern forming properties during pattern exposure through the temporary support and transparency of the temporary support, it is preferable that the number of fine particles, foreign substances, defects, and precipitates included in the temporary support is small. The number of fine particles, foreign substances, and defects having a diameter of 1 μm or more is preferably 50 pieces/10 mm² or less, more preferably 10 pieces/10 mm² or less, still more preferably 3 pieces/10 mm² or less, and particularly preferably 0 pieces/10 mm².

From the viewpoints of the defect suppressibility and resolution of the resin pattern and the transparency of the temporary support, it is preferable that the haze of the temporary support is small. Specifically, the haze value of the temporary support is preferably 2% or less, more preferably 1.5% or less, still more preferably less than 1.0%, and particularly preferably 0.5% or less.

The haze value in the present disclosure is measured by a haze meter (NDH-2000, manufactured by NIPPON DENSHOKU INDUSTRIES Co., Ltd.) by a method according to JIS K 7105: 1981.

From the viewpoint of imparting handleability, a layer (a lubricant layer) containing fine particles may be provided on the surface of the temporary support. The lubricant layer may be provided on one surface of the temporary support or on both surfaces thereof. The diameter of the particles included in the lubricant layer can be, for example, 0.05 μm to 0.8 μm. In addition, the layer thickness of the lubricant layer can be, for example, 0.05 μm to 1.0 μm.

The arithmetic average roughness Ra of the surface of the temporary support opposite to the photosensitive resin layer side is preferably equal to or larger than an arithmetic average roughness Ra of the surface of the temporary support on the photosensitive resin layer side, from the viewpoints of the transportability, the defect suppressibility of the resin pattern, and the resolution.

The arithmetic average roughness Ra of the surface of the temporary support opposite to the photosensitive resin layer side is preferably 100 nm or less, more preferably 50 nm or less, still more preferably 20 nm or less, and particularly preferably 10 nm or less, from the viewpoints of the transportability, the defect suppressibility of the resin pattern, and the resolution.

The arithmetic average roughness Ra of the surface of the temporary support on the photosensitive resin layer side is preferably 100 nm or less, more preferably 50 nm or less, still more preferably 20 nm or less, and particularly preferably 10 nm or less, from the viewpoints of the peelability of the temporary support, the defect suppressibility of the resin pattern, and the resolution.

Further, the value of “the arithmetic average roughness Ra of the surface of the temporary support opposite to the photosensitive resin layer side”-“the arithmetic average roughness Ra of the surface of the temporary support on the photosensitive resin layer side” is preferably 0 nm to 10 nm and more preferably 0 nm to 5 nm from the viewpoints of the transportability, the defect suppressibility of the resin pattern, and the resolution.

The arithmetic average roughness Ra of the surface of the temporary support or the protective film in the present disclosure shall be measured by the following method.

Using a three-dimensional optical profiler (New View7300, manufactured by Zygo Corporation), the surface of the temporary support or the protective film is measured under the following conditions to obtain a surface profile of the film.

As the measurement and analysis software, Microscope Application of MetroPro ver. 8.3.2 is used. Next, the Surface Map screen is displayed with the above analysis software, and the histogram data is obtained in the Surface Map screen. From the obtained histogram data, the arithmetic average roughness is calculated, and the Ra value of the surface of the temporary support or the protective film is obtained.

In a case where the temporary support or the protective film is bonded to the photosensitive resin layer or the like, the temporary support or the protective film may be peeled off from the photosensitive resin layer and followed by measuring the Ra value of the surface on the peeled side.

The peeling force of the temporary support, specifically, the peeling force between the temporary support and the photosensitive resin layer or the thermoplastic resin layer is preferably 0.5 mN/mm or more, and more preferably 0.5 mN/mm to 2.0 mN/mm from the viewpoint of suppressibility of the peeling of the temporary support due to the adhesion between the vertically stacked laminates in a case where the laminate wound backward is transported again by the roll-to-roll method.

The peeling force of the temporary support in the present disclosure shall be measured as follows.

A copper layer having a thickness of 200 nm is produced on a polyethylene terephthalate (PET) film having a thickness of 100 μm by a sputtering method, and a PET substrate attached with a copper layer is produced.

The protective film is peeled off from the produced photosensitive transfer material, which is subsequently laminated to the PET substrate attached with a copper layer under laminating conditions of a laminating roll temperature of 100° C., a linear pressure of 0.6 MPa, and a linear speed (a laminating rate) of 1.0 m/min. Next, after attaching a tape (PRINTACK manufactured by Nitto Denko Corporation) to the surface of the temporary support, a laminate having at least the temporary support and the photosensitive resin layer is cut to a size of 70 mm×10 mm on the PET substrate attached with a copper layer to produce a sample. The PET substrate side of the sample is fixed on the sample table.

Using a tensile compression tester (SV-55, manufactured by IMADA SEISAKUSHO CO., LTD.), the tape is pulled in a direction of 180 degrees at 5.5 mm/sec so that peeling is caused to occur between the photosensitive resin layer or thermoplastic resin layer and the temporary support, and an adhesion force, the force (the peeling force) required for peeling, is measured.

Preferred aspects of the temporary support are described in, for example, paragraph 0017 and paragraph 0018 of JP2014-85643A, paragraphs 0019 to 0026 of JP2016-27363A, paragraphs 0041 to 0057 of WO2012/081680A, paragraphs 0029 to 0040 of WO2018/179370A, and paragraph 0012 to paragraph 0032 of JP2019-101405A, the contents of these publications are incorporated in the present specification.

Photosensitive Resin Layer

The photosensitive transfer material that is used in the present disclosure has a photosensitive resin layer.

The photosensitive resin layer may be a positive type photosensitive resin layer or a negative type photosensitive resin layer, and it is preferably a negative type photosensitive resin layer.

The negative type photosensitive resin layer preferably contains an alkali-soluble resin, a polymerizable compound, and a photopolymerization initiator, and based on the total mass of the photosensitive resin layer, it preferably contains the alkali-soluble resin: 10% by mass to 90% by mass, ethylenically unsaturated compound: 5% by mass to 70% by mass, and photopolymerization initiator: 0.01% by mass to 20% by mass.

The positive type photosensitive resin layer is not limited, and a known positive type photosensitive resin layer can be used. The positive type photosensitive resin layer preferably contains an acid-decomposable resin, that is, a polymer having a constitutional unit having an acid group protected by an acid-decomposable group, and a photoacid generator. Further, the positive type photosensitive resin layer preferably contains a resin having a constitutional unit having a phenolic hydroxyl group, and a quinone diazide compound.

Further, the positive type photosensitive resin layer is more preferably a chemically amplified positive type photosensitive resin layer containing a polymer having a constitutional unit having an acid group protected by an acid-decomposable group and containing a photoacid generator.

Hereinafter, each component will be described in order. It is noted that in a case where the “photosensitive resin layer” is mentioned, it shall refer to both a positive type photosensitive resin layer and a negative type photosensitive resin layer.

Polymerizable Compound

The negative type photosensitive resin layer preferably contains a polymerizable compound. In the present specification, the “polymerizable compound” is a compound that polymerizes under the action of a photopolymerization initiator described later, and it means a compound different from the alkali-soluble resin described later.

The polymerizable group contained in the polymerizable compound is not particularly limited as long as it is a group involved in the polymerization reaction, and examples thereof include groups having an ethylenic unsaturated group, such as a vinyl group, an acryloyl group, a methacryloyl group, a styryl group, and a maleimide group; and groups having a cationically polymerizable group, such as an epoxy group and an oxetane group.

The polymerizable group is preferably a group having an ethylenic unsaturated group, and more preferably an acryloyl group or a methacryloyl group.

Further, the polymerizable compound preferably includes an ethylenically unsaturated compound and more preferably includes a (meth)acrylate compound.

The negative type photosensitive resin layer preferably contains a bifunctional or higher functional polymerizable compound (a polyfunctional polymerizable compound) and more preferably contains a trifunctional or higher functional polymerizable compound from the viewpoints of resolution and pattern forming properties.

Here, the bifunctional or higher functional polymerizable compound means a compound having two or more polymerizable groups in one molecule.

Further, the number of polymerizable groups in one molecule of the polymerizable compound is preferably 6 or less in terms of excellent resolution and peelability.

The negative type photosensitive resin layer preferably contains a bifunctional or trifunctional ethylenically unsaturated compound and more preferably contains a bifunctional ethylenically unsaturated compound in that the negative type photosensitive resin layer has a better balance between the photosensitivity of the photosensitive resin layer and the resolution as well as the peelability.

In terms of excellent peelability, the content of the bifunctional or trifunctional ethylenically unsaturated compound in the negative type photosensitive resin layer is preferably 60% by mass or more, more preferably more than 70% by mass, and still more preferably 90% by mass or more, with respect to the total content of the ethylenically unsaturated compound. The upper limit thereof is not particularly limited and may be 100% by mass. That is, all the ethylenically unsaturated compounds contained in the negative type photosensitive resin layer may be bifunctional ethylenically unsaturated compounds.

From the viewpoint of resolution and pattern forming properties, the negative type photosensitive resin layer preferably contains a polymerizable compound having a polyalkylene oxide structure and more preferably contains a polymerizable compound having a polyethylene oxide structure.

Preferred examples of the polymerizable compound having a polyalkylene oxide structure include a polyalkylene glycol di(meth)acrylate which will be described later.

Ethylenically Unsaturated Compound B1

The negative type photosensitive resin layer preferably contains an ethylenically unsaturated compound B1 having an aromatic ring and two ethylenic unsaturated groups. The ethylenically unsaturated compound B1 is a bifunctional ethylenically unsaturated compound having one or more aromatic rings in one molecule, among the above-described ethylenically unsaturated compounds.

In the negative type photosensitive resin layer, the mass ratio of the content of the ethylenically unsaturated compound B1 to the content of the ethylenically unsaturated compound is preferably 40% by mass or more, more preferably 50% by mass or more, still more preferably 55% by mass or more, and particularly preferably 60% by mass or more, from the viewpoint of more excellent resolution. The upper limit thereof is not particularly limited; however, it is preferably 99% by mass or less, more preferably 95% by mass or less, still more preferably 90% by mass or less, and particularly preferably 85% by mass or less, in terms of peelability.

Examples of the aromatic ring contained in the ethylenically unsaturated compound B1 include aromatic hydrocarbon rings such as a benzene ring, a naphthalene ring, and an anthracene ring, aromatic heterocyclic rings such as a thiophene ring, a furan ring, a pyrrole ring, an imidazole ring, a triazole ring, and a pyridine ring, and fused rings thereof, where an aromatic hydrocarbon ring is preferable, and a benzene ring is more preferable. It is noted that the aromatic ring may have a substituent.

The ethylenically unsaturated compound B1 may have only one aromatic ring or may have two or more aromatic rings.

The ethylenically unsaturated compound B1 preferably has a bisphenol structure from the viewpoint of improving the resolution by suppressing the swelling of the negative type photosensitive resin layer due to the developer.

Examples of the bisphenol structure include a bisphenol A structure derived from bisphenol A (2,2-bis(4-hydroxyphenyl)propane) a bisphenol F structure derived from bisphenol F (2,2-bis(4-hydroxyphenyl)methane), and a bisphenol B structure derived from bisphenol B (2,2-bis(4-hydroxyphenyl)butane), where a bisphenol A structure is preferable.

Examples of the ethylenically unsaturated compound B1 having a bisphenol structure include a compound having a bisphenol structure and two ethylenic unsaturated groups (preferably (meth)acryloyl groups) bonded to both ends of the bisphenol structure.

Both ends of the bisphenol structure and the two ethylenic unsaturated groups may be directly bonded or may be bonded through one or more alkyleneoxy groups. The alkyleneoxy group to be added to both ends of the bisphenol structure is preferably an ethyleneoxy group or a propyleneoxy group and more preferably an ethyleneoxy group. The number of alkyleneoxy groups to be added to the bisphenol structure is not particularly limited; however, it is preferably 4 to 16 and more preferably 6 to 14 per molecule.

The ethylenically unsaturated compound B1 having a bisphenol structure is described in paragraphs 0072 to 0080 of JP2016-224162A, and the content described in this publication is incorporated in the present specification.

The ethylenically unsaturated compound B1 is preferably a bifunctional ethylenically unsaturated compound having a bisphenol A structure, and it is more preferably 2,2-bis(4-((meth)acryloxypolyalkoxy)phenyl)propane.

Examples of the 2,2-bis(4-((meth)acryloxypolyalkoxy)phenyl)propane include 2,2-bis(4-(methacryloxydiethoxy)phenyl)propane (FA-324M, manufactured by Showa Denko Materials Co., Ltd.), 2,2-bis(4-(methacryloxyethoxypropoxy)phenyl)propane, 2,2-bis(4-(methacryloxypentaethoxy)phenyl)propane (BPE-500, manufactured by Shin-Nakamura Chemical Co., Ltd.), 2,2-bis(4-(methacryloxydodecaethoxytetrapropoxy)phenyl)propane (FA-3200MY, manufactured by Showa Denko Materials Co., Ltd.), 2,2-bis(4-(methacryloxypentadecaethoxy)phenyl)propane (BPE-1300, manufactured by Shin-Nakamura Chemical Co., Ltd.), 2,2-bis(4-(methacryloxydiethoxy)phenyl)propane (BPE-200, manufactured by Shin-Nakamura Chemical Co., Ltd.), and ethoxylated (10) bisphenol A diacrylate (NK Ester A-BPE-10, manufactured by Shin-Nakamura Chemical Co., Ltd.).

As the ethylenically unsaturated compound B1, a compound represented by Formula (Bis) can be used.

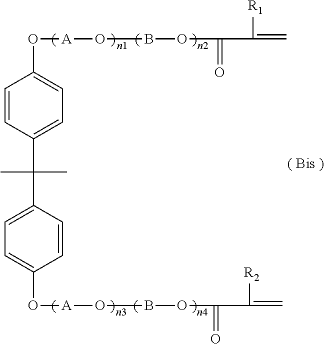

In Formula (Bis), R₁ and R₂ each independently represent a hydrogen atom or a methyl group, A is C₂H₄, B is C₃H₆, n₁ and n₃ are each independently an integer of 1 to 39, where n₁+n₃ is an integer of 2 to 40, n₂ and n₄ are each independently an integer of 0 to 29, where n₂+n₄ is an integer of 0 to 30, and the sequences of repeating units of -(A-O)— and —(B—O)— may be a random type or a block type. Here, in a case of a block type, any one of -(A-O)— or —(B—O)— may be on the bisphenol structure side.

In one aspect, n₁+n₂+n₃+n₄ is preferably an integer of 2 to 20, more preferably an integer of 2 to 16, and still more preferably an integer of 4 to 12. In addition, n₂+n₄ is preferably an integer of 0 to 10, more preferably an integer of 0 to 4, still more preferably an integer of 0 to 2, and particularly preferably 0.

The ethylenically unsaturated compound B1 may be used alone or in a combination of two or more thereof.

From the viewpoint of more excellent resolution, the content of the ethylenically unsaturated compound B1 in the negative type photosensitive resin layer is preferably 10% by mass or more and more preferably 20% by mass or more with respect to the total mass of the negative type photosensitive resin layer. The upper limit thereof is not particularly limited; however, it is preferably 70% by mass or less and more preferably 60% by mass or less in terms of transferability and edge fusion (a phenomenon in which a component in the negative type photosensitive resin layer exudes from the end part of the photosensitive transfer material).

The negative type photosensitive resin layer may contain an ethylenically unsaturated compound other than the above-described ethylenically unsaturated compound B1.

The ethylenically unsaturated compound other than the ethylenically unsaturated compound B1 is not particularly limited and can be appropriately selected from known compounds. Examples thereof include a compound having one ethylenic unsaturated group in one molecule (a monofunctional ethylenically unsaturated compound), a bifunctional ethylenically unsaturated compound having no aromatic ring, and a trifunctional or higher functional ethylenically unsaturated compound.

Examples of the monofunctional ethylenically unsaturated compound include ethyl (meth)acrylate, ethylhexyl (meth)acrylate, 2-(meth)acryloyloxyethyl succinate, polyethylene glycol mono(meth)acrylate, polypropylene glycol mono(meth)acrylate, and phenoxyethyl (meth)acrylate.

Examples of the bifunctional ethylenically unsaturated compound having no aromatic ring include alkylene glycol di(meth)acrylate, polyalkylene glycol di(meth)acrylate, urethane di(meth)acrylate, and trimethylolpropane diacrylate.

Examples of the alkylene glycol di(meth)acrylate include tricyclodecanedimethanol diacrylate (A-DCP, manufactured by Shin-Nakamura Chemical Co., Ltd.), tricyclodecanedimethanol dimethacrylate (DCP, manufactured by Shin-Nakamura Chemical Co., Ltd.), 1,9-nonandiol diacrylate (A-NOD-N, manufactured by Shin-Nakamura Chemical Co., Ltd.), 1,6-hexanediol diacrylate (A-HD-N, manufactured by Shin-Nakamura Chemical Co., Ltd.), ethylene glycol dimethacrylate, 1,10-decanediol diacrylate, and neopentyl glycol di(meth)acrylate.

Examples of the polyalkylene glycol di(meth)acrylate include polyethylene glycol di(meth)acrylate, dipropylene glycol diacrylate, tripropylene glycol diacrylate, and polypropylene glycol di(meth)acrylate.

Examples of the urethane di(meth)acrylate include propylene oxide-modified urethane di(meth)acrylate, as well as ethylene oxide- and propylene oxide-modified urethane di(meth)acrylates. Examples of the commercially available product include 8UX-015A (manufactured by Taisei Fine Chemical Co., Ltd.), UA-32P (manufactured by Shin-Nakamura Chemical Co., Ltd.), and UA-1100H (manufactured by Shin-Nakamura Chemical Co., Ltd.).

Examples of the trifunctional or higher functional ethylenically unsaturated compound include dipentaerythritol (tri/tetra/penta/hexa)(meth)acrylate, pentaerythritol (tri/tetra)(meth)acrylate, trimethylolpropane tri(meth)acrylate, ditrimethylolpropane tetra(meth)acrylate, trimethylolethane tri(meth)acrylate, isocyanuric acid tri(meth)acrylate, glycerin tri(meth)acrylate, and an alkylene oxide-modified product thereof.

Here, “(tri/tetra/penta/hexa)(meth)acrylate” has a concept including tri(meth)acrylate, tetra(meth)acrylate, penta(meth)acrylate, and hexa(meth)acrylate, and “(tri/tetra)(meth)acrylate” has a concept that includes tri(meth)acrylate and tetra(meth)acrylate. In one aspect, the negative type photosensitive resin layer preferably contains the above-described ethylenically unsaturated compound B1 and the above-described trifunctional or higher functional ethylenically unsaturated compound, and more preferably contains the above-described ethylenically unsaturated compound B1 and two or more kinds of trifunctional or higher functional ethylenically unsaturated compounds. In this case, the mass ratio of the ethylenically unsaturated compound B1 to the trifunctional or higher functional ethylenically unsaturated compound ((the total mass of the ethylenically unsaturated compound B1):(the total mass of the trifunctional or higher functional ethylenically unsaturated compound)) is preferably 1:1 to 5:1, more preferably 1.2:1 to 4:1, and still more preferably 1.5:1 to 3:1.

Further, in one aspect, the negative type photosensitive resin layer preferably contains the above-described ethylenically unsaturated compound B1 and two or more kinds of trifunctional ethylenically unsaturated compounds.

Examples of the alkylene oxide-modified product of the trifunctional or higher functional ethylenically unsaturated compound include a caprolactone-modified (meth)acrylate compound (KAYARAD (registered trade name) DPCA-20 manufactured by Nippon Kayaku Co., Ltd., A-9300-1CL manufactured by Shin-Nakamura Chemical Co., Ltd., or the like), an alkylene oxide-modified (meth)acrylate compound (KAYARAD RP-1040 manufactured by Nippon Kayaku Co., Ltd., ATM-35E or A-9300 manufactured by Shin-Nakamura Chemical Co., Ltd., EBECRYL (registered trade name) 135 manufactured by DAICEL-ALLNEX Ltd., or the like), ethoxylated glycerin triacrylate (A-GLY-9E manufactured by Shin-Nakamura Chemical Co., Ltd. or the like), ARONIX (registered trade name) TO-2349 (manufactured by Toagosei Co., Ltd.), ARONIX M-520 (manufactured by Toagosei Co., Ltd.), and ARONIX M-510 (manufactured by Toagosei Co., Ltd.).

Further, as the ethylenically unsaturated compound other than the ethylenically unsaturated compound B1, the ethylenically unsaturated compounds having an acid group described in paragraphs 0025 to 0030 of JP2004-239942A may be used.

In the negative type photosensitive resin layer, the value of the ratio Mm/Mb of the content Mm of the ethylenically unsaturated compound to the content Mb of the alkali-soluble resin is preferably 1.0 or less, more preferably 0.9 or less, and particularly preferably 0.5 or more and 0.9 or less, from the viewpoint of resolution and linearity.

Further, the ethylenically unsaturated compound in the negative type photosensitive resin layer preferably contains a (meth)acrylic compound from the viewpoint of curing properties and resolution.

Furthermore, from the viewpoint of curing properties, resolution, and linearity, it is more preferable that the ethylenically unsaturated compound in the negative type photosensitive resin layer contains a (meth)acrylic compound and the content of the acrylic compound is 60% by mass or less with respect to the total mass of the (meth)acrylic compound contained in the negative type photosensitive resin layer.

The molecular weight (the weight-average molecular weight (Mw) in a case of having a distribution) of the ethylenically unsaturated compound including the ethylenically unsaturated compound B1 is preferably 200 to 3,000, more preferably 280 to 2,200, and still more preferably 300 to 2,200.

The ethylenically unsaturated compound may be used alone or in a combination of two or more thereof.

The content of the ethylenically unsaturated compound in the negative type photosensitive resin layer is preferably 10% by mass to 70% by mass, more preferably 20% by mass to 60% by mass, and still more preferably 20% by mass to 50% by mass, with respect to the total mass of the negative type photosensitive resin layer.

Photopolymerization Initiator

The negative type photosensitive resin layer preferably contains a photopolymerization initiator.

The photopolymerization initiator is a compound that initiates the polymerization of an ethylenically unsaturated compound by receiving an actinic ray such as an ultraviolet ray, visible light, or an X-ray. The photopolymerization initiator is not particularly limited, and a known photopolymerization initiator can be used.

Examples of the photopolymerization initiator include a photoradical polymerization initiator and a photocationic polymerization initiator.

Among them, the photosensitive resin layer is preferably a photoradical polymerization initiator from the viewpoints of resolution and pattern forming properties.

Examples of the photoradical polymerization initiator include a photopolymerization initiator having an oxime ester structure, a photopolymerization initiator having an α-aminoalkyl phenone structure, a photopolymerization initiator having an α-hydroxyalkyl phenone structure, a photopolymerization initiator having an acylphosphine oxide structure, a photopolymerization initiator having an N-phenyl glycine structure, and a biimidazole compound.

Examples of the photoradical polymerization initiator which may be used include polymerization initiators described in paragraphs 0031 to 0042 of JP2011-95716A and paragraphs 0064 to 0081 of JP2015-14783A.

Examples of the photoradical polymerization initiator include ethyl dimethylaminobenzoate (DBE, CAS No. 10287-53-3), benzoin methyl ether, anisyl (p,p′-dimethoxybenzyl), TAZ-110 (product name: Midori Kagaku Co., Ltd.), benzophenone, TAZ-111 (product name: Midori Kagaku Co., Ltd.), Irgacure OXE01, OXE02, OXE03, OXE04 (BASF SE), Omnirad 651 and 369 (product name: IGM Resins B.V.), and 2,2′-bis(2-chlorophenyl)-4,4′,5,5′-tetraphenyl-1,2′-biimidazole (manufactured by Tokyo Chemical Industry Co., Ltd.).

Examples of the commercially available product of the photoradical polymerization initiator include 1-[4-(phenylthio)phenyl]-1,2-octanedione-2-(O-benzoyloxime) (product name: IRGACURE (registered trade name)), OXE01 (manufactured by BASF SE), 1-[9-ethyl-6-(2-methylbenzoyl)-9H-carbazole-3-yl]ethanone-1-(O-acetyloxime) (product name: IRGACURE OXE02, manufactured by BASF SE), IRGACURE OXE03 (manufactured by BASF SE), 2-(dimethylamino)-2-[(4-methylphenyl)methyl]-1-[4-(4-morpholinyl)phenyl]-1-butanone (product name: Omnirad 379EG, IGM Resins B.V.), 2-methyl-1-(4-methylthiophenyl)-2-morpholinopropane-1-one (product name: Omnirad 907, IGM Resins B.V.), 2-hydroxy-1-{4-[4-(2-hydroxy-2-methylpropionyl)benzyl]phenyl}-2-methylpropane-1-one (product name: Omnirad 127, IGM Resins B.V.), 2-benzyl-2-dimethylamino-1-(4-morpholinophenyl)butanone-1 (product name: Omnirad 369, manufactured by IGM Resins B.V.), 2-hydroxy-2-methyl-1-phenylpropane-1-one (product name: Omnirad 1173, manufactured by IGM Resins B.V.), 1-hydroxycyclohexylphenylketone (product name: Omnirad 184, manufactured by IGM Resins B.V.), 2,2-dimethoxy-1,2-diphenylethane-1-one (product name: Omnirad 651, manufactured by IGM Resins B.V.), 2,4,6-trimethylbenzoyl-diphenylphosphinoxide (product name: Omnirad TPO H, IGM Resins B.V.), bis(2,4,6-trimethylbenzoyl)phenylphosphine oxide (product name: Omnirad 819, IGM Resins B.V.), an oxime ester-based photopolymerization initiator (product name: Lunar 6, DKSH Management Ltd.), 2,2′-bis(2-chlorophenyl)-4,4′,5,5′-tetraphenylbisimidazole (a 2-(2-chlorophenyl)-4,5-diphenylimidazole dimer (product name: B-CIM, manufactured by Hampford Research Inc.), and a 2-(o-chlorophenyl)-4,5-diphenylimidazole dimer (product name: BCTB, manufactured by Tokyo Kasei Kogyo Co., Ltd.).

The photocationic polymerization initiator (a photoacid generator) is a compound that generates an acid by receiving an actinic ray. The photocationic polymerization initiator is preferably a compound which becomes sensitive to an actinic ray having a wavelength of 300 nm or more, preferably 300 to 450 nm, and generates an acid; however, the chemical structure thereof is not limited. A photocationic polymerization initiator which does not directly become sensitive to an actinic ray having a wavelength of 300 nm or more can also be preferably used in combination with a sensitizing agent as long as it is a compound which becomes sensitive to an actinic ray having a wavelength of 300 nm or more and then generates an acid by being used in combination with the sensitizing agent.

The photocationic polymerization initiator is preferably a photocationic polymerization initiator that generates an acid having a pKa of 4 or less, more preferably a photocationic polymerization initiator that generates an acid having a pKa of 3 or less, and particularly preferably a photocationic polymerization initiator that generates an acid having a pKa of 2 or less. The lower limit of pKa is not particularly defined; however, it is, for example, preferably −10.0 or more.

Examples of the photocationic polymerization initiator include an ionic photocationic polymerization initiator and a nonionic photocationic polymerization initiator.

Examples of the ionic photocationic polymerization initiator include onium salt compounds such as diaryliodonium salts and triarylsulfonium salts, and quaternary ammonium salts.

As the ionic photocationic polymerization initiator, the ionic photocationic polymerization initiators described in paragraphs 0114 to 0133 of JP2014-85643A may be used.

Examples of the nonionic photocationic polymerization initiator include trichloromethyl-s-triazines, diazomethane compounds, imide sulfonate compounds, and oxime sulfonate compounds. As the trichloromethyl-s-triazines, the diazomethane compounds, and the imide sulfonate compounds, the compounds described in paragraphs 0083 to 0088 of JP2011-221494A may be used. Further, as the oxime sulfonate compound, the compounds described in paragraphs 0084 to 0088 of WO2018/179640A may be used.

The negative type photosensitive resin layer may contain one kind of photopolymerization initiator alone or may contain two or more kinds thereof.

The content of the photopolymerization initiator in the negative type photosensitive resin layer is not particularly limited, and it is preferably 0.1% by mass or more, more preferably 0.5% by mass or more, and still more preferably 1.0% by mass or more, with respect to the total mass of the photosensitive resin layer. The upper limit thereof is not particularly limited; however, it is preferably 10% by mass or less and more preferably 5% by mass or less with respect to the total mass of the photosensitive resin layer.

Alkali-Soluble Resin

The negative type photosensitive resin layer preferably contains an alkali-soluble resin.

In the present specification, “alkali-soluble” means that the solubility in 100 g of an aqueous solution of 1% by mass sodium carbonate at a liquid temperature of 22° C. is 0.1 g or more.

The alkali-soluble resin is not particularly limited, and suitable examples thereof include a known alkali-soluble resin that is used in the etching resist.

Further, the alkali-soluble resin is preferably a binder polymer.

The alkali-soluble resin is preferably an alkali-soluble resin having an acid group.

Among the above, the alkali-soluble resin is preferably a polymer A which will be described later.

Polymer A

The alkali-soluble resin preferably contains a polymer A.

The acid value of the polymer A is preferably 220 mgKOH/g or less, more preferably less than 200 mgKOH/g, and still more preferably less than 190 mgKOH/g, from the viewpoint of more excellent resolution by suppressing the swelling of the photosensitive resin layer due to the developer.

The lower limit of the acid value of the polymer A is not particularly limited; however, it is preferably 60 mgKOH/g or more, more preferably 120 mgKOH/g or more, still more preferably 150 mgKOH/g or more, and particularly preferably 170 mgKOH/g or more, from the viewpoint of more excellent developability.

It is noted that the acid value is the mass [mg] of potassium hydroxide required to neutralize 1 g of the sample, and the unit thereof is described as mgKOH/g in the present specification. The acid value can be calculated, for example, from the average content of acid groups in the compound.

The acid value of the polymer A may be adjusted according to the kind of the constitutional unit that constitutes the polymer A and the content of the constitutional unit containing an acid group.

The weight-average molecular weight of the polymer A is preferably 5,000 to 500,000. It is preferable to set the weight-average molecular weight to 500,000 or less from the viewpoint of improving resolution and developability. The weight-average molecular weight is more preferably 100,000 or less, still more preferably 60,000 or less, and particularly preferably 50,000 or less. On the other hand, it is preferable to set the weight-average molecular weight to 5,000 or more from the viewpoint of controlling the properties of the development aggregates and the properties of the unexposed film such as edge fusibility and cut chip property. The weight-average molecular weight is more preferably 10,000 or more, still more preferably 20,000 or more, and particularly preferably 30,000 or more. The edge fusibility refers to a degree of ease with which the photosensitive resin layer protrudes from the edge face of the roll in a case where the photosensitive transfer material is wound backward in a roll shape. The cut chip property refers to a degree of ease of chip flying in a case where the unexposed film is cut with a cutter. In a case where this chip adheres to the upper surface of the photosensitive resin layer or the like, it is transferred to the mask in the later exposure step or the like, which causes a defective product. The dispersity of the polymer A is preferably 1.0 to 6.0, more preferably 1.0 to 5.0, still more preferably 1.0 to 4.0, and even still more preferably 1.0 to 3.0. In the present disclosure, the molecular weight is a value measured by using gel permeation chromatography. In addition, the dispersity is a ratio of the weight-average molecular weight to the number-average molecular weight (weight-average molecular weight/number-average molecular weight).

The negative type photosensitive resin layer preferably contains, as the polymer A, a monomer component having an aromatic hydrocarbon group from the viewpoint of suppressing line width thickening and deterioration of resolution in a case where the focal position has deviated during exposure. Examples of such an aromatic hydrocarbon group include a substituted or unsubstituted phenyl group and a substituted or unsubstituted aralkyl group. The content proportion of the monomer component having an aromatic hydrocarbon group in the polymer A is preferably 20% by mass or more, more preferably 30% by mass or more, still more preferably 40% by mass or more, particularly preferably 45% by mass or more, and most preferably 50% by mass or more, based on the total mass of all the monomer components. The upper limit thereof is not particularly limited; however, it is preferably 95% by mass or less and more preferably 85% by mass or less. It is noted that in a case where a plurality of kinds of the polymer A are contained, the content proportion of the monomer component having an aromatic hydrocarbon group is determined as a weight average value.

Examples of the monomer having an aromatic hydrocarbon group include a monomer having an aralkyl group, styrene, and a polymerizable styrene derivative (for example, methyl styrene, vinyl toluene, tert-butoxy styrene, acetoxy styrene, 4-vinylbenzoic acid, a styrene dimer, or a styrene trimer). Among them, a monomer having an aralkyl group or styrene is preferable. In one aspect, in a case where the monomer component having an aromatic hydrocarbon group in the polymer A is styrene, the content proportion of the styrene monomer component is preferably 20% by mass to 50% by mass, more preferably 25% by mass to 45% by mass, still more preferably 30% by mass to 40% by mass, and particularly preferably 30% by mass to 35% by mass, based on the total mass of all the monomer components.

Examples of the aralkyl group include a substituted or unsubstituted phenylalkyl group (excluding a benzyl group) and a substituted or unsubstituted benzyl group, where a substituted or unsubstituted benzyl group is preferable.

Examples of the monomer having a phenylalkyl group include phenylethyl (meth)acrylate.

Examples of the monomer having a benzyl group include (meth)acrylate having a benzyl group, for example, benzyl (meth)acrylate or chlorobenzyl (meth)acrylate; and a vinyl monomer having a benzyl group, for example, vinylbenzyl chloride or vinylbenzyl alcohol. Among them, benzyl (meth)acrylate is preferable. In one aspect, in a case where the monomer component having an aromatic hydrocarbon group in the polymer A is benzyl (meth)acrylate, the content proportion of the benzyl (meth)acrylate monomer component is preferably 50% by mass to 95% by mass, more preferably 60% by mass to 90% by mass, still more preferably 70% by mass to 90% by mass, and particularly preferably 75% by mass to 90% by mass, based on the total mass of all the monomer components.

The polymer A containing a monomer component having an aromatic hydrocarbon group is preferably obtained by polymerizing a monomer having an aromatic hydrocarbon group with at least one kind of the first monomer described below and/or at least one kind of the second monomer described below.

The polymer A containing no monomer component but having an aromatic hydrocarbon group is preferably obtained by polymerizing at least one kind of the first monomers described later, and more preferably obtained by copolymerizing at least one kind of the first monomer and at least one kind of the second monomer described later.

The first monomer is a monomer having a carboxy group in the molecule. Examples of the first monomer include (meth)acrylic acid, fumaric acid, cinnamic acid, crotonic acid, itaconic acid, 4-vinylbenzoic acid, a maleic acid anhydride, and a maleic acid semi-ester. Among these, (meth)acrylic acid is preferable.

The content proportion of the first monomer in the polymer A is preferably 5% by mass to 50% by mass, preferably 10% by mass to 40% by mass, and still more preferably 15% by mass to 30% by mass, based on the total mass of all the monomer components.

The copolymerization proportion of the first monomer is preferably 10% by mass to 50% by mass based on the total mass of all the monomer components. It is preferable to set the copolymerization proportion to 10% by mass or more from the viewpoint of exhibiting good developability and the viewpoint of controlling edge fusibility, and it is more preferably 15% by mass or more and still more preferably 20% by mass or more. It is preferable to set the copolymerization proportion to 50% by mass or less from the viewpoint of the high resolution and the edge shape of the resist pattern as well as from the viewpoint of the chemical resistance of the resist pattern, and in terms of these viewpoints, it is more preferably 35% by mass or less, still more preferably 30% by mass or less, and particularly preferably 27% by mass or less.

The second monomer is a monomer that is non-acidic and has at least one polymerizable unsaturated group in the molecule. Examples of the second monomer include (meth)acrylate such as methyl (meth)acrylate, ethyl (meth)acrylate, n-propyl (meth)acrylate, isopropyl (meth)acrylate, n-butyl (meth)acrylate, isobutyl (meth)acrylate, tert-butyl (meth)acrylate, 2-hydroxyethyl (meth)acrylate, 2-hydroxypropyl (meth)acrylate, cyclohexyl (meth)acrylate, 2-ethylhexyl (meth)acrylate; esters of vinyl alcohols such as vinyl acetate; and (meth)acrylonitriles. Among them, methyl (meth)acrylate, 2-ethylhexyl (meth)acrylate, or n-butyl (meth)acrylate is preferable, and methyl (meth)acrylate is particularly preferable.

The content proportion of the second monomer in the polymer A is preferably 5% by mass to 60% by mass, preferably 15% by mass to 50% by mass, and still more preferably 20% by mass to 45% by mass, based on the total mass of all the monomer components.

It is preferable to contain a monomer having an aralkyl group and/or styrene as a monomer from the viewpoint of suppressing line width thickening and deterioration of resolution in a case where the focal position has deviated during exposure. For example, a copolymer containing methacrylic acid, benzyl methacrylate, and styrene, a copolymer containing methacrylic acid, methyl methacrylate, benzyl methacrylate, and styrene, or the like is preferable.

In one aspect, the polymer A is preferably a polymer containing 25% by mass to 40% by mass of a monomer component having an aromatic hydrocarbon group, 20% by mass to 35% by mass of the first monomer component, and 30% by mass to 45% by mass of the second monomer component. Further, in another aspect, it is preferably a polymer containing 70% by mass to 90% by mass of a monomer component having an aromatic hydrocarbon group and 10% by mass to 25% by mass of the first monomer component.

The polymer A may have any structure of a linear structure, a branched structure, or an alicyclic structure in the side chain. In a case where a monomer containing a group having a branched structure in the side chain or a monomer containing a group having an alicyclic structure in the side chain is used, it is possible to introduce a branched structure or an alicyclic structure into the side chain of polymer A. The group having an alicyclic structure may be a monocyclic ring or a polycyclic ring.

Specific examples of the monomer containing a group having a branched structure in the side chain include i-propyl (meth)acrylate, i-butyl (meth)acrylate, s-butyl (meth)acrylate, t-butyl (meth)acrylate, i-amyl (meth)acrylate, t-amyl (meth)acrylate, iso-amyl (meth)acrylate, 2-octyl (meth)acrylate, 3-octyl (meth)acrylate, and t-octyl (meth)acrylate. Among these, i-propyl (meth)acrylate, i-butyl (meth)acrylate, or t-butyl methacrylate is preferable, and i-propyl methacrylate or t-butyl methacrylate is more preferable.

Examples of the monomer containing a group having an alicyclic structure in the side chain include a monomer having a monocyclic aliphatic hydrocarbon group and a monomer having a polycyclic aliphatic hydrocarbon group, which include (meth)acrylates having an alicyclic hydrocarbon group having 5 to 20 carbon atoms. More specific examples thereof include (bicyclo[2.2.1]heptyl-2) (meth)acrylate, 1-adamantyl (meth)acrylate, 2-adamantyl (meth)acrylate, 3-methyl-1-adamantyl (meth)acrylate, 3,5-dimethyl-1-adamantyl (meth)acrylate, 3-ethyladamantyl (meth)acrylate, 3-methyl-5-ethyl-1-adamantyl (meth)acrylate, 3,5,8-triethyl-1-adamantyl (meth)acrylate, 3,5-dimethyl-8-ethyl-1-adamantyl (meth)acrylate, 2-methyl-2-adamantyl (meth)acrylate, 2-ethyl-2-adamantyl (meth)acrylate, 3-hydroxy-1-adamantyl (meth)acrylate, octahydro-4,7-menthanoinden-5-yl (meth)acrylate, octahydro-4,7-menthanoinden-1-ylmethyl (meth)acrylate, 1-menthyl (meth)acrylate, tricyclodecane (meth)acrylate, 3-hydroxy-2,6,6-trimethyl-bicyclo[3.1.1]heptyl (meth)acrylate, 3,7,7-trimethyl-4-hydroxybicyclo[4.1.0]heptyl (meth)acrylate, (nor)bornyl (meth)acrylate, isobornyl (meth)acrylate, fenchyl (meth)acrylate, 2,2,5-trimethylcyclohexyl (meth)acrylate, and cyclohexyl (meth)acrylate. Among these (meth)acrylate esters, cyclohexyl (meth)acrylate (nor)bornyl (meth)acrylate, isobornyl (meth)acrylate, 1-adamantyl (meth)acrylate, 2-adamantyl (meth)acrylate, fenchyl (meth)acrylate, 1-menthyl (meth)acrylate, or tricyclodecane (meth)acrylate is preferable, and cyclohexyl (meth)acrylate, (nor)bornyl (meth)acrylate, isobornyl (meth)acrylate, 2-adamantyl (meth)acrylate, or tricyclodecane (meth)acrylate is particularly preferable.

The polymer A can be used alone, or two or more thereof may be mixed and used. In a case where two or more kinds are mixed and used, it is preferable that two kinds of the polymer A containing a monomer component having an aromatic hydrocarbon group are mixed and used, or it is preferable that the polymer A containing a monomer component having an aromatic hydrocarbon group and the polymer A containing no monomer component having an aromatic hydrocarbon group are mixed and used. In the latter case, the using proportion of the polymer A containing a monomer component having an aromatic hydrocarbon group is preferably 50% by mass or more, more preferably 70% by mass or more, still more preferably 80% by mass or more, and even still more preferably 90% by mass or more, with respect to the total amount of the polymer A.

The synthesis of the polymer A is preferably carried out by adding an appropriate amount of a radical polymerization initiator such as benzoyl peroxide or azoisobutyronitrile to a solution obtained by diluting the one or more monomers described above with a solvent such as acetone, methyl ethyl ketone, or isopropanol, and then stirring and heating the resultant mixture. In some cases, the synthesis is carried out while a part of the mixture is added dropwise to the reaction solution. After completion of the reaction, a solvent may be further added to adjust the concentration to a desired level. As the synthesis means, bulk polymerization, suspension polymerization, or emulsion polymerization may be used in addition to the solution polymerization.

The glass transition temperature Tg of the polymer A is preferably 30° C. or higher and 135° C. or lower. In a case where the polymer A having a Tg of 135° C. or lower is used in the photosensitive resin layer, it is possible to suppress line width thickening and deterioration of resolution in a case where the focal position has deviated during exposure. From this viewpoint, the Tg of the polymer A is more preferably 130° C. or lower, still more preferably 120° C. or lower, and particularly preferably 110° C. or lower. Further, it is preferable to use the polymer A having a Tg of 30° C. or higher from the viewpoint of improving the edge fusibility resistance. From this viewpoint, the Tg of the polymer A is more preferably 40° C. or higher, still more preferably 50° C. or higher, particularly preferably 60° C. or higher, and most preferably 70° C. or higher.

The negative type photosensitive resin layer may contain a resin other than the alkali-soluble resin.

Examples of the resin other than the alkali-soluble resin include an acrylic resin, a styrene-acrylic copolymer (however, the styrene content is 40% by mass or less), a polyurethane resin, polyvinyl alcohol, polyvinyl formal, a polyamide resin, a polyester resin, an epoxy resin, a polyacetal resin, a polyhydroxystyrene resin, a polyimide resin, a polybenzoxazole resin, a polysiloxane resin, a polyethyleneimine, a polyallylamine, and a polyalkylene glycol.

The alkali-soluble resin can be used alone, or two or more thereof may be mixed and used.

The proportion of the alkali-soluble resin with respect to the total mass of the negative type photosensitive resin layer is preferably in a range of 10% by mass to 90% by mass, more preferably in a range of 30% by mass to 70% by mass, and still more preferably in a range of 40% by mass to 60% by mass. From the viewpoint of controlling the developing time, it is preferable to set the proportion of the alkali-soluble resin to 90% by mass or less with respect to the negative type photosensitive resin layer. On the other hand, from the viewpoint of improving edge fusibility resistance, it is preferable to set the proportion of the alkali-soluble resin to 10% by mass or more with respect to the negative type photosensitive resin layer.

Compound Having Unshared Electron Pair

The photosensitive resin layer preferably contains a compound having an unshared electron pair from the viewpoint of the adhesiveness to the conductive layer.

From the viewpoint of the adhesiveness to the conductive layer, the compound having an unshared electron pair is preferably a compound having at least a nitrogen atom, an oxygen atom, or a sulfur atom, more preferably a heterocyclic compound, a thiol compound, or a disulfide compound, still more preferably a heterocyclic compound, and particularly preferably a nitrogen-containing heterocyclic compound.

Preferred examples of the compound having an unshared electron pair include the compounds exemplified in the above-described compound e.

The photosensitive resin layer may contain one kind of compound having an unshared electron pair alone, or may contain two or more kinds of thereof.

From the viewpoint of adhesiveness to the conductive layer, the content of the compound having an unshared electron pair is preferably 0.01% by mass to 20% by mass, more preferably 0.1% by mass to 10% by mass, still more preferably 0.3% by mass to 8% by mass, and particularly preferably 0.5% by mass to 5% by mass, with respect to the total mass of the photosensitive resin layer.

Dye

From the viewpoints of visibility of the exposed portion and the non-exposed portion, the pattern visibility after development, and the resolution, the photosensitive resin layer preferably contains a dye and more preferably contains a dye (also referred to simply as a “dye N”) that has a maximum absorption wavelength of 450 nm or more in a wavelength range of 400 nm to 780 nm at the time of color development, where the maximum absorption wavelength is changed by an acid, a base, or a radical. In a case where the dye N is contained, the adhesiveness to the adjacent layer (for example, the temporary support and the substrate) is improved, and thus the resolution is more excellent although the detailed mechanism is unknown.

In the present specification, the description that “the maximum absorption wavelength of the dye is changed by an acid, a base, or a radical” may mean any one of an aspect in which a dye in a colored state is decolorized by an acid, a base, or a radical, as aspect in which a dye in a decolorized state develops a color by an acid, a base, or a radical, or an aspect in which a dye in a colored state changes to a colored state of another color tone.

Specifically, the dye N may be a compound that changes from the decolorized state to develop a color upon exposure or may be a compound that changes from the colored state to be decolorized upon exposure. In this case, it may be a dye of which the color developing state or decolorized state changes by an action of an acid, a base, or a radical, which is generated upon exposure in the photosensitive resin layer, or it may be a dye of which the color developing state or decolorized state changes due to a change in the state (for example, pH) of the inside of the photosensitive resin layer, the change being caused by an acid, a base, or a radical. Further, it may be a dye of which the color developing state or decolorized state changes by directly receiving an acid, a base, or a radical as a stimulus without undergoing exposure.

Among the above, the dye N is preferably a dye of which the maximum absorption wavelength is changed by an acid or a radical, and more preferably a dye of which the maximum absorption wavelength is changed by a radical, from the viewpoints of the visibility of the exposed portion and the non-exposed portion and the resolution.

The photosensitive resin layer preferably contains both a dye of which the maximum absorption wavelength is changed by a radical as the dye N and a photoradical polymerization initiator from the viewpoints of the visibility of the exposed portion and the non-exposed portion and the resolution.

Further, from the viewpoint of the visibility of the exposed portion and the non-exposed portion, the dye N is preferably a dye that develops color by an acid, a base, or a radical.

Examples of the color development mechanism of the dye N in the present disclosure include an aspect in which a photoradical polymerization initiator, a photocationic polymerization initiator (a photoacid generator), or a photobase generator is added to the photosensitive resin layer so that a radical-reactive dye, an acid-reactive dye, or a base-reactive dye (for example, a leuco dye) develops a color by a radical, an acid, or a base, which is generated after exposure from the photoradical polymerization initiator, the photocationic polymerization initiator, or the photobase generator.

From the viewpoint of the visibility of the exposed portion and the non-exposed portion, the dye N preferably has a maximum absorption wavelength of 550 nm or more, more preferably 550 nm to 700 nm, and still more preferably 550 nm to 650 nm, in a wavelength range of 400 nm to 780 nm at the time of color development.

The maximum absorption wavelength of the dye N is obtained by measuring a transmission spectrum of a solution (solution temperature: 25° C.) containing the dye N in a range of 400 nm to 780 nm using a spectrophotometer: UV3100 (manufactured by Shimadzu Corporation) in an atmospheric air and detecting a wavelength (a maximum absorption wavelength) at which the intensity of light is minimized in the above wavelength range.

Examples of the dye that develops a color or is decolorized under exposure include a leuco compound.

Examples of the dye that is decolorized under exposure include a leuco compound, a diarylmethane-based dye, an oxazine-based dye, a xanthene-based dye, an iminonaphthoquinone-based dye, an azomethine-based dye, and an anthraquinone-based dye.

From the viewpoint of the visibility of the exposed portion and the non-exposed portion, the dye N is preferably a leuco compound.

Examples of the leuco compound include a leuco compound having a triarylmethane skeleton (a triarylmethane-based dye), a leuco compound having a spiropyran skeleton (a spiropyran-based dye), a leuco compound having a fluoran skeleton (a fluoran-based dye), a leuco compound having a diarylmethane skeleton (a diarylmethane-based dye), a leuco compound having a rhodamine lactam skeleton (a rhodamine lactam-based dye), a leuco compound having an indolyl phthalide skeleton (an indolyl phthalide-based dye), and a leuco compound having a leuco auramine skeleton (a leuco auramine-based dye).

Among them, a triarylmethane-based dye or a fluoran-based dye is preferable, and a leuco compound having a triphenylmethane skeleton (a triphenylmethane-based dye) or a fluoran-based dye is more preferable.

From the viewpoint of the visibility of the exposed portion and the non-exposed portion, the leuco compound preferably has a lactone ring, a sultine ring, or a sultone ring. As a result, the lactone ring, the sultine ring, or the sultone ring contained in the leuco compound is reacted with a radical generated from the photoradical polymerization initiator or an acid generated from the photocationic polymerization initiator to change the leuco compound into a closed ring state, thereby being decolorized, or change the leuco compound to an open ring state, whereby a color is developed. It is preferable that the leuco compound is a compound having a lactone ring, a sultine ring, or a sultone ring, where the lactone ring, the sultine ring, or the sultone ring is opened by a radical or an acid to develop a color, and it is more preferable that it is a compound having a lactone ring, where the lactone ring is opened by a radical or an acid to develop a color.

Examples of the dye N include the following dyes and leuco compounds.

Among dyes N, specific examples of the dye include Brilliant green, Ethyl violet, Methyl green, Crystal violet, Basic fuchsine, Methyl violet 2B, Quinaldine red, Rose bengal, Metanil yellow, thymol sulfonphthalein, Xylenol blue, Methyl orange, Paramethyl red, Congo red, Benzopurpurine 4B, α-Naphthyl red, Nile blue 2B, Nile blue A, Methyl violet, Malachite green, Parafuchsine, Victoria pure blue-naphthalene sulfonate, Victoria pure blue BOH (manufactured by HODOGAYA CHEMICAL CO., LTD.), Oil blue #603 (manufactured by ORIENT CHEMICAL INDUSTRIES CO., LTD.), Oil pink #312 (manufactured by ORIENT CHEMICAL INDUSTRIES CO., LTD.), Oil red 5B (manufactured by ORIENT CHEMICAL INDUSTRIES CO., LTD.), Oil scarlet #308 (manufactured by ORIENT CHEMICAL INDUSTRIES CO., LTD.), Oil red OG (manufactured by ORIENT CHEMICAL INDUSTRIES CO., LTD.), Oil red RR (manufactured by ORIENT CHEMICAL INDUSTRIES CO., LTD.), Oil green #502 (manufactured by ORIENT CHEMICAL INDUSTRIES CO., LTD.), Spiron red BEH special (manufactured by HODOGAYA CHEMICAL CO., LTD.), m-Cresol purple, Cresol red, rhodamine B, rhodamine 6G, sulforhodamine B, auramine, 4-p-diethylaminophenyliminonaphthoquinone, 2-carboxyanilino-4-p-diethylaminophenyliminonaphthoquinone, 2-carboxystearylamino-4-p-N,N-bis(hydroxyethyl) amino-phenyliminonaphthoquinone, 1-phenyl-3-methyl-4-p-diethylaminophenylimino-5-pyrazolone, and 1-β-naphthyl-4-p-diethylaminophenylimino-5-pyrazolone.

Among the dyes N, specific examples of the leuco compound include p,p′,p″-hexamethyltriaminotriphenylmethane (Leuco crystal violet), Pergascript blue SRB (manufactured by Ciba-Geigy AG), Crystal violet lactone, malachite green lactone, benzoyl leucomethylene blue, 2-(N-phenyl-N-methylamino)-6-(N-p-tolyl-N-ethyl) aminofluoran, 2-anilino-3-methyl-6-(N-ethyl-p)-toluidino) fluoran, 3,6-dimethoxyfluoran, 3-(N,N-diethylamino)-5-methyl-7-(N,N-dibenzylamino) fluoran, 3-(N-cyclohexyl-N-methyl)amino)-6-methyl-7-anilinofluoran, 3-(N,N-diethylamino)-6-methyl-7-anilinofluoran, 3-(N,N-diethylamino)-6-methyl-7-xylidinofluoran, 3-(N,N-diethylamino)-6-methyl-7-chlorofluoran, 3-(N,N-diethylamino)-6-methoxy-7-aminofluoran, 3-(N,N-diethylamino)-7-(4-chloroanilino) fluoran, 3-(N,N-diethylamino)-7-chlorofluoran, 3-(N,N-diethylamino)-7-benzylaminofluoran, 3-(N,N-diethylamino)-7,8-benzofluoran, 3-(N,N-dibutylamino)-6-methyl-7-anilinofluoran, 3-(N,N-dibutylamino)-6-methyl-7-xylidinofluoran, 3-piperidino-6-methyl-7-anilinofluoran, 3-pyrrolidino-6-methyl-7-anilinofluoran, 3,3-bis(1-ethyl-2-methylindole-3-yl)phthalide, 3,3-bis(1-n-butyl-2-methylindole-3-yl)phthalide, 3,3-bis(p-dimethylaminophenyl)-6-dimethylaminophthalide, 3-(4-diethylamino-2-ethoxyphenyl)-3-(1-ethyl-2-methylindole-3-yl)-4-azaphthalide, 3-(4-diethylaminophenyl)-3-(1-ethyl-2-methylindole-3-yl)phthalide, and 3′,6′-bis(diphenylamino)spiroisobenzofuran-1 (3H),9′-[9H]xanthene-3-one.

From the viewpoints of visibility of the exposed portion and the non-exposed portion, the pattern visibility after development, and the resolution, the dye N is preferably a dye of which the maximum absorption wavelength is changed by a radical, and more preferably a dye that develops a color by a radical.

The dye N is preferably leuco crystal violet, crystal violet lactone, brilliant green, or Victoria pure blue-naphthalene sulfonate.

One kind of dye may be used alone, or two or more kinds thereof may be used.

From the viewpoints of visibility of the exposed portion and the non-exposed portion, the pattern visibility after development, and the resolution, the content of the dye is preferably 0.1% by mass or more, more preferably 0.1% by mass to 10% by mass, still more preferably 0.1% by mass to 5% by mass, and particularly preferably 0.1% by mass to 1% by mass, with respect to the total mass of the photosensitive resin layer.

In addition, from the viewpoints of visibility of the exposed portion and the non-exposed portion, the pattern visibility after development, and the resolution, the content of the dye N is preferably 0.1% by mass or more, more preferably 0.1% by mass to 10% by mass, still more preferably 0.1% by mass to 5% by mass, and particularly preferably 0.1% by mass to 1% by mass, with respect to the total mass of the photosensitive resin layer.

The content of the dye N means the content of the dye in a case where the whole dye N contained in the photosensitive resin layer is in a colored state. Hereinafter, a method of quantifying the content of the dye N will be described by taking a dye that develops color by a radical as an example.

Two kinds of dye solutions obtained by respectively dissolving 0.001 g and 0.01 g in 100 mL of methyl ethyl ketone are prepared. A photoradical polymerization initiator Irgacure OXE01 (product name, BASF Japan Ltd.) is added to each of the obtained solutions, and radicals are generated by the irradiation with light of 365 nm to bring the whole dye into a colored state. Then, in the atmospheric air, the absorbance of each solution having a liquid temperature of 25° C. is measured using a spectrophotometer (UV3100, manufactured by Shimadzu Corporation), and a calibration curve is created.

Next, the absorbance of the solution in which the whole dye has been caused to develop a color is measured by the same method as the above except that 3 g of the photosensitive resin layer is dissolved in methyl ethyl ketone instead of the dye. From the obtained absorbance of the solution containing the photosensitive resin layer, the content of the dye contained in the photosensitive resin layer is calculated based on the calibration curve.

Thermal Crosslinking Compound

From the viewpoint of the hardness of the cured film to be obtained and the pressure-sensitive adhesiveness of the uncured film to be obtained, the photosensitive resin layer preferably contains a thermal crosslinking compound. In this specification, the thermal crosslinking compound having an ethylenic unsaturated group described later shall be not treated as a polymerizable compound but be treated as a thermal crosslinking compound.

Examples of the thermal crosslinking compound include a methylol compound and a blocked isocyanate compound. Among these, from the viewpoint of the hardness of the cured film to be obtained and the pressure-sensitive adhesiveness of the uncured film to be obtained, a blocked isocyanate compound is preferable.

By the way, the blocked isocyanate compound reacts with a hydroxy group and a carboxy group. As a result, for example, in a case where the resin and/or the polymerizable compound has at least one of a hydroxy group or a carboxy group, a film to be formed has a low hydrophilicity, and thus in a case where a film obtained by curing the photosensitive resin layer is used as a protective film, the function thereof tends to be enhanced.

The blocked isocyanate compound refers to a “compound having a structure in which the isocyanate group of isocyanate is protected (so-called masked) by a blocking agent”.

The dissociation temperature of the blocked isocyanate compound is not particularly limited; however, it is preferably 100° C. to 160° C. and more preferably 130° C. to 150° C.

The dissociation temperature of blocked isocyanate means “temperature at an endothermic peak accompanied with a deprotection reaction of blocked isocyanate, in a case where the measurement is carried out by differential scanning calorimetry (DSC) analysis using a differential scanning calorimeter”.

As the differential scanning calorimeter, for example, a differential scanning calorimeter (model: DSC6200) manufactured by Seiko Instruments Inc. can be suitably used. However, the differential scanning calorimeter is not limited thereto.

Examples of the blocking agent having a dissociation temperature of 100° C. to 160° C. include an active methylene compound [diester malonate (such as dimethyl malonate, diethyl malonate, di-n-butyl malonate, or di-2-ethylhexyl malonate)] and an oxime compound (a compound having a structure represented by —C(═N—OH)— in the molecule, such as formaldoxime, acetoaldoxime, acetoxime, methyl ethyl ketoxime, or cyclohexanoneoxime).

Among these, for example, an oxime compound is preferably contained as the blocking agent having a dissociation temperature of 100° C. to 160° C. from the viewpoint of storage stability.

From the viewpoint of improving brittleness of the film and improving the adhesion force to a transferred material, for example, the blocked isocyanate compound preferably has an isocyanurate structure.

The blocked isocyanate compound having an isocyanurate structure can be obtained, for example, by isocyanurate-forming and protecting hexamethylene diisocyanate.

Among the blocked isocyanate compounds having an isocyanurate structure, a compound having an oxime structure using an oxime compound as a blocking agent is preferable from the viewpoint that the dissociation temperature can be easily set in a preferred range and the development residue can be easily reduced, as compared with a compound having no oxime structure.

The blocked isocyanate compound may have a polymerizable group.

The polymerizable group is not particularly limited, and a known polymerizable group can be used, where a radically polymerizable group is preferable.

Examples of the polymerizable group include a (meth)acryloxy group, a (meth)acrylamide group, an ethylenic unsaturated group such as styryl group, and an epoxy group such as a glycidyl group.

Among them, the polymerizable group is preferably an ethylenic unsaturated group, more preferably a (meth)acryloxy group, and still more preferably an acryloxy group.

As the blocked isocyanate compound, a commercially available product can be used.

Examples of the commercially available blocked isocyanate compound include compounds such as Karenz (registered trade name), AOI-BM, Karenz (registered trade name), MOI-BM, Karenz (registered trade name), and MOI-BP (all manufactured by Showa Denko K.K.); and block type DURANATE series (for example, DURANATE (registered trade name)), TPA-B80E, DURANATE (registered trade name), and WT32-B75P, manufactured by Asahi Kasei Chemicals Co., Ltd.).

Further, as the blocked isocyanate compound, a compound having the following structure can also be used.

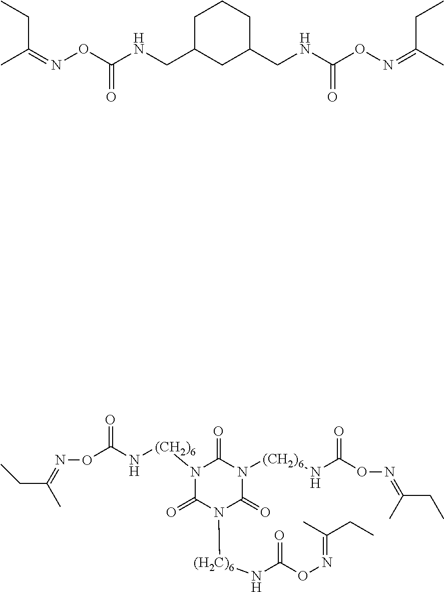

One kind of thermal crosslinking compound may be used alone, or two or more kinds thereof may be used.

In a case where the photosensitive resin layer contains a thermal crosslinking compound, the content of the thermal crosslinking compound is preferably 1% by mass to 50% by mass and more preferably 5% by mass to 30% by mass with respect to the total mass of the photosensitive resin layer.

Polymer having constitutional unit having acid group protected by acid-decomposable group

The positive type photosensitive resin layer preferably contains a polymer (hereinafter, referred to as a “polymer X”) having a constitutional unit (hereinafter, may be referred to as a “constitutional unit A”) having an acid group protected by an acid-decomposable group. The positive type photosensitive resin layer may contain one kind of polymer X alone or may contain two or more kinds of polymers X.

In the polymer X, the acid group protected by the acid-decomposable group is converted into an acid group through a deprotection reaction under the action of a catalytic amount of an acidic substance (for example, an acid) that is generated under exposure. The generation of the acid group in the polymer X increases the solubility of the positive type photosensitive resin layer in the developer.

The polymer X is preferably an addition polymerization type polymer and more preferably a polymer having a constitutional unit derived from (meth)acrylic acid or an ester thereof

Constitutional Unit Having Acid Group Protected by Acid-Decomposable Group

The polymer X preferably has a constitutional unit (a constitutional unit A) having an acid group protected by an acid-decomposable group. In a case where the polymer X has the constitutional unit A, the sensitivity of the positive type photosensitive resin layer can be improved.

The acid group is not limited, and a known acid group can be used. The acid group is preferably a carboxy group or a phenolic hydroxyl group.

Examples of the acid-decomposable group include a group that is relatively easily decomposed by an acid and a group that is relatively difficult to be decomposed by an acid. Examples of the group that is relatively easily decomposed by an acid include acetal-type protective groups (for example, a 1-alkoxyalkyl group, a tetrahydropyranyl group, and a tetrahydrofuranyl group). Examples of the group that is relatively difficult to be decomposed by an acid include a tertiary alkyl group (for example, a tert-butyl group) and a tertiary alkyloxycarbonyl group (for example, a tert-butyloxycarbonyl group). Among them, the acid-decomposable group is preferably an acetal-type protective group.

The molecular weight of the acid-decomposable group is preferably 300 or less from the viewpoint of suppressing the variation in the line width of the resin pattern.

From the viewpoint of sensitivity and resolution, the constitutional unit A is preferably a constitutional unit represented by the following formula A1, a constitutional unit represented by the following formula A2, or a constitutional unit represented by the following formula A3, and it is more preferably a constitutional unit represented by the formula A3. The constitutional unit represented by the formula A3 is a constitutional unit having a carboxy group protected by an acetal-type acid-decomposable group.

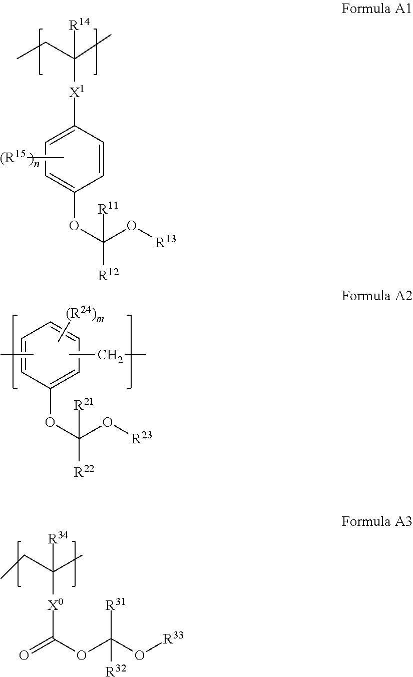

In the formula A1, R¹¹ and R¹² each independently represent a hydrogen atom, an alkyl group, or an aryl group, at least one of R¹¹ or R¹² is an alkyl group or an aryl group, R¹³ represents an alkyl group or an aryl group, R¹¹ or R¹² may be linked to R¹³ to form a cyclic ether, R¹⁴ represents a hydrogen atom or a methyl group, X¹ represents a single bond or a divalent linking group, R¹⁵ represent a substituent, and n represents an integer of 0 to 4.

In the formula A2, R²¹ and R²² each independently represent a hydrogen atom, an alkyl group, or an aryl group, at least one of R²¹ or R²² is an alkyl group or an aryl group, R²³ represents an alkyl group or an aryl group, R²¹ or R²² may be linked to R²³ to form a cyclic ether, R²⁴'s each independently represent a hydroxy group, a halogen atom, an alkyl group, an alkoxy group, an alkenyl group, an aryl group, an aralkyl group, an alkoxycarbonyl group, a hydroxyalkyl group, an arylcarbonyl group, an aryloxycarbonyl group, or a cycloalkyl group, and m represents an integer of 0 to 3.

In the formula A3, R³¹ and R³² each independently represent a hydrogen atom, an alkyl group, or an aryl group, at least one of R³¹ or R³² is an alkyl group or an aryl group, R³³ represents an alkyl group or an aryl group, R³¹ or R³² may be linked to R³³ to form a cyclic ether, R³⁴ represents a hydrogen atom or a methyl group, and X⁰ represents a single bond or an arylene group.

In the formula A3, in a case where R³¹ or R³² is an alkyl group, it is preferably an alkyl group having 1 to 10 carbon atoms.

In the formula A3, in a case where R³¹ or R³² is an aryl group, it is preferably a phenyl group.

In the formula A3, it is preferable that R³¹ and R³² are each independently a hydrogen atom or an alkyl group having 1 to 4 carbon atoms.

In the formula A3, R³³ is preferably an alkyl group having 1 to 10 carbon atoms and more preferably an alkyl group having 1 to 6 carbon atoms.

In the formula A3, the alkyl group and the aryl group represented by R³¹ to R³³ may have a substituent.

In the formula A3, it is preferable that R³¹ or R³² is linked to R³³ to form a cyclic ether. The number of ring members of the cyclic ether is preferably 5 or 6, and more preferably 5.

In the formula A3, X° is preferably a single bond. The arylene group may have a substituent.

In the formula A3, R³⁴ is preferably a hydrogen atom from the viewpoint that the glass transition temperature (Tg) of the polymer X can be further decreased.

The content of the constitutional unit in which R³⁴ in the formula A3 is a hydrogen atom is preferably 20% by mass or more with respect to the total mass of the constitutional unit A contained in the polymer X. The content of the constitutional unit in the constitutional unit A in which R³⁴ in the formula A3 is a hydrogen atom can be checked by the intensity ratio of the peak intensity calculated from the ¹³C-nuclear magnetic resonance spectrum (NMR) measurement by a conventional method.

As the preferred aspects of the formulae A1 to A3, paragraph 0044 to paragraph 0058 of WO2018/179640A can be referred to.

From the viewpoint of sensitivity, in the formulae A1 to A3, the acid-decomposable group is preferably a group having a cyclic structure, more preferably a group having a tetrahydrofuran ring structure or a tetrahydropyran ring structure, still more preferably a tetrahydrofuran ring structure, and particularly preferably a group having a tetrahydrofuranyl group.

The polymer X may have one kind of constitutional unit A alone or may have two or more kinds of constitutional units A.

The content of the constitutional unit A is preferably 10% by mass to 70% by mass, more preferably 15% by mass to 50% by mass, and particularly preferably 20% by mass to 40% by mass, with respect to the total mass of the polymer X. In a case where the content of the constitutional unit A is within the above range, the resolution is further improved. In a case where the polymer X contains two or more kinds of constitutional units A, the content of the above-described constitutional unit A shall indicate the total content of the two or more kinds of constitutional units A. The content of the constitutional unit A can be checked by the intensity ratio of the peak intensity calculated from the ¹³C-NMR measurement by a conventional method.

Constitutional Unit Having Acid Group

The polymer X may have a constitutional unit having an acid group (hereinafter, may be referred to as a “constitutional unit B”).

The constitutional unit B is an acid group that is not protected by an acid-decomposable group, that is, a constitutional unit having an acid group having no protective group. In a case where the polymer X has the constitutional unit B, the sensitivity at the time of pattern formation becomes good. In addition, since it becomes easily dissolved in an alkaline developer in the development step after exposure, the developing time can be shortened.

The acid group in the constitutional unit B means a proton dissociative group having a pKa of 12 or less. The pKa of the acid group is preferably 10 or less and more preferably 6 or less from the viewpoint of improving sensitivity. In addition, the pKa of the acid group is preferably −5 or more.

Examples of the acid group include a carboxy group, a sulfonamide group, a phosphonic acid group, a sulfo group, a phenolic hydroxyl group, and a sulfonylimide group. The acid group is preferably a carboxy group or a phenolic hydroxyl group, and more preferably a carboxy group.

The polymer X may have one kind of constitutional unit B alone or may have two or more kinds of constitutional units B.

The content of the constitutional unit B is preferably 0.01% by mass to 20% by mass, more preferably 0.01% by mass to 10% by mass, and particularly preferably 0.1% by mass to 5% by mass, with respect to the total mass of the polymer X. In a case where the content of the constitutional unit B is within the above range, the resolution becomes better. In a case where the polymer X has two or more kinds of constitutional units B, the content of the above-described constitutional unit B shall indicate the total content of the two or more kinds of constitutional units B. The content of the constitutional unit B can be checked by the intensity ratio of the peak intensity calculated from the ¹³C-NMR measurement by a conventional method.

Another Constitutional Unit

It is preferable that the polymer X has a constitutional unit (hereinafter, may be referred to as a “constitutional unit C”) other than the constitutional unit A and the constitutional unit B described above. Various properties of the polymer X can be adjusted by preparing at least one of the kind or the content of the constitutional unit C. In a case where the polymer X has the constitutional unit C, the glass transition temperature, the acid value, and the hydrophobicity of the polymer X can be easily adjusted.

Examples of the monomer that forms the constitutional unit C include styrenes, a (meth)acrylic acid alkyl ester, a (meth)acrylic acid cyclic alkyl ester, a (meth)acrylic acid aryl ester, an unsaturated dicarboxylic acid diester, a bicyclic unsaturated compound, a maleimide compound, an unsaturated aromatic compound, a conjugated diene compound, an unsaturated monocarboxylic acid, an unsaturated dicarboxylic acid, and an unsaturated dicarboxylic acid anhydride.

From the viewpoint of the adhesiveness to the substrate, the monomer that forms the constitutional unit C is preferably a (meth)acrylic acid alkyl ester and more preferably a (meth)acrylic acid alkyl ester having an alkyl group having 4 to 12 carbon atoms.

Examples of the (meth)acrylic acid alkyl ester include methyl (meth)acrylate, ethyl (meth)acrylate, propyl (meth)acrylate, n-butyl (meth)acrylate, and 2-ethylhexyl (meth)acrylate.

Examples of the constitutional unit C include a constitutional unit derived from styrene, α-methylstyrene, acetoxystyrene, methoxystyrene, ethoxystyrene, chlorostyrene, methyl vinylbenzoate, ethyl vinylbenzoate, methyl (meth)acrylate, ethyl (meth)acrylate, n-propyl (meth)acrylate, isopropyl (meth)acrylate, n-butyl (meth)acrylate, 2-ethylhexyl (meth)acrylate, 2-hydroxyethyl (meth)acrylate, 2-hydroxypropyl (meth)acrylate benzyl (meth)acrylate, cyclopentyl (meth)acrylate, cyclohexyl (meth)acrylate, isobornyl (meth)acrylate, acrylonitrile, or ethylene glycol monoacetoacetate mono(meth)acrylate. Examples of the constitutional unit C include constitutional units derived from the compounds described in paragraph 0021 to paragraph 0024 of JP2004-264623A.

From the viewpoint of resolution, the constitutional unit C preferably contains a constitutional unit having a basic group. Examples of the basic group include a group having a nitrogen atom. Examples of the group having a nitrogen atom include an aliphatic amino group, an aromatic amino group, and a nitrogen-containing heteroaromatic ring group. The basic group is preferably an aliphatic amino group.

The aliphatic amino group may be any one of a primary amino group, a secondary amino group, or a tertiary amino group; however, it is preferably a secondary amino group or a tertiary amino group from the viewpoint of resolution.

Examples of the monomer that forms a constitutional unit having a basic group include 1,2,2,6,6-pentamethyl-4-piperidyl methacrylate, 2-(dimethylamino)ethyl methacrylate, 2,2,6,6-tetramethyl-4-piperidyl acrylate, 2,2,6,6-tetramethyl-4-piperidyl methacrylate, 2,2,6,6-tetramethyl-4-piperidyl acrylate, 2-(diethylamino)ethyl methacrylate, 2-(diethylamino)ethyl acrylate, 2-(diethylamino)ethyl acrylate, N-(3-dimethylamino)propyl methacrylate, N-(3-dimethylamino)propyl acrylate, N-(3-diethylamino)propyl methacrylate, N-(3-diethylamino)propyl acrylate, 2-(diisopropylamino)ethyl methacrylate, 2-morpholinoethyl methacrylate, 2-morpholinoethyl acrylate, N-[3-(dimethyl)amino)propyl]acrylamide, 4-aminostyrene, 4-vinylpyridine, 2-vinylpyridine, 3-vinylpyridine, 1-vinylimidazole, 2-methyl-1-vinylimidazole, 1-allylimidazole, and 1-vinyl-1,2,4-triazole. Among them, 1,2,2,6,6-pentamethyl-4-piperidyl methacrylate is preferable.

Further, the constitutional unit C is preferably a constitutional unit having an aromatic ring or a constitutional unit having an aliphatic cyclic skeleton from the viewpoint of improving electrical characteristics. Examples of the monomers that form these constitutional units include styrene, α-methylstyrene, dicyclopentanyl (meth)acrylate, cyclopentyl (meth)acrylate, cyclohexyl (meth)acrylate, isobornyl (meth)acrylate, and benzyl (meth)acrylate. Among the above, cyclohexyl (meth)acrylate is preferable.

The polymer X may have one kind of constitutional unit C alone or may have two or more kinds of constitutional units C.

The content of the constitutional unit C is preferably 90% by mass or less, more preferably 85% by mass or less, and particularly preferably 80% by mass or less, with respect to the total mass of the polymer X. The content of the constitutional unit C is preferably 10% by mass or more and more preferably 20% by mass or more with respect to the total mass of the polymer X. In a case where the content of the constitutional unit C is within the above range, the resolution and the adhesiveness to the substrate are further improved. In a case where the polymer X has two or more kinds of constitutional units C, the content of the above-described constitutional unit C shall indicate the total content of the two or more kinds of constitutional units C. The content of the constitutional unit C can be checked by the intensity ratio of the peak intensity calculated from the ¹³C-NMR measurement by a conventional method.

Preferred examples of the polymer X are described below. However, the polymer X is not limited to the following examples. The ratio and the weight-average molecular weight of each constitutional unit in the polymer X shown below are appropriately selected in order to obtain preferred physical properties.

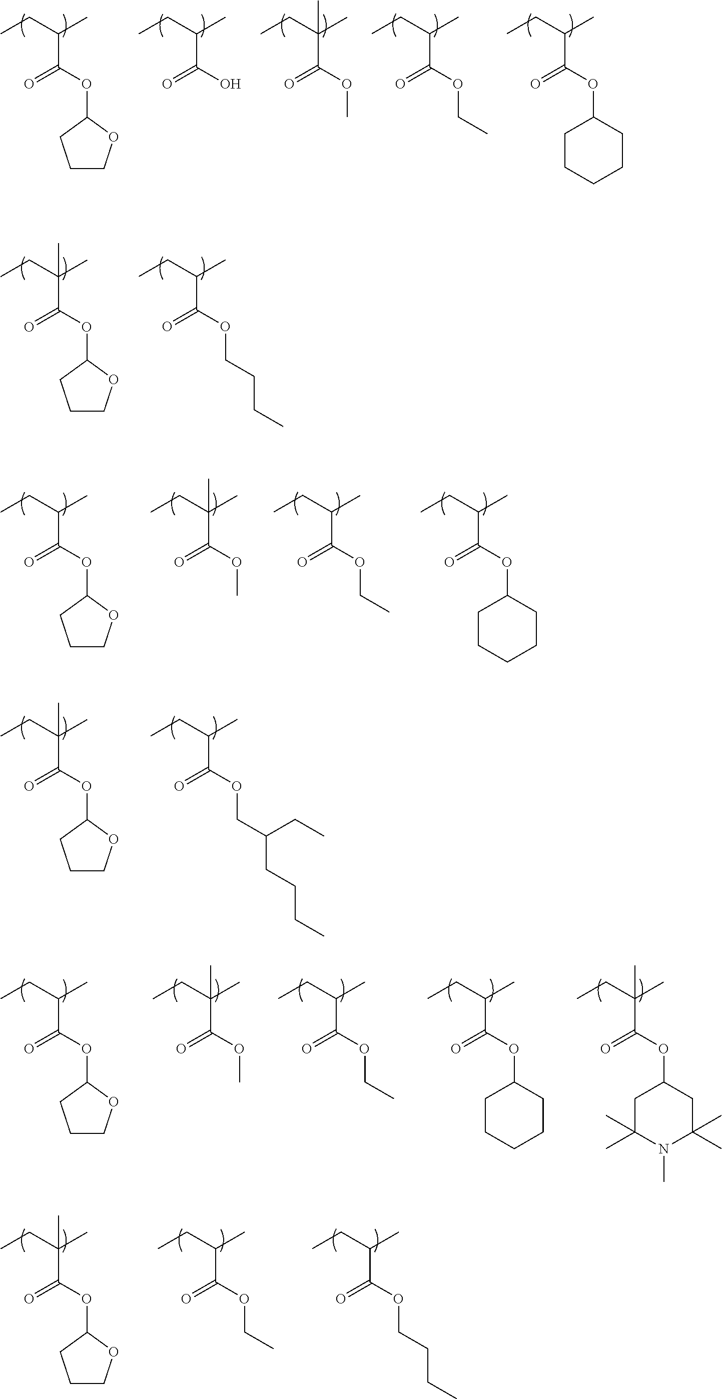

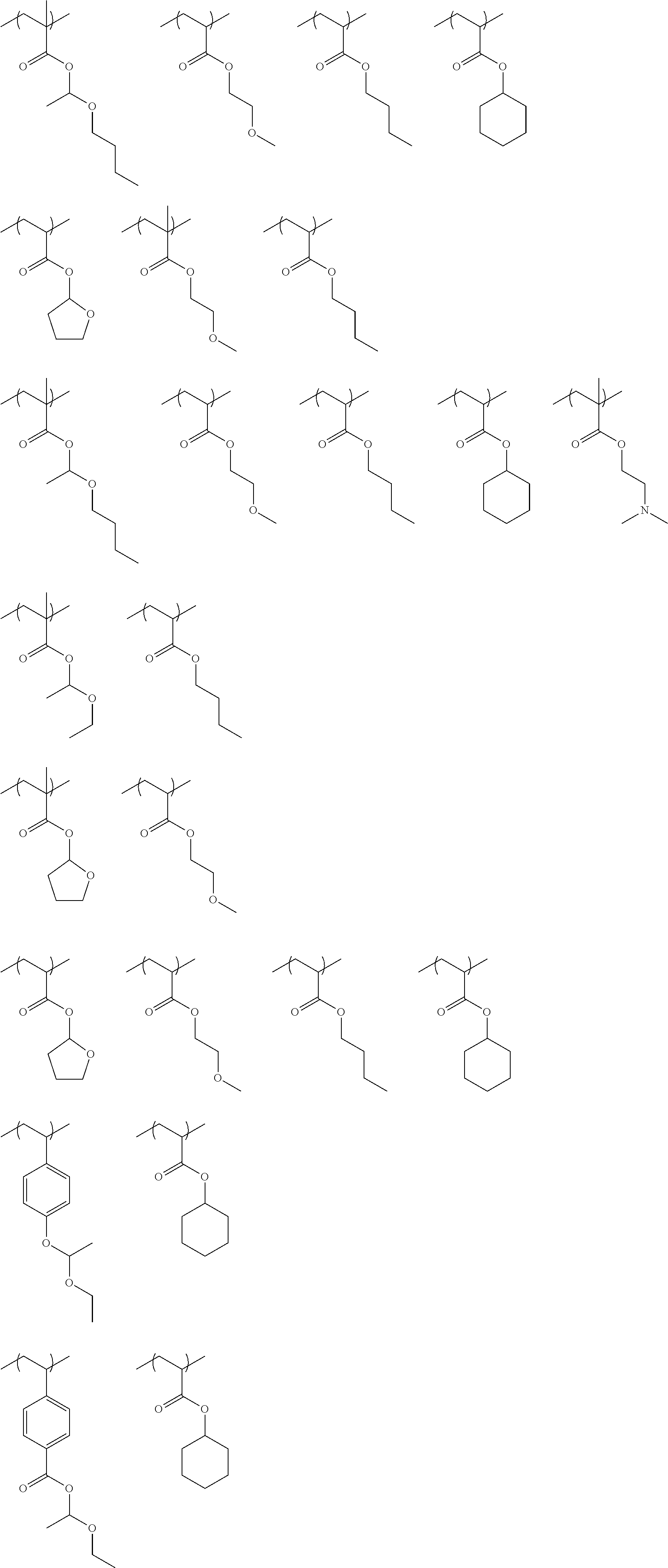

Glass Transition Temperature

The glass transition temperature (Tg) of the polymer X is preferably 90° C. or lower, more preferably 20° C. to 60° C., and particularly preferably 30° C. to 50° C. In a case where the positive type photosensitive resin layer is formed from a transfer material described later, the transferability of the positive type photosensitive resin layer can be improved by keeping the glass transition temperature of the polymer X within the above range.

Examples of the method of adjusting the Tg of the polymer X within the above range include a method of using the FOX expression. According to the FOX expression, it is possible to adjust the Tg of the target polymer X, for example, based on the Tg of the homopolymer of each constitutional unit in the target polymer X and the mass fraction of each constitutional unit.

Hereinafter, the FOX expression will be described by using a copolymer having a first constitutional unit and a second constitutional unit as an example.

In a case where the glass transition temperature of the homopolymer of the first constitutional unit is denoted by Tg1, the mass fraction of the first constitutional unit in the copolymer is denoted by W1, the glass transition temperature of the homopolymer of the second constitutional unit is denoted by Tg2, and the mass fraction of the second constitutional unit in the copolymer is denoted by W2, the glass transition temperature Tg0 (unit: K) of the copolymer having the first constitutional unit and the second constitutional unit can be estimated according to the following expression.

1/Tg0=(W1/Tg1)+(W2/Tg2) FOX expression:

Further, in a case where the weight-average molecular weight of a polymer is adjusted, it is also possible to adjust the Tg of the polymer.

Acid Value

From the viewpoint of resolution, the acid value of the polymer X is preferably 0 mgKOH/g to 50 mgKOH/g, more preferably 0 mgKOH/g to 20 mgKOH/g, and particularly preferably 0 mgKOH/g to 10 mgKOH/g.

The acid value of the polymer indicates a mass of potassium hydroxide per 1 g of the polymer, which is required to neutralize acidic components therein. A specific measuring method will be described below. First, a measurement sample is dissolved in a mixed solvent containing tetrahydrofuran and water (volume ratio: tetrahydrofuran/water=9/1). Using a potentiometric titrator (for example, product name: AT-510, manufactured by KYOTO ELECTRONICS MANUFACTURING Co., Ltd.), the obtained solution is subjected to neutralizing titration at 25° C. with a 0.1 mol/L sodium hydroxide aqueous solution. An acid value is calculated according to the following expression by using an inflection point of a titration pH curve as the end point of titration.

A=56.11×Vs×0.1×f/w

A: acid value (mgKOH/g)

Vs: using amount (mL) of 0.1 mol/L sodium hydroxide aqueous solution used for titration

f: titer of 0.1 mol/L sodium hydroxide aqueous solution

w: mass (g) of measurement sample (expressed in terms of solid contents)

Weight-Average Molecular Weight

The weight-average molecular weight (Mw) of the polymer X is preferably a polystyrene-equivalent weight-average molecular weight of 60,000 or less. In a case where the weight-average molecular weight of the polymer X is 60,000 or less, the positive type photosensitive resin layer can be transferred at a low temperature (for example, 130° C. or lower) in a case where the positive type photosensitive resin layer is formed from a transfer material described later.

The weight-average molecular weight of the polymer X is preferably 2,000 to 60,000 and more preferably 3,000 to 50,000.

The ratio (the dispersity) of the number-average molecular weight to the weight-average molecular weight of the polymer X is preferably 1.0 to 5.0 and more preferably 1.05 to 3.5.

The weight-average molecular weight of the polymer X is measured by gel permeation chromatography (GPC). As the measuring device, various commercially available devices can be used. Hereinafter, a method of measuring the weight-average molecular weight of the polymer X by GPC will be specifically described.

As a measuring device, HLC (registered trade name)-8220GPC (manufactured by Tosoh Corporation) is used.

As the column, the following columns are connected one by one in series and used; TSKgel (registered trade name) Super HZM-M (4.6 mm ID×15 cm, manufactured by Tosoh Corporation), Super HZ4000 (4.6 mm ID×15 cm, manufactured by Tosoh Corporation), Super HZ3000 (4.6 mm ID×15 cm, manufactured by Tosoh Corporation), and Super HZ2000 (4.6 mm ID×15 cm, Tosoh Corporation).

Tetrahydrofuran (THF) is used as the eluent.

The measurement conditions are set as follows, sample concentration: 0.2% by mass, flow rate: 0.35 mL/min, sample injection amount: 10 μL, and measurement temperature: 40° C.

A differential refractive index (RI) detector is used as the detector.

The calibration curve is created using any one of seven samples of “Standard sample TSK standard, polystyrene”: “F-40”, “F-20”, “F-4”, “F-1”, “A-5000”, “A-2500”, and “A-1000”, manufactured by Tosoh Corporation.

Content

From the viewpoint of high resolution, the content of the polymer X is preferably 50% by mass to 99.9% by mass and more preferably 70% by mass to 98% by mass with respect to the total mass of the positive type photosensitive resin layer.

Production Method

The production method for the polymer X is not limited, and a known method can be used. For example, the polymer X can be produced in an organic solvent by using a polymerization initiator and polymerizing a monomer for forming the constitutional unit A, and, as necessary, a monomer for forming the constitutional unit B and a monomer for forming the constitutional unit C. Further, the polymer X can also be produced by a so-called polymer reaction.

Another Polymer

In a case where the positive type photosensitive resin layer contains a polymer having a constitutional unit having an acid group protected by an acid-decomposable group, it may contain, in addition to the polymer having a constitutional unit having an acid group protected by an acid-decomposable group, a polymer that does not contain a constitutional unit having an acid group protected by an acid-decomposable group (hereinafter, may be referred to as the “other polymer”).

Examples of the other polymer include polyhydroxystyrene. Commercially available products of polyhydroxystyrene include SMA 1000P, SMA 2000P, SMA 3000P, SMA 1440F, SMA 17352P, SMA 2625P, and SMA 3840F, manufactured by Sartomer Company Inc.; ARUFON UC-3000, ARUFON UC-3510, ARUFON UC-3900, ARUFON UC-3910, ARUFON UC-3920, and ARUFON UC-3080, manufactured by Toagosei Co., Ltd.; and Joncryl 690, Joncryl 678, Joncryl 67, and Joncryl 586, manufactured by BASF SE.

The positive type photosensitive resin layer may contain one kind of other polymer alone, or may contain two or more kinds of other polymers.

In a case where the positive type photosensitive resin layer contains the other polymer, the content of the other polymer is preferably 50% by mass or less, preferably 30% by mass or less, and particularly preferably 20% by mass or less, with respect to the total mass of the polymer component.

In the present disclosure, the “polymer component” is a general term for all the polymers contained in the positive type photosensitive resin layer. For example, in a case where the positive type photosensitive resin layer contains the polymer X and the other polymer, the polymer X and the other polymers are collectively referred to as a “polymer component”. It is noted that compounds corresponding to a cross-linking agent, a dispersing agent, and a surfactant described later are not included in the polymer component even in a case where they are polymeric compounds.

The content of the polymer component is preferably 50% by mass to 99.9% by mass and more preferably 70% by mass to 98% by mass with respect to the total mass of the positive type photosensitive resin layer.

Alkali-Soluble Resin (Positive Type)

The positive type photosensitive resin layer preferably contains an alkali-soluble resin, more preferably contains an alkali-soluble resin and a quinone diazide compound, and particularly preferably contains a resin having a constitutional unit having a phenolic hydroxyl group and a quinone diazide compound.

Examples of the alkali-soluble resin include resins having a hydroxyl group, a carboxy group, or a sulfo group in the main chain or side chain. Examples of the alkali-soluble resin include a polyamide resin, polyhydroxystyrene, a polyhydroxystyrene derivative, a styrene-maleic acid anhydride copolymer, polyvinylhydroxybenzoate, a carboxy group-containing (meth)acrylic resin, and a novolak resin. Preferred examples of the alkali-soluble resin include a condensation polymer of mixed m-/p-cresol and formaldehyde, and a condensation polymer of phenol, cresol, and formaldehyde.

The alkali-soluble resin may contain a phenolic hydroxyl group (—Ar—OH), a carboxy group (—CO₂H), a sulfo group (—SO₃H), a phosphate group (—OPO₃H), a sulfonamide group (—SO₂NH—R), or a substituted sulfonamide-based group (for example, an active imide group, —SO₂NHCOR, —SO₂NHSO₂R, or —CONHSO₂R). Here, Ar represents a divalent aryl group which may have a substituent, and R represents a hydrocarbon group which may have a substituent.

The novolak resin is obtained, for example, by subjecting a phenolic compound and an aldehyde compound to condensation in the presence of an acid catalyst. Examples of the phenolic compound include o-, m-, or p-cresol, 2,5-, 3,5-, or 3,4-xylenol, 2,3,5-trimethylphenol, 2-t-butyl-5-methylphenol, and t-butyl hydroquinone. Examples of the aldehyde compound include aliphatic aldehydes (for example, formaldehyde, acetaldehyde, and glyoxal) and aromatic aldehydes (for example, benzaldehyde and salicylaldehyde). Examples of the acid catalyst include inorganic acids (for example, hydrochloric acid, sulfuric acid, and phosphoric acid), organic acids (for example, oxalic acid, acetic acid, and p-toluenesulfonic acid), and divalent metal salts (for example, zinc acetate). The condensation reaction can be carried out according to a conventional method. The condensation reaction is carried out, for example, at a temperature in a range of 60° C. to 120° C. for 2 hours to 30 hours. The condensation reaction may be carried out in a suitable solvent.

Among them, the alkali-soluble resin is preferably a resin having a constitutional unit having a phenolic hydroxyl group, such as a novolak resin.

The weight-average molecular weight of the alkali-soluble resin is preferably 5.0×10² to 2.0×10⁵ from the viewpoint of pattern forming properties. The number-average molecular weight of the alkali-soluble resin is preferably 2.0×10² to 1.0×10⁵ from the viewpoint of pattern forming properties.

For example, a condensation polymer of phenol having an alkyl group having 3 to 8 carbon atoms as a substituent and formaldehyde, such as the condensation polymer of t-butyl phenol and formaldehyde and the condensation polymer of octyl phenol and formaldehyde described in U.S. Pat. No. 4,123,279A, may be used in combination. A condensate of phenol having an alkyl group having 3 to 8 carbon atoms as a substituent and formaldehyde, such as the t-butyl phenol formaldehyde resin and the octyl phenol formaldehyde resin described in U.S. Pat. No. 4,123,279A may be used in combination.

The positive type photosensitive resin layer may contain one kind alone or two or more kinds of alkali-soluble resins.

The content of the alkali-soluble resin is preferably 30% by mass to 99.9% by mass, more preferably 40% by mass to 99.5% by mass, and particularly preferably 70% by mass to 99% by mass, with respect to the total mass of the positive type photosensitive resin layer.

Photoacid Generator

The positive type photosensitive resin layer preferably contains a photoacid generator as the photosensitive compound. The photoacid generator is a compound capable of generating an acid by irradiation with an actinic ray (for example, an ultraviolet ray, a far ultraviolet ray, an X-ray, and an electron beam).

The photoacid generator is preferably a compound that generates an acid by becoming sensitive to an actinic ray having a wavelength of 300 nm or more, preferably a wavelength of 300 nm to 450 nm. A photoacid generator which does not directly become sensitive to an actinic ray having a wavelength of 300 nm or more can also be preferably used in combination with a sensitizing agent as long as it is a compound which becomes sensitive to an actinic ray having a wavelength of 300 nm or more and then generates an acid by being used in combination with the sensitizing agent.

The photoacid generator is preferably a photoacid generator that generates an acid having a pKa of 4 or less, more preferably a photoacid generator that generates an acid having a pKa of 3 or less, and particularly preferably a photoacid generator that generates an acid having a pKa of 2 or less. The lower limit of pKa of the acid derived from the photoacid generator is not limited. The pKa of the acid derived from the photoacid generator is, for example, preferably −10.0 or more.

Examples of the photoacid generator include an ionic photoacid generator and a nonionic photoacid generator.

Examples of the ionic photoacid generator include an onium salt compound. Examples of the onium salt compound include a diaryliodonium salt compound, a triarylsulfonium salt compound, and a quaternary ammonium salt compound. The ionic photoacid generator is preferably an onium salt compound, and particularly preferably at least one of a triarylsulfonium salt compound or a diaryliodonium salt compound.

As the ionic photoacid generator, the ionic photoacid generators described in paragraph 0114 to paragraph 0133 of JP2014-85643A can also be preferably used.

Examples of the nonionic photoacid generator include a trichloromethyl-s-triazine compound, a diazomethane compound, an imide sulfonate compound, and an oxime sulfonate compound. The nonionic photoacid generator is preferably an oxime sulfonate compound from the viewpoints of sensitivity, resolution, and adhesiveness to the substrate.

Specific examples of the trichloromethyl-s-triazine compound, the diazomethane compound, and the imide sulfonate compound include the compounds described in paragraph 0083 to paragraph 0088 of JP2011-221494A.

As the oxime sulfonate compound, those described in paragraphs 0084 to paragraph 0088 of WO2018/179640A can be suitably used.

From the viewpoint of sensitivity and resolution, the photoacid generator is preferably at least one compound selected from the group consisting of an onium salt compound and an oxime sulfonate compound, and it is more preferably an oxime sulfonate compound.

Preferred examples of the photoacid generator include photoacid generators having the following structures.

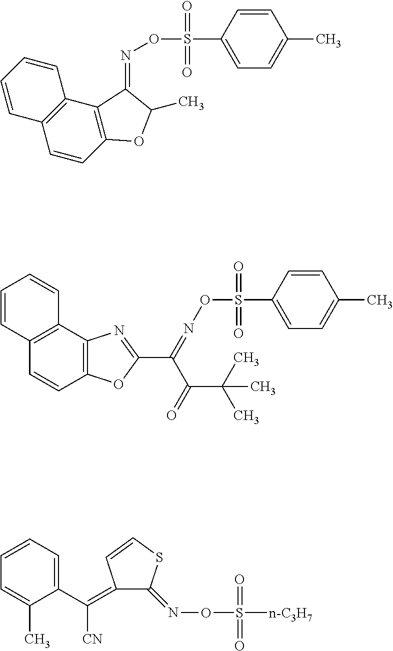

Examples of the photoacid generator having absorption at a wavelength of 405 nm include ADEKA ARKLS (registered trade name) SP-601 (manufactured by ADEKA Corporation).

From the viewpoint of heat resistance and dimensional stability, the positive type photosensitive resin layer preferably contains a quinone diazide compound as an acid generator (preferably as a photoacid generator).

The quinone diazide compound can be synthesized, for example, by subjecting a compound having a phenolic hydroxyl group and a quinone diazide sulfonic acid halide to a condensation reaction in the presence of a dehydrohalogenation agent.

Examples of the quinone diazide compound include 1,2-benzoquinone diazido-4-sulfonic acid ester, 1,2-naphthoquinone diazido-4-sulfonic acid ester, 1,2-naphthoquinone diazido-5-sulfonic acid ester, 1,2-naphthoquinone diazido-6-sulfonic acid ester, 2,1-naphthoquinone diazido-4-sulfonic acid ester, 2,1-naphthoquinone diazido-5-sulfonic acid ester, 2,1-naphthoquinone diazido-6-sulfonic acid ester, a sulfonic acid ester of another quinone diazide derivative, 1,2-benzoquinone diazido-4-sulfonic acid chloride, 1,2-naphthoquinone diazido-4-sulfonic acid chloride, 1,2-naphthoquinone diazido-5-sulfonic acid chloride, 1,2-naphthoquinone diazido-6-sulfonic acid chloride, 2,1-naphthoquinone diazido-4-sulfonic acid chloride, 2,1-naphthoquinone diazido-5-sulfonic acid chloride, and 2,1-naphthoquinone diazido-6-sulfonic acid chloride.

The positive type photosensitive resin layer may contain one kind of photoacid generator alone or may contain two or more kinds of photoacid generators.

From the viewpoints of sensitivity and resolution, the content of the photoacid generator is preferably 0.1% by mass to 10% by mass and more preferably 0.5% by mass to 5% by mass with respect to the total mass of the positive type photosensitive resin layer.

Another Component

The photosensitive resin layer may contain a component other than those described above.

Surfactant

The photosensitive resin layer preferably contains a surfactant from the viewpoint of thickness uniformity.

Examples of the surfactant include an anionic surfactant, a cationic surfactant, a nonionic surfactant, and an amphoteric surfactant, where a nonionic surfactant is preferable.

Examples of the surfactant include the surfactants described in paragraph 0017 of JP4502784B and paragraphs 0060 to 0071 of JP2009-237362A.

The surfactant is preferably a fluorine-based surfactant or a silicone-based surfactant.

Examples of the commercially available product of the fluorine-based surfactant MEGAFACE (product name) F-171, F-172, F-173, F-176, F-177, F-141, F-142, F-143, F-144, F-437, F-444, F-475, F-477, F-479, F-482, F-551-A, F-552, F-554, F-555-A, F-556, F-557, F-558, F-559, F-560, F-561, F-565, F-563, F-568, F-575, F-780, EXP, MFS-330, MFS-578, MFS-579, MFS-586, MFS-587, R-41, R-41-LM, R-01, R-40, R-40-LM, RS-43, TF-1956, RS-90, R-94, RS-72-K, DS-21 (all manufactured by DIC Corporation); Florard (product name) FC430, FC431, FC171 (all manufactured by Sumitomo 3M Limited); Surflon (product name) S-382, SC-101, SC-103, SC-104, SC-105, SC-1068, SC-381, SC-383, S-393, KH-40 (all manufactured by AGC Inc.); PolyFox (product name) PF636, PF656, PF6320, PF6520, PF7002 (all manufactured by OMNOVA Solutions Inc.); and FTERGENT 710FL, 710FM, 610FM, 601AD, 601ADH2, 602A, 215M, 245F, 251, 212M, 250, 209F, 222F, 208G, 710LA, 710FS, 730LM, 650AC, 681, 683 (all manufactured by NEOS COMPANY LIMITED).

In addition, as the fluorine-based surfactant, an acrylic compound which has a molecular structure having a functional group containing a fluorine atom and in which, by applying heat to the molecular structure, the functional group containing a fluorine atom is broken to volatilize a fluorine atom can also be suitably used. Examples of such a fluorine-based surfactant include MEGAFACE (product name) DS series manufactured by DIC Corporation (The Chemical Daily (Feb. 22, 2016), Nikkei Business Daily (Feb. 23, 2016)) such as MEGAFACE (product name) DS-21.

In addition, as the fluorine-based surfactant, a polymer of a fluorine atom-containing vinyl ether compound having a fluorinated alkyl group or a fluorinated alkylene ether group, and a hydrophilic vinyl ether compound can be preferably used.

As the fluorine-based surfactant, a block polymer can also be used. As the fluorine-based surfactant, a fluorine-containing polymeric compound including a constitutional unit derived from a (meth)acrylate compound having a fluorine atom and a constitutional unit derived from a (meth)acrylate compound having 2 or more (preferably 5 or more) alkyleneoxy groups (preferably ethyleneoxy groups or propyleneoxy groups) can also be preferably used.

As the fluorine-based surfactant, a fluorine-containing polymer having an ethylenic unsaturated group in the side chain can be used. Examples thereof include MEGAFACE (product name) RS-101, RS-102, RS-718K, and RS-72-K (all manufactured by DIC Corporation).

Examples of the nonionic surfactant include glycerol, trimethylolpropane, trimethylolethane, and ethoxylates and propoxylates (for example, glycerol propoxylate, glycerol ethoxylate) thereof, polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid ester, Pluronic (product name) L10, L31, L61, L62, 10R5, 17R2, 25R2 (all manufactured by BASF SE), Tetronic (product name) 304, 701, 704, 901, 904, 150R1 (all manufactured by BASF SE), Solsperse (product name) 20000 (all manufactured by Lubrizol Japan Limited.), NCW-101, NCW-1001, NCW-1002 (all manufactured by FUJIFILM Wako Pure Chemical Corporation), Pionin (product name) D-6112, D-6112-W, D-6315 (all manufactured by TAKEMOTO OIL & FAT Co., Ltd.), and OLFINE E1010, SURFYNOL 104, 400, 440 (all manufactured by Nissin Chemical Co., Ltd.).

By the way, in recent years, compounds having a linear perfluoroalkyl group having 7 or more carbon atoms are concerned about environmental aptitude, and thus it is preferable to use a surfactant obtained by using a substitute material for perfluorooctanoic acid (PFOA) and perfluorooctanesulfonic acid (PFOS).

Examples of the silicone-based surfactant include a linear polymer consisting of a siloxane bond and a modified siloxane polymer having an organic group introduced into a side chain or a terminal thereof.

Specific examples of the silicone-based surfactant include DOWSIL (product name) 8032 ADDITIVE, TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, TORAY SILICONE SH8400 (all manufactured by Toray Dow Corning Co., Ltd.); X-22-4952, X-22-4272, X-22-6266, KF-351A, K354L, KF-355A, KF-945, KF-640, KF-642, KF-643, X-22-6191, X-22-4515, KF-6004, KP-341, KF-6001, KF-6002 (all manufactured by Shin-Etsu Chemical Co., Ltd.); F-4440, TSF-4300, TSF-4445, TSF-4460, TSF-4452 (all manufactured by Momentive Performance Materials Inc.); and BYK307, BYK323, BYK330 (all manufactured by BYK Additives & Instruments).

The photosensitive resin layer may contain one kind of surfactant alone or may contain two or more kinds thereof.

The content of the surfactant is preferably 0.01% by mass to 10% by mass and more preferably 0.001% by mass to 3% by mass with respect to the total mass of the photosensitive resin layer.

Additive

In addition to the above components, the photosensitive resin layer may contain known additives, as necessary.

Examples of the additive include a polymerization inhibitor, a sensitizing agent, a plasticizer, an alkoxysilane compound, and a solvent. The photosensitive resin layer may contain one kind of each additive alone or may contain two or more kinds of additives.

In addition, examples of the additive include a metal oxide particle, an antioxidant, a dispersing agent, an acid proliferation agent, a development accelerator, a conductive fiber, a thermal radical polymerization initiator, a thermal acid generator, an ultraviolet absorbing agent, a thickener, and an organic or inorganic anti-precipitation agent. Each of preferred aspects of these additives is described in paragraph 0165 to paragraph 0184 of JP2014-85643A, and the contents thereof are incorporated in the present specification by reference.

The photosensitive resin layer may contain a polymerization inhibitor. The polymerization inhibitor is preferably a radical polymerization inhibitor.

Examples of the polymerization inhibitor include the thermal polymerization inhibitors described in paragraph 0018 of JP4502784B. Among them, phenothiazine, phenoxazine, or 4-methoxyphenol is preferable. Examples of other polymerization inhibitors include naphthylamine, cuprous chloride, a nitrosophenylhydroxyamine aluminum salt, and diphenylnitrosamine. It is preferable to use a nitrosophenylhydroxyamine aluminum salt as a polymerization inhibitor so that the sensitivity of the photosensitive resin composition is not impaired.

The content of the polymerization inhibitor is preferably 0.01% by mass to 3% by mass and more preferably 0.05% by mass to 1% by mass with respect to the total mass of the photosensitive resin layer. It is preferable to set the above content to 0.01% by mass or more from the viewpoint of imparting storage stability to the photosensitive resin composition. On the other hand, it is preferable to set the above content to 3% by mass or less from the viewpoint of maintaining sensitivity.

The photosensitive resin layer may contain a sensitizing agent.

The sensitizing agent is not particularly limited, and a known sensitizing agent, a dye, or a pigment can be used. Examples of the sensitizing agent include a dialkylaminobenzophenone compound, a pyrazoline compound, an anthracene compound, a coumarin compound, a xanthone compound, a thioxanthone compound, an acridone compound, an oxazole compound, a benzoxazole compound, a thiazole compound, a benzothiazole compound, a triazole compound (for example, 1,2,4-triazole), a stilbene compound, a triazine compound, a thiophene compound, a naphthalimide compound, a triarylamine compound, and an aminoacridine compound.

The photosensitive resin layer may contain one kind of sensitizing agent alone or may contain two or more kinds thereof.

In a case where the photosensitive resin layer contains a sensitizing agent, the content of the sensitizing agent can be appropriately selected depending on the intended purpose; however, from the viewpoints of improving the sensitivity to the light source and improving the curing rate by balancing the polymerization rate and the chain transfer, it is preferably 0.01% by mass to 5% by mass and more preferably 0.05% by mass to 1% by mass with respect to the total mass of the photosensitive resin layer.

The photosensitive resin layer may contain at least one selected from the group consisting of a plasticizer and a heterocyclic compound.

Examples of the plasticizer and the heterocyclic compound include the compounds described in paragraphs 0097 to 0103 and 0111 to 0118 of WO2018/179640A.

The photosensitive resin layer, preferably the positive type photosensitive resin layer, may contain an alkoxysilane compound.

Examples of the alkoxysilane compound include γ-aminopropyl trimethoxysilane, γ-aminopropyl triethoxysilane, γ-glycidoxypropyl triacoxysilane, γ-glycidoxypropylalkyl dialkoxysilane, γ-methacryloxypropyl trialkoxysilane, γ-methacryloxypropylalkyl dialkoxysilane, γ-chloropropyl trialkoxysilane, γ-mercaptopropyl trialkoxysilane, β-(3,4-epoxycyclohexyl)ethyl trialkoxysilane, and vinyl trialkoxysilane.

Among the above, the alkoxysilane compound is preferably a trialkoxysilane compound, more preferably γ-glycidoxypropyl trialkoxysilane or γ-methacryloxypropyl trialkoxysilane, and still more preferably γ-glycidoxypropyl trialkoxysilane, and particularly preferably 3-glycidoxypropyl trimethoxysilane.

The photosensitive resin layer may contain one kind of alkoxysilane compound alone or may contain two or more kinds of alkoxysilane compounds.

From the viewpoints of the adhesiveness to the substrate and the etching resistance, the content of the alkoxysilane compound is preferably 0.1% by mass to 50% by mass, preferably 0.5% by mass to 40% by mass, and particularly preferably 1.0% by mass to 30% by mass, with respect to the total mass of the photosensitive resin layer.

The photosensitive resin layer may contain a solvent. In a case where the photosensitive resin layer is formed from the photosensitive resin composition containing a solvent, the solvent may remain in the photosensitive resin layer.

Impurities and the Like

The photosensitive resin layer may include a predetermined amount of impurities.

Specific examples of the impurities include sodium, potassium, magnesium, calcium, iron, manganese, copper, aluminum, titanium, chromium, cobalt, nickel, zinc, tin, halogen, and ions of thereof. Among these, a halide ion, a sodium ion, and a potassium ion are easily mixed as impurities, and thus it is preferable to set the content of the impurities to the following content.

The content of impurities in the photosensitive resin layer is preferably 80 ppm or less, more preferably 10 ppm or less, and still more preferably 2 ppm or less on a mass basis. The content of the impurities can be 1 ppb or more or may be 0.1 ppm or more on a mass basis.

Examples of the method of keeping the impurities in the above range include selecting a raw material having a low content of impurities as a raw material for the composition, preventing the impurities from being mixed during the production of the photosensitive resin layer, and washing and removing the impurities. Such a method makes it possible for the amount of impurities to be kept within the above range.

The impurities can be quantified by a known method such as inductively coupled plasma (ICP) emission spectroscopy, atomic absorption spectroscopy, and ion chromatography.

In the photosensitive resin layer, it is preferable that the content of the compound such as benzene, formaldehyde, trichloroethylene, 1,3-butadiene, carbon tetrachloride, chloroform, N,N-dimethylformamide, N,N-dimethylacetamide, or hexane is low. The content of this compound with respect to the total mass of the photosensitive resin layer is preferably 100 ppm or less, more preferably 20 ppm or less, and still more preferably 4 ppm or less on a mass basis.

The lower limit thereof can be 10 ppb or more or can be 100 ppb or more on a mass basis, with respect to the total mass of the photosensitive resin layer. The content of these compounds can be suppressed in the same manner as in the above-described metal as impurities. Further, it can be quantified by a known measuring method.

From the viewpoint of improving reliability and laminating property, the content of water in the photosensitive resin layer is preferably 0.01% by mass to 1.0% by mass and more preferably 0.05% by mass to 0.5% by mass.

Residual Monomer

The photosensitive resin layer may contain a residual monomer corresponding to each of the constitutional units of the alkali-soluble resin described above.

From the viewpoint of patterning properties and reliability, the content of the residual monomer is preferably 5,000 ppm by mass or less, more preferably 2,000 ppm by mass or less, and still more preferably 500 ppm by mass or less, with respect to the total mass of the alkali-soluble resin. The lower limit thereof is not particularly limited; however, it is preferably 1 ppm by mass or more and more preferably 10 ppm by mass or more.

From the viewpoint of patterning properties and reliability, the residual monomer of each constitutional unit in the alkali-soluble resin is preferably 3,000 ppm by mass or less, more preferably 600 ppm by mass or less, and still more preferably 100 ppm by mass or less, with respect to the total mass of the photosensitive resin layer. The lower limit thereof is not particularly limited; however, it is preferably 0.1 ppm by mass or more and more preferably 1 ppm by mass or more.

It is preferable that the amount of residual monomer of the monomer in a case of synthesizing the alkali-soluble resin by the polymer reaction is also within the above range. For example, in a case where glycidyl acrylate is reacted with a carboxylic acid side chain to synthesize the alkali-soluble resin, the content of glycidyl acrylate is preferably within the above range.

The amount of the residual monomer can be measured by a known method such as liquid chromatography or gas chromatography.

Physical Characteristics and the Like

The layer thickness of the photosensitive resin layer is preferably 0.1 μm to 300 μm, more preferably 0.2 μm to 100 μm, still more preferably 0.5 μm to 50 μm, even still more preferably 0.5 μm to 15 μm, particularly preferably 0.5 μm to 10 μm, and most preferably 0.5 μm to 8 μm. This makes it possible for the developability of the photosensitive resin layer to be improved and makes it possible for the resolution to be improved.

Further, the layer thickness (the thickness) of the photosensitive resin layer is preferably 10 μm or less, more preferably 5.0 μm or less, still more preferably 0.5 μm to 4.0 μm, and particularly preferably 0.5 μm to 3.0 μm, from the viewpoints of resolution and further exhibiting the effects in the present disclosure.

The layer thickness of each layer provided in the photosensitive transfer material is measured by observing the cross section in a direction perpendicular to the main surface of the photosensitive transfer material with a scanning electron microscope (SEM), measuring the thickness of each layer at 10 points or more based on the obtained observation image, and calculating the average value thereof.

In addition, from the viewpoint of excellent adhesiveness, the light transmittance of light having a wavelength of 365 nm in the photosensitive resin layer is preferably 10% or more, more preferably 30% or more, and still more preferably 50% or more. The upper limit thereof is not particularly limited; however, it is preferably 99.9% or less.

Forming Method

The method of forming the photosensitive resin layer is not particularly limited as long as it is a method capable of forming a layer containing the above components.

Examples of the method of forming the photosensitive resin layer include a method in which, in a case of a negative type photosensitive resin layer, a photosensitive resin composition containing an alkali-soluble resin, a polymerizable compound, a photopolymerization initiator, a solvent, and the like is prepared, the photosensitive resin composition is applied onto the surface of the temporary support or the like, and the coating film of the photosensitive resin composition is dried to form the photosensitive resin composition.

Examples of the photosensitive resin composition that is used in the formation of the photosensitive resin layer include a composition containing an alkali-soluble resin, a polymerizable compound, a photopolymerization initiator, the above-described optional component, and a solvent.

The photosensitive resin composition preferably contains a solvent in order to adjust the viscosity of the photosensitive resin composition and facilitate the formation of the photosensitive resin layer.

Solvent

The solvent contained in the photosensitive resin composition is not particularly limited as long as it is capable of dissolving or dispersing an alkali-soluble resin, a polymerizable compound, a photopolymerization initiator, and the above-described optional component, and a known solvent can be used.

Examples of the solvent include an alkylene glycol ether solvent, an alkylene glycol ether acetate solvent, an alcohol solvent (methanol, ethanol, or the like), a ketone solvent (acetone, methyl ethyl ketone, or the like), an aromatic hydrocarbon solvent (toluene or the like), an aprotonic polar solvent (N,N-dimethylformamide or the like), a cyclic ether solvent (tetrahydrofuran or the like), an ester solvent, an amide solvent, a lactone solvent, and a mixed solvent containing two or more of these.

In a case of producing a photosensitive transfer material including a temporary support, a thermoplastic resin layer, a water-soluble resin layer, a photosensitive resin layer, and a protective film, the photosensitive resin composition preferably contains at least one selected from the group consisting of an alkylene glycol ether solvent and an alkylene glycol ether acetate solvent. Among the above, the solvent is more preferably a mixed solvent containing at least one solvent selected from the group consisting of an alkylene glycol ether solvent and an alkylene glycol ether acetate solvent and at least one solvent selected from the group consisting of a ketone solvent and a cyclic ether solvent, and still more preferably a mixed solvent containing at least three solvents of one solvent selected from the group consisting of an alkylene glycol ether solvent and an alkylene glycol ether acetate solvent, a ketone solvent, and a cyclic ether solvent.

Examples of the alkylene glycol ether solvent include ethylene glycol monoalkyl ether, ethylene glycol dialkyl ether, propylene glycol monoalkyl ether, propylene glycol dialkyl ether, diethylene glycol dialkyl ether, dipropylene glycol monoalkyl ether, and dipropylene glycol dialkyl ether.

Examples of the alkylene glycol ether acetate solvent include ethylene glycol monoalkyl ether acetate, propylene glycol monoalkyl ether acetate, diethylene glycol monoalkyl ether acetate, and dipropylene glycol monoalkyl ether acetate.

As the solvent, the solvents described in paragraphs 0092 to 0094 of WO2018/179640A and the solvents described in paragraph 0014 of JP2018-177889A may be used, the contents of which are incorporated in the present specification.

The photosensitive resin composition may contain one kind of solvent alone or may contain two or more kinds of thereof.

In a case where the photosensitive resin composition is applied, the content of the solvent is preferably 50 parts by mass to 1,900 parts by mass and more preferably 100 parts by mass to 900 parts by mass with respect to 100 parts by mass of the total solid content in the photosensitive resin composition.

The method of preparing the photosensitive resin composition is not particularly limited. Examples thereof include a method in which each solution is prepared in advance by dissolving each component in the above solvent, and the obtained solutions are mixed at a predetermined ratio to prepare the photosensitive resin composition.

From the viewpoint of particle removability, the photosensitive resin composition is preferably filtered using a filter before forming the photosensitive resin layer, more preferably filtered using a filter having a pore diameter of 0.2 μm to 10 μm, still more preferably filtered using a filter having a pore diameter of 0.2 μm to 7 μm, and particularly preferably filtered using a filter having a pore diameter of 0.2 μm to 5 μm.

The material and shape of the filter are not particularly limited, and known ones can be used.

Further, the above filtration is preferably carried out one time or more, and it is also preferably carried out a plurality of times.

The method of applying the photosensitive resin composition is not particularly limited, and the photosensitive resin composition may be applied by a known method. Examples of the coating method include slit coating, spin coating, curtain coating, and inkjet coating.

In addition, the photosensitive resin layer may be formed by applying the photosensitive resin composition onto a protective film described later and drying it.

Further, the photosensitive transfer material in the present disclosure preferably has another layer between the temporary support and the photosensitive resin layer from the viewpoints of the resolution and the peelability of the temporary support.

Preferred examples of the other layer include a water-soluble resin layer, a thermoplastic resin layer, and a protective film.

Among them, as the transfer layer, it is preferable to have a water-soluble resin layer, and it is more preferable to have a thermoplastic resin layer and a water-soluble resin layer.

Water-soluble resin layer

The photosensitive transfer material preferably has a water-soluble resin layer between the temporary support and the photosensitive resin layer, or between a thermoplastic resin layer described later and the photosensitive resin layer in a case where the photosensitive transfer material has the thermoplastic resin layer. According to the water-soluble resin layer, it is possible to suppress the mixing of components in a case of forming a plurality of layers and in a case of storing.

The water-soluble resin layer is preferably a water-soluble layer from the viewpoints of the developability and suppressing mixing of components in a case of coating a plurality of layers and in a case of storing after coating. In the present disclosure, “water-soluble” means that the solubility in 100 g of water having a liquid temperature of 22° C. and a pH of 7.0 is 0.1 g or more.

Examples of the water-soluble resin layer include the oxygen blocking layer having an oxygen blocking function, which is described as a “separation layer” in JP1993-72724A (JP-H5-72724A). In a case where the water-soluble resin layer is an oxygen blocking layer, the sensitivity at the time of exposure is improved, the time load of the exposure machine is reduced, and as a result, the productivity is improved. The oxygen blocking layer that is used as a water-soluble resin layer may be appropriately selected from known layers. The oxygen blocking layer that is used as a water-soluble resin layer is preferably an oxygen blocking layer that exhibits low oxygen permeability and is dispersed or dissolved in water or an alkaline aqueous solution (an aqueous solution of 1% by mass sodium carbonate at 22° C.).

Further, the water-soluble resin layer preferably contains an inorganic layered compound from the viewpoints of oxygen blocking property, resolution, and pattern forming properties.

The inorganic layered compound indicates a particle having a thin tabular shape, and examples thereof include a mica compound such as natural mica and synthetic mica, talc represented by Formula: 3MgO.4SiO.H₂O, taeniolite, montmorillonite, saponite, hectorite, and zirconium phosphate.

Examples of the mica compound include mica groups such as natural mica and synthetic mica represented by Formula: A(B, C)₂₋₅D₄O₁₀(OH, F, O)₂ [here, A represents any of K, Na, and Ca, B and C represent any of Fe (II), Fe (III), Mn, Al, Mg, and V, and D represents Si or Al.].

In the mica group, examples of the natural mica include muscovite, soda mica, phlogopite, biotite, and lepidolite. Examples of synthetic mica include non-swelling mica such as fluorine phlogopite KMg₃(AlSi₃O₁₀)F₂, potassium tetrasilic mica KMg_{2.5}(Si₄O₁₀)F₂, and, Na tetrasilylic mica NaMg_{2.5}(Si₄O₁₀)F₂, swelling mica such as Na or Li taeniolite (Na, Li)Mg₂Li(Si₄O₁₀)F₂, montmorillonite-based Na or Li hectorite (Na, Li)_{1/8}Mg_{2/5}Li_{1/8}(Si₄O₁₀)F₂. Furthermore, synthetic smectite is also useful.

As the shape of the inorganic layered compound, from the viewpoint of controlling diffusion, it is preferable that the thickness thereof is as small as possible and the plane size thereof is as large as possible within a range where the smoothness of the coating surface or the transmittance of the actinic ray is not inhibited. As a result, the aspect ratio is preferably 20 or more, more preferably 100 or more, and particularly preferably 200 or more. The aspect ratio is the ratio of the major diameter to the thickness of a particle, and it can be measured, for example, from a projection view obtained from the microphotograph of the particle. The effects to be obtained increase as the aspect ratio increases.

Regarding the particle diameter of the inorganic layered compound, the average major diameter thereof is preferably 0.3 μm to 20 μm, more preferably 0.5 μm to 10 μm, and particularly preferably 1 μm to 5 μm. The average thickness of the particles is preferably 0.1 μm or less, more preferably 0.05 μm or less, and particularly preferably 0.01 μm or less. Specifically, for example, as a preferable aspect of swellable synthetic mica which is a representative compound, the thickness thereof is in a range of 1 nm to 50 nm and the surface size (major diameter) is in a range of 1 μm to 20 μm.

From the viewpoints of oxygen blocking property, resolution, and pattern forming properties, the content of the inorganic layered compound is preferably 0.1% by mass to 50% by mass and more preferably 1% by mass to 20% by mass with respect to the total mass of the water-soluble resin layer.

The water-soluble resin layer preferably contains a resin. Examples of the resin contained in the water-soluble resin layer include a polyvinyl alcohol-based resin, a polyvinylpyrrolidone-based resin, a cellulose-based resin, an acrylamide-based resin, a polyethylene oxide-based resin, gelatin, a vinyl ether-based resin, a polyamide resin, and a copolymer thereof. The resin contained in the water-soluble resin layer is preferably a water-soluble resin.

From the viewpoint of suppressing the mixing of the components between the plurality of layers, the resin contained in the water-soluble resin layer is preferably a resin different from any one of the polymer A contained in the negative type photosensitive resin layer or the thermoplastic resin (the alkali-soluble resin) contained in the thermoplastic resin layer.

Further, the water-soluble resin layer preferably contains a water-soluble compound and more preferably contains a water-soluble resin from the viewpoints of oxygen blocking property, developability, resolution, and pattern forming properties.

The water-soluble compound is not particularly limited. However, from the viewpoints of oxygen blocking property, developability, resolution, and pattern forming properties, it is preferably one or more compounds selected from the group consisting of a water-soluble cellulose derivative, polyhydric alcohols, oxide adducts of polyhydric alcohols, polyethers, a phenol derivative, and an amide compound, and more preferably at least one water-soluble resin selected from the group consisting of polyvinyl alcohol, polyvinylpyrrolidone, hydroxypropyl cellulose, and hydroxypropylmethyl cellulose.

Examples of the water-soluble resin include resins such as a water-soluble cellulose derivative, polyvinyl alcohol, polyvinylpyrrolidone, an acrylamide resin, a (meth)acrylate resin, a polyethylene oxide resin, gelatin, a vinyl ether resin, a polyamide resin, and a copolymer thereof.

Among them, the water-soluble compound preferably contains polyvinyl alcohol, and it is more preferably polyvinyl alcohol, from the viewpoints of oxygen blocking property, developability, resolution, and pattern forming properties.

The degree of hydrolysis of polyvinyl alcohol is not particularly limited; however, it is preferably 73% by mole to 99% by mole from the viewpoints of oxygen blocking property, developability, resolution, and pattern forming properties.

Further, polyvinyl alcohol preferably contains ethylene as a monomer unit from the viewpoints of oxygen blocking property, developability, resolution, and pattern forming properties.

From the viewpoints of oxygen blocking property and suppressing mixing of components in a case of coating a plurality of layers and in a case of storing after coating, the water-soluble resin layer preferably contains polyvinyl alcohol and more preferably contains polyvinyl alcohol and polyvinylpyrrolidone.

The water-soluble resin layer may contain one kind of resin alone or two or more kinds of resins.

From the viewpoints of oxygen blocking property and suppressing mixing of components in a case of coating a plurality of layers and in a case of storing after coating, the content proportion of the water-soluble compound in the water-soluble resin layer is preferably 50% by mass to 100% by mass, more preferably 70% by mass to 100% by mass, still more preferably 80% by mass to 100% by mass, and particularly preferably 90% by mass to 100% by mass, with respect to the total mass of the water-soluble resin layer.

Further, the water-soluble resin layer may contain an additive as necessary. Examples of the additive include a surfactant.

The thickness of the water-soluble resin layer is not limited. The average thickness of the water-soluble resin layer is preferably 0.1 μm to 5 μm and more preferably 0.5 μm to 3 μm. In a case where the thickness of the water-soluble resin layer is within the above range, it is possible to suppress the mixing of components in a case of forming a plurality of layers and in a case of storing, without reducing the oxygen blocking property, and it is possible to suppress an increase in the removal time of the water-soluble resin layer in a case of development.

The method of forming the water-soluble resin layer is not limited as long as it is a method capable of forming a layer containing the above components. Examples of the method of forming the water-soluble resin layer include a method of applying the water-soluble resin layer composition onto the surface of the thermoplastic resin layer or the photosensitive resin layer and then drying the coating film of the water-soluble resin layer composition.

Examples of the water-soluble resin layer composition include a resin and a composition containing any additive. The water-soluble resin layer composition preferably contains a solvent in order to adjust the viscosity of the water-soluble resin layer composition and facilitate the formation of the water-soluble resin layer. The solvent is not limited as long as it is a solvent capable of dissolving or dispersing a resin. The solvent is preferably at least one selected from the group consisting of water and a water-miscible organic solvent, and it is more preferably water or a mixed solvent of water and a water-miscible organic solvent.

Examples of the water-miscible organic solvent include an alcohol having 1 to 3 carbon atoms, acetone, ethylene glycol, and glycerin. The water-miscible organic solvent is preferably an alcohol having 1 to 3 carbon atoms and more preferably methanol or ethanol.

Thermoplastic Resin Layer

The photosensitive transfer material that is used in the present disclosure may have a thermoplastic resin layer. The photosensitive transfer material preferably has a thermoplastic resin layer between the temporary support and the photosensitive resin layer. This is due to the reason that in a case where the thermoplastic resin layer is provided between the temporary support and the photosensitive resin layer, the photosensitive transfer material has improved followability to the adherend, and as a result of suppressing the mixing of bubbles between the adherend and the photosensitive transfer material, the adhesiveness between the layers is improved.

The thermoplastic resin layer preferably contains an alkali-soluble resin as the thermoplastic resin.

Examples of the alkali-soluble resin include an acrylic resin, a polystyrene resin, a styrene-acrylic copolymer, a polyurethane resin, polyvinyl alcohol, polyvinyl formal, a polyamide resin, a polyester resin, an epoxy resin, a polyacetal resin, a polyhydroxystyrene resin, a polyimide resin, a polybenzoxazole resin, a polysiloxane resin, polyethyleneimine, polyallylamine, and polyalkylene glycol.

The alkali-soluble resin is preferably an acrylic resin from the viewpoints of developability and adhesiveness to a layer adjacent to the thermoplastic resin layer. Here, the “acrylic resin” means a resin having at least one selected from the group consisting of a constitutional unit derived from (meth)acrylic acid, a constitutional unit derived from (meth)acrylic acid ester, and a constitutional unit derived from (meth)acrylic acid amide.

In the acrylic resin, the proportion of the total content of the constitutional unit derived from (meth)acrylic acid, the constitutional unit derived from (meth)acrylic acid ester, and the constitutional unit derived from (meth)acrylic acid amide is preferably 50% by mass or more with respect to the total mass the acrylic resin. In the acrylic resin, the proportion of the total content of the constitutional unit derived from (meth)acrylic acid and the constitutional unit derived from (meth)acrylic acid ester is preferably 30% by mass to 100% by mass and more preferably 50% by mass to 100% by mass with respect to the total mass of the acrylic resin.

Further, the alkali-soluble resin is preferably a polymer having an acid group. Examples of the acid group include a carboxy group, a sulfo group, a phosphate group, and a phosphonate group, where a carboxy group is preferable.

From the viewpoint of developability, the alkali-soluble resin is preferably an alkali-soluble resin having an acid value of 60 mgKOH/g or more and more preferably a carboxy group-containing acrylic resin having an acid value of 60 mgKOH/g or more. The upper limit of the acid value is not limited. The acid value of the alkali-soluble resin is preferably 200 mgKOH/g or less and more preferably 150 mgKOH/g or less.

The carboxy group-containing acrylic resin having an acid value of 60 mgKOH/g or more is not limited and can be appropriately selected from known resins and used. Examples of the carboxy group-containing acrylic resin having an acid value of 60 mgKOH/g or more include the carboxy group-containing acrylic resin having an acid value of 60 mgKOH/g or more among the polymers described in paragraph 0025 of JP2011-95716A, the carboxy group-containing acrylic resin having an acid value of 60 mgKOH/g or more among the polymers described in paragraph 0033 to paragraph 0052 of JP2010-237589A, and the carboxy group-containing acrylic resin having an acid value of 60 mgKOH/g or more among the binder polymers described in paragraph 0053 to paragraph 0068 of JP2016-224162A.

In the carboxy group-containing acrylic resin, the content proportion of the constitutional unit having a carboxy group is preferably 5% by mass to 50% by mass, preferably 10% by mass to 40% by mass, and particularly preferably 12% by mass to 30% by mass, with respect to the total mass of the carboxy group-containing acrylic resin.

The alkali-soluble resin is particularly preferably an acrylic resin having a constitutional unit derived from (meth) acrylic acid from the viewpoints of developability and adhesiveness to a layer adjacent to the thermoplastic resin layer.

The alkali-soluble resin may have a reactive group. The reactive group may be, for example, a group capable of undergoing the addition polymerization. Examples of the reactive group include an ethylenic unsaturated group, a polycondensable group (for example, a hydroxy group or a carboxy group), and a polyadditionally reactive group (for example, an epoxy group or a (blocked) isocyanate group).

The weight-average molecular weight (Mw) of the alkali-soluble resin is preferably 1,000 or more, more preferably 10,000 to 100,000, and particularly preferably 20,000 to 50,000.

The thermoplastic resin layer may contain one kind alone or two or more kinds of alkali-soluble resins.

From the viewpoints of developability and adhesiveness to a layer adjacent to the thermoplastic resin layer, the content proportion of the alkali-soluble resin is preferably 10% by mass to 99% by mass, more preferably 20% by mass to 90% by mass, still more preferably 40% by mass to 80% by mass, and particularly preferably 50% by mass to 70% by mass, with respect to the total mass of the thermoplastic resin layer.

The thermoplastic resin layer preferably contains a dye (hereinafter, may be referred to as a “dye B”) that has a maximum absorption wavelength of 450 nm or more in a range of 400 nm to 780 nm of the wavelength range at the time of color development, where the maximum absorption wavelength is changed by an acid, a base, or a radical. The preferred aspect of the dye B is the same as the preferred aspect of the dye N described above, except for the points described later.

From the viewpoints of visibility of the exposed portion, the visibility of the non-exposed portion, and the resolution, the dye B is preferably a dye of which the maximum absorption wavelength is changed by an acid or a radical and more preferably a dye of which the maximum absorption wavelength is changed by an acid.

From the viewpoints of visibility of the exposed portion, the visibility of the non-exposed portion, and the resolution, the thermoplastic resin layer preferably contains, as the dye B, a dye of which the maximum absorption wavelength is changed by an acid, and a compound C which will be described later.

The thermoplastic resin layer may contain one kind alone or two or more kinds of dyes B.

From the viewpoints of the visibility of the exposed portion and the visibility of the non-exposed portion, the content proportion of the dye B is preferably 0.2% by mass or more, preferably 0.2% by mass to 6% by mass, still more preferably 0.2% by mass to 5% by mass, and particularly preferably 0.25% by mass to 3.0% by mass, with respect to the total mass of the thermoplastic resin layer.

Here, the content proportion of the dye B means the content proportion of the dye in a case where the whole dye B contained in the thermoplastic resin layer is in a colored state. Hereinafter, a method of quantifying the content proportion of the dye B will be described by taking a dye that develops color by a radical as an example. Two solutions obtained by respectively dissolving a dye (0.001 g) and a dye (0.01 g) in methyl ethyl ketone (100 mL) are prepared. IRGACURE OXE01 (manufactured by BASF SE) is added to each of the obtained solutions as a photoradical polymerization initiator and then irradiated with light of 365 nm to generate radicals, whereby all the dyes are brought into a colored state. Next, in the atmospheric air, the absorbance of each solution having a liquid temperature of 25° C. is measured using a spectrophotometer (UV3100, manufactured by Shimadzu Corporation), and a calibration curve is created. Next, the absorbance of the solution in which the whole dye has been caused to develop a color is measured by the same method as the above except that the thermoplastic resin layer (0.1 g) is dissolved in methyl ethyl ketone instead of the dye. From the obtained absorbance of the solution containing the thermoplastic resin layer, the amount of the dye contained in the thermoplastic resin layer is calculated based on the calibration curve.

The thermoplastic resin layer may contain a compound that generates an acid, a base, or a radical by light (hereinafter, may be referred to as a “compound C”). The compound C is preferably a compound that receives an actinic ray (for example, an ultraviolet ray or visible light) to generate an acid, a base, or a radical. Examples of the compound C include known compounds such as a photoacid generator, a photobase generator, and a photoradical polymerization initiator (a photoradical generator). The compound C is preferably a photoacid generator.

From the viewpoint of resolution, the thermoplastic resin layer preferably contains a photoacid generator. Examples of the photoacid generator include a photocationic polymerization initiator that may be contained in the above-described photosensitive resin layer, and the same applies to the preferred aspect thereof except for the points described below.

From the viewpoints of sensitivity and resolution, the photoacid generator preferably contains at least one selected from the group consisting of an onium salt compound and an oxime sulfonate compound, and from the viewpoints of sensitivity, resolution, and adhesiveness, it more preferably contains an oxime sulfonate compound.

Further, the photoacid generator is preferably a photoacid generator having the following structure.

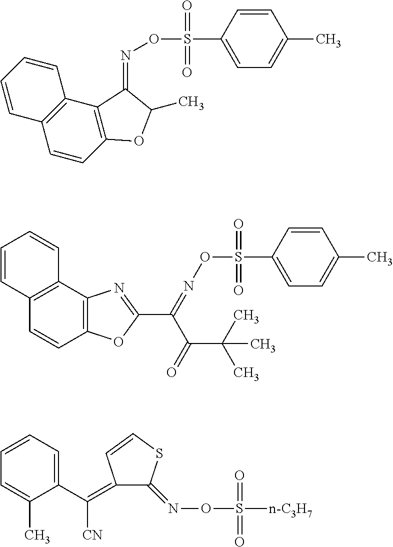

The thermoplastic resin layer may contain a photobase generator. Examples of the photobase generator include 2-nitrobenzylcyclohexylcarbamate, triphenyl methanol, O-carbamoylhydroxylamide, O-carbamoyloxime, [[(2,6-dinitrobenzyl)oxy]carbonyl]cyclohexylamine, bis[[(2-nitrobenzyl)oxy]carbonyl]hexane-1,6-diamine, 4-(methylthiobenzoyl)-1-methyl-1-morpholinoethane, (4-morpholinobenzoyl)-1-benzyl-1-dimethylaminopropane, N-(2-nitrobenzyloxycarbonyl)pyrrolidine, hexaammine cobalt (III) tris(triphenylmethylborate), 2-benzyl-2-dimethylamino-1-(4-morpholinophenyl)butanone, 2,6-dimethyl-3,5-diacetyl-4-(2-nitrophenyl)-1,4-dihydropyridine, and 2,6-dimethyl-3,5-diacetyl-4-(2,4-dinitrophenyl)-1,4-dihydropyridine.

The thermoplastic resin layer may contain a photoradical polymerization initiator. Examples of the photoradical polymerization initiator include a photoradical polymerization initiator that may be contained in the above-described photosensitive resin layer, and the same applies to the preferred aspect thereof.

The thermoplastic resin layer may contain one kind alone or two or more kinds of compounds C.

From the viewpoints of visibility of the exposed portion, the visibility of the non-exposed portion, and the resolution, the content proportion of the compound C is preferably 0.1% by mass to 10% by mass and more preferably 0.5% by mass to 5% by mass, with respect to the total mass of the thermoplastic resin layer.

The thermoplastic resin layer preferably contains a plasticizer from the viewpoints of resolution, adhesiveness to a layer adjacent to the thermoplastic resin layer, and developability.

The molecular weight of the plasticizer (in a case of a molecular weight of an oligomer or a polymer, it refers to the weight-average molecular weight (Mw), the same applies in this paragraph hereinafter) is preferably smaller than the molecular weight of the alkali-soluble resin. The molecular weight of the plasticizer is preferably 200 to 2,000.

The plasticizer is not limited as long as it is a compound that is compatible with the alkali-soluble resin and exhibits plasticity. From the viewpoint of imparting plasticity, the plasticizer is preferably a compound having an alkyleneoxy group in the molecule and more preferably a polyalkylene glycol compound. The alkyleneoxy group contained in the plasticizer preferably has a polyethyleneoxy structure or a polypropyleneoxy structure.

The plasticizer preferably contains a (meth)acrylate compound from the viewpoints of resolution and storage stability. From the viewpoint of compatibility, resolution, and adhesiveness to a layer adjacent to the thermoplastic resin layer, it is more preferable that the alkali-soluble resin is an acrylic resin and the plasticizer contains a (meth)acrylate compound.

Examples of the (meth)acrylate compound that is used as a plasticizer include the (meth)acrylate compound described in the ethylenically unsaturated compound. In the photosensitive transfer material, in a case where the thermoplastic resin layer and the photosensitive resin layer are arranged in direct contact with each other, the thermoplastic resin layer and the photosensitive resin layer each preferably contain the same (meth)acrylate compound. This is due to the reason that in a case where the thermoplastic resin layer and the photosensitive resin layer each contain the same (meth)acrylate compound, the diffusion of components between the layers is suppressed and the storage stability is improved.

In a case where the thermoplastic resin layer contains a (meth)acrylate compound as a plasticizer, it is preferable that the (meth)acrylate compound does not polymerize even in the exposed portion after exposure from the viewpoint of adhesiveness to a layer adjacent to the thermoplastic resin layer.

In a certain embodiment, the (meth)acrylate compound that is used as a plasticizer is preferably a (meth)acrylate compound having two or more a (meth)acryloyl groups in one molecule from the viewpoints of resolution, adhesiveness to a layer adjacent to the thermoplastic resin layer, and developability.

In a certain embodiment, the (meth)acrylate compound that is used as a plasticizer is preferably a (meth)acrylate compound having an acid group or a urethane (meth)acrylate compound.

The thermoplastic resin layer may contain one kind alone or two or more kinds of plasticizers.

From the viewpoints of resolution, adhesiveness to a layer adjacent to the thermoplastic resin layer, and developability, the content proportion of the plasticizer is preferably 1% by mass to 70% by mass, more preferably 10% by mass to 60% by mass, and particularly preferably 20% by mass to 50% by mass, with respect to the total mass of the thermoplastic resin layer.

The thermoplastic resin layer preferably contains a surfactant from the viewpoint of thickness uniformity. Examples of the surfactant include a surfactant that may be contained in the above-described photosensitive resin layer, and the same applies to the preferred aspect thereof.

The thermoplastic resin layer may contain one kind alone or two or more kinds of surfactants.

The content proportion of the surfactant is preferably 0.001% by mass to 10% by mass and more preferably 0.01% by mass to 3% by mass with respect to the total mass of the thermoplastic resin layer.

The thermoplastic resin layer may contain a sensitizing agent. Examples of the sensitizing agent include the sensitizing agent that may be contained in the negative type photosensitive resin layer described above.

The thermoplastic resin layer may contain one kind alone or two or more kinds of sensitizing agents.

From the viewpoints of the improvement of sensitivity to the light source, the visibility of the exposed portion, and the visibility of the non-exposed portion, the content proportion of the sensitizing agent is preferably 0.01% by mass to 5% by mass and more preferably 0.05% by mass to 1% by mass with respect to the total mass of the thermoplastic resin layer.

The thermoplastic resin layer may contain known additives in addition to the above components, as necessary.

Further, the thermoplastic resin layer is described in paragraph 0189 to paragraph 0193 of JP2014-85643A. The content of the above publication is incorporated in the present specification by reference.

The thickness of the thermoplastic resin layer is not limited. The average thickness of the thermoplastic resin layer is preferably 1 μm or more and more preferably 2 μm or more from the viewpoint of adhesiveness to a layer adjacent to the thermoplastic resin layer. The upper limit of the average thickness of the thermoplastic resin layer is not limited. From the viewpoints of developability and resolution, the average thickness of the thermoplastic resin layer is preferably 20 μm or less, more preferably 10 μm or less, and particularly preferably 5 μm or less.

The method of forming the thermoplastic resin layer is not limited as long as it is a method capable of forming a layer containing the above components. Examples of the method of forming the thermoplastic resin layer include a method in which the thermoplastic resin composition is applied onto the surface of the temporary support and the coating film of the thermoplastic resin composition is dried.

Examples of the thermoplastic resin composition include a composition containing the above-described components. The thermoplastic resin composition preferably contains a solvent in order to adjust the viscosity of the thermoplastic resin composition and facilitate the formation of the thermoplastic resin layer.

The solvent contained in the thermoplastic resin composition is not limited as long as it is a solvent capable of dissolving or dispersing the components contained in the thermoplastic resin layer. Examples of the solvent include a solvent that may be contained in the above-described photosensitive resin composition, and the same applies to the preferred aspect thereof.

The thermoplastic resin composition may contain one kind alone or two or more kinds of solvents.

The content proportion of the solvent in the thermoplastic resin composition is preferably 50 parts by mass to 1,900 parts by mass and more preferably 100 parts by mass to 900 parts by mass with respect to 100 parts by mass of the total solid content in the thermoplastic resin composition.

The preparation of the thermoplastic resin composition and the formation of the thermoplastic resin layer may be carried out according to the above-described method of preparing the photosensitive resin composition and the method of forming the negative type photosensitive resin layer. For example, the thermoplastic resin layer can be formed by preparing in advance each solution obtained by dissolving each of the components contained in the thermoplastic resin layer in a solvent, subsequently mixing the obtained solutions in a predetermined ratio to prepare the thermoplastic resin composition, applying the obtained thermoplastic resin composition onto the surface of the temporary support, and drying the coating film of the thermoplastic resin composition. Further, the thermoplastic resin layer may be formed on the surface of the photosensitive resin layer after forming the photosensitive resin layer on the protective film.

Protective Film

The photosensitive transfer material preferably has a protective film.

It is noted that the protective film is not included in the transfer layer.

It is preferable that the photosensitive resin layer and the protective film are in direct contact with each other.

Examples of the material that constitutes the protective film include a resin film and paper, where a resin film is preferable from the viewpoints of hardness and flexibility.

Examples of the resin film include a polyethylene film, a polypropylene film, a polyethylene terephthalate film, a cellulose triacetate film, a polystyrene film, and a polycarbonate film. Among them, a polyethylene film, a polypropylene film, or a polyethylene terephthalate film is preferable.

The thickness (the layer thickness) of the protective film is not particularly limited; however, it is preferably 5 μm to 100 μm and more preferably 10 μm to 50 μm.

From the viewpoints of the transportability, the defect suppressibility of the resin pattern, and the resolution, the arithmetic average roughness Ra of the surface of the protective film opposite to the photosensitive resin layer side is preferably equal to or smaller than the arithmetic average roughness Ra of the surface of the protective film on the photosensitive resin layer side, and more preferably smaller than the arithmetic average roughness Ra of the surface of the protective film on the photosensitive resin layer side.

From the viewpoints of transportability and backward winding property, the arithmetic average roughness Ra of the surface of the protective film opposite to the photosensitive resin layer side is preferably 300 nm or less, more preferably 100 nm or less, still more preferably 70 nm or less, and particularly preferably 50 nm or less.

Further, from the viewpoint of excellent resolution, the arithmetic average roughness Ra of the surface of the protective film on the photosensitive resin layer side is preferably 300 nm or less, more preferably 100 nm or less, still more preferably 70 nm or less, and particularly preferably 50 nm or less. This is conceived to be because in a case where the Ra value on the surface of the protective film is in the above range, the uniformity of the layer thickness of the photosensitive resin layer and the resin pattern to be formed are improved.

The lower limit of the Ra value on the surface of the protective film is not particularly limited; however, it is preferably 1 nm or more, more preferably 10 nm or more, and particularly preferably 20 nm or more on both surfaces.

Further, the peeling force of the protective film is preferably smaller than the peeling force of the temporary support.

The photosensitive transfer material may include a layer other than the above-described layers (hereinafter, also referred to as “other layer”). Examples of the other layers include a contrast enhancement layer.

The contrast enhancement layer is described in paragraph 0134 of WO2018/179640A. Further, the other layer is described in paragraphs 0194 to 0196 of JP2014-85643A. The contents of these publications are incorporated in the present specification by reference.

The total thickness of the photosensitive transfer material is preferably 5 μm to 55 μm, more preferably 10 μm to 50 μm, and particularly preferably 20 μm to 40 μm. The total thickness of the photosensitive transfer material is measured by a method according to the above-described method of measuring the thickness of each layer.

The total thickness of each layer of the photosensitive transfer material excluding the temporary support and the protective film is preferably 20 μm or less, more preferably 10 μm or less, still more preferably 8 μm or less, particularly preferably 2 μm or more and 8 μm or less, from the viewpoint of further exhibiting the effects in the present disclosure.

In addition, in the photosensitive transfer material, the total thickness of the photosensitive resin layer, the water-soluble resin layer, and the thermoplastic resin layer is preferably 20 μm or less, more preferably 10 μm or less, still more preferably 8 μm or less, particularly preferably 2 μm or more and 8 μm or less, from the viewpoint of further exhibiting the effects in the present disclosure.

Manufacturing Method for Photosensitive Transfer Material

The manufacturing method for the photosensitive transfer material that is used in the present disclosure is not particularly limited, and a known manufacturing method, for example, a known method of forming each layer can be used.

Hereinafter, the manufacturing method for the photosensitive transfer material that is used in the present disclosure will be described with reference to FIG. 1. However, the photosensitive transfer material that is used in the present disclosure is not limited to the one having the configuration illustrated in FIG. 1.

FIG. 1 is a schematic cross-sectional view illustrating one example of a layer structure in one embodiment of the photosensitive transfer material that is used in the present disclosure. A photosensitive transfer material 20 illustrated in FIG. 1 has a configuration in which a temporary support 11, a thermoplastic resin layer 13, a water-soluble resin layer 15, a photosensitive resin layer 17, and a protective film 19 are laminated in this order. Further, a transfer layer 12 in FIG. 1 is the thermoplastic resin layer 13, the water-soluble resin layer 15, and the photosensitive resin layer 17.

Examples of the manufacturing method for the photosensitive transfer material 20 include a method including a step of applying the thermoplastic resin composition onto the surface of the temporary support 11 and then drying the coating film of the thermoplastic resin composition to form the thermoplastic resin layer 12, a step of applying the water-soluble resin layer composition onto the surface of the thermoplastic resin layer 13 and then drying the coating film of the water-soluble resin layer composition to form the water-soluble resin layer 15, and a step of applying a photosensitive resin composition containing an ethylenically unsaturated compound onto the surface of the water-soluble resin layer 15 and then drying the coating film of the photosensitive resin composition to form the photosensitive resin layer 16.

In the above manufacturing method, it is preferable to use a thermoplastic resin composition containing at least one selected from the group consisting of an alkylene glycol ether solvent and an alkylene glycol ether acetate solvent, a water-soluble resin layer composition containing at least one selected from the group consisting of water and a water-miscible organic solvent, and a photosensitive resin composition containing at least one selected from the group consisting of a binder polymer, an ethylenically unsaturated compound, an alkylene glycol ether solvent, and an alkylene glycol ether acetate solvent. This makes it possible to suppress the mixing of the component contained in the thermoplastic resin layer 13 and the component contained in the water-soluble resin layer 15 during the application of the water-soluble resin layer composition onto the surface of the thermoplastic resin layer 13 and/or during the storage period of the laminate having the coating film of the water-soluble resin layer composition, and also makes it possible to suppress the mixing of the component contained in the water-soluble resin layer 15 and the component contained in the photosensitive resin layer 16 during the application of the photosensitive resin composition onto the surface of the water-soluble resin layer 15 and/or during the storage period of the laminate having the coating film of the photosensitive resin composition.

The protective film 19 is subjected to pressure bonding to the photosensitive resin layer 17 of the laminate manufactured by the above manufacturing method, whereby the photosensitive transfer material 20 is manufactured.

The manufacturing method for the photosensitive transfer material that is used in the present disclosure preferably includes a step of providing the protective film 19 to be in contact with the second surface of the photosensitive resin layer 17, thereby manufacturing the photosensitive transfer material 20 including the temporary support 11, the thermoplastic resin layer 13, the water-soluble resin layer 15, the photosensitive resin layer 17, and the protective film 19.

After the photosensitive transfer material 20 is manufactured by the above-described manufacturing method, the photosensitive transfer material 20 may be wound backward to produce and store the photosensitive transfer material having a roll form. The photosensitive transfer material having a roll form can be provided as it is in the step of bonding with a substrate by the roll-to-roll method described later.

Pigment

The photosensitive resin layer may be a colored resin layer containing a pigment.

In recent years, a liquid crystal display window included in an electronic device may be attached with a cover glass having a black frame-shaped light shielding layer formed on the peripheral portion of the back surface of a transparent glass substrate or the like in order to protect the liquid crystal display window. A colored resin layer can be used to form such a light shielding layer.

The pigment may be appropriately selected depending on the desired color tone, and it can be selected from a black pigment, a white pigment, and chromatic pigments other than black and white. Among them, in a case of forming a black pattern, a black pigment is suitably selected as the pigment.

As the black pigment, a known black pigment (an organic pigment, an inorganic pigment, or the like) can be appropriately selected as long as the effects in the present disclosure are not impaired. Among them, from the viewpoint of optical density, suitable examples of the black pigment include carbon black, titanium oxide, titanium carbide, iron oxide, titanium oxide, and graphite, where carbon black is particularly preferable. From the viewpoint of surface resistance, the carbon black is preferably a carbon black in which at least a part of the surface is coated with a resin.

From the viewpoint of dispersion stability, the particle diameter of the black pigment is preferably 0.001 μm to 0.1 μm and more preferably 0.01 μm to 0.08 μm in terms of number average particle diameter.

Here, the particle diameter refers to a diameter of a circle in a case where the area of the pigment particles is determined from the photographic image of the pigment particles captured with an electronic microscope and a circle having the same area as the area of the pigment particles is assumed, and the number average particle diameter is an average value obtained by determining the above particle diameter for any 100 particles and averaging the determined diameters of the 100 particles.

As the pigment other than the black pigment, the white pigments described in paragraphs 0015 and 0114 of JP2005-007765A can be used as the white pigment. Specifically, among the white pigments, the inorganic pigment is preferably titanium oxide, zinc oxide, lithopone, light calcium carbonate, white carbon, aluminum oxide, aluminum hydroxide, or barium sulfate, more preferably titanium oxide or zinc oxide, and still more preferably titanium oxide. The inorganic pigment is preferably a rutile-type or anatase-type titanium oxide, and particularly preferably a rutile-type titanium oxide.

Further, the surface of titanium oxide may be subjected to a silica treatment, an alumina treatment, a titania treatment, a zirconia treatment, or an organic substance treatment, or may be subjected to two or more treatments. As a result, the catalytic activity of titanium oxide is suppressed, and thus heat resistance, fading, and the like are improved.

From the viewpoint of reducing the thickness of the photosensitive resin layer after heating, the surface treatment of the surface of titanium oxide is preferably at least one of an alumina treatment or a zirconia treatment, and particularly preferably both alumina treatment and zirconia treatment.

Further, in a case where the photosensitive resin layer is a colored resin layer, the photosensitive resin layer preferably further contains a chromatic pigment other than the black pigment and the white pigment from the viewpoint of transferability. In a case where a chromatic pigment is contained, the particle diameter of the chromatic pigment is preferably 0.1 μm or less and more preferably 0.08 μm or less in terms of more excellent dispersibility.

Examples of the chromatic pigment include Victoria pure blue BO (Color Index (hereinafter C.I.) 42595), Auramine (C.I. 41000), Fat black HB (C.I. 26150), Monolite yellow GT (C.I. Pigment yellow 12), Permanent yellow GR (C.I. Pigment yellow 17), Permanent yellow HR (C.I. Pigment yellow 83), Permanent carmine FBB (C.I. Pigment red 146), Hoster balm red ESB (C.I. Pigment violet 19), Permanent ruby FBH (C.I. Pigment red 11), Pastel pink B supra (C.I. Pigment red 81), Monastral first blue (C.I. Pigment blue 15), Monolite first black B (C.I. Pigment black 1), and Carbon, as well as C.I. Pigment red 97, C.I. Pigment red 122, C.I. Pigment red 149, C.I. Pigment red 168, C.I. Pigment red 177, C.I. Pigment red 180, C.I. Pigment red 192, C.I. Pigment red 215, C.I. Pigment Green 7, C.I. Pigment blue 15:1, C.I. Pigment blue 15:4, C.I. Pigment blue 22, C.I. Pigment blue 60, C.I. Pigment blue 64, and C.I. Pigment violet 23. Among them, C.I. Pigment red 177 is preferable.

In a case where the photosensitive resin layer contains a pigment, the content of the pigment is preferably more than 3% by mass and 40% by mass or less, more preferably more than 3% by mass and 35% by mass or less, still more preferably more than 5% by mass and 35% by mass or less, and particularly preferably 10% by mass or more and 35% by mass or less, with respect to the total mass of the photosensitive resin layer.

In a case where the photosensitive resin layer contains a pigment (a white pigment and a chromatic pigment) other than the black pigment, the content of the pigment other than the black pigment is preferably 30% by mass or less, preferably 1% by mass to 20% by mass, and still more preferably 3% by mass to 15% by mass, with respect to the black pigment.

In a case where the photosensitive resin layer contains a black pigment and the photosensitive resin layer is formed from a photosensitive resin composition, the black pigment (preferably carbon black) is preferably introduced into the photosensitive resin composition in a form of a pigment dispersion liquid.

The dispersion liquid may be a dispersion liquid prepared by adding a mixture obtained by mixing in advance a black pigment and a pigment dispersing agent to an organic solvent (or a vehicle) and dispersing it with a disperser. The pigment dispersing agent may be selected depending on the pigment and the solvent, and for example, a commercially available dispersing agent can be used. It is noted that the vehicle refers to a medium portion which disperses a pigment in a case where the pigment is made to be a pigment dispersion liquid, where the vehicle is liquid and contains a binder component that holds the black pigment in a dispersed state and a solvent component (an organic solvent) that dissolves and dilutes the binder component.

The disperser is not particularly limited, and examples thereof include known dispersers such as a kneader, a roll mill, an attritor, a super mill, a dissolver, a homogenization mixer, and a sand mill. Further, fine pulverization may be carried out by mechanical grinding using frictional force. Regarding the disperser and fine pulverization, the description in “Encyclopedia of Pigments” (Kunizo Asakura, First Edition, Asakura Publishing Co., Ltd., 2000, 438, 310) can be referred to.

Manufacturing Method for Electronic Device

The manufacturing method for an electronic device according to the present disclosure is not particularly limited as long as it is a manufacturing method for an electronic device, including a substrate having a conductive pattern, the substrate being obtained by the manufacturing method for a substrate having a conductive pattern according to the present disclosure.

The specific aspect of each step in the manufacturing method for an electronic device and the embodiment for the order in which each step is carried out are as described in the above-described “manufacturing method for a conductive pattern”, and the same applies to the preferred aspect thereof.

Regarding the manufacturing method for an electronic device, a known manufacturing method for an electronic device may be referred to, except that the wire for an electronic device is formed by the above-described method.

Further, the manufacturing method for an electronic device may include any step (another step) other than those described above.

The electronic device is not particularly limited; however, suitable examples thereof include a semiconductor package, a printed circuit board, a device for various wire forming applications for a sensor board, a touch panel, an electromagnetic wave shielding material, a conductive film such as a film heater, a liquid crystal sealing material, and a construct in the field of micromachines or microelectronics.

The resin pattern is preferably used as a permanent film in the electronic device, for example, an interlayer insulating film, a wire protective film, or a wire protective film having an index matching layer.

Among them, particularly suitable examples of the electronic device include a touch panel.

Further, suitable examples of the electronic device include a flexible display device, particularly a flexible touch panel.

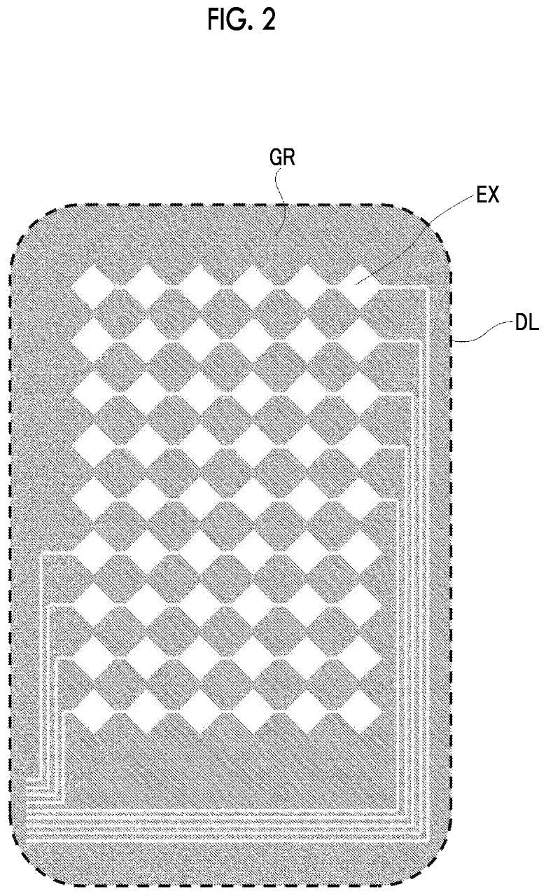

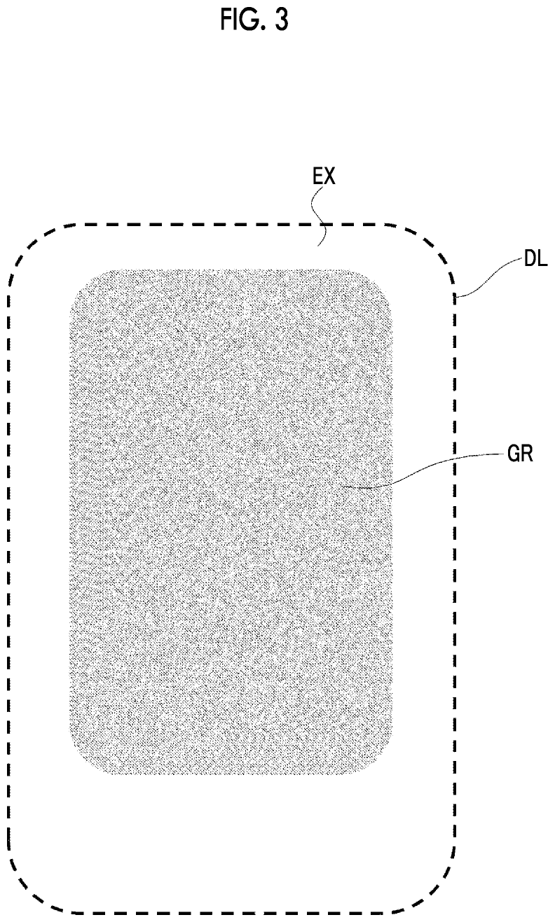

FIG. 2 and FIG. 3 are views each illustrating one example of a mask pattern that is used for manufacturing a touch panel.

In a pattern A illustrated in FIG. 2 and a pattern B illustrated in FIG. 3, GR is a non-image area (a light shielding unit), EX is an image area (an exposed portion), and DL is an alignment matching frame that is illustrated virtually. In the manufacturing method for a touch panel, a touch panel having circuit wiring having the pattern A corresponding to EX can be manufactured, for example, by exposing the photosensitive resin layer through a mask having the pattern A illustrated in FIG. 2. Specifically, it can be produced by the method illustrated in FIG. 1 of WO2016/190405A. In one example of the manufactured touch panel, the central portion (the pattern portion where the squares are connected) of the exposed portion EX is a portion where the transparent electrode (the electrode for a touch panel) is formed, and the peripheral portion (the thin line portion) of the exposed portion EX is a portion where a wire of the lead-out part is formed.

According to the manufacturing method for an electronic device, an electronic device having at least a wire for an electronic device is manufactured, and preferably, for example, a touch panel having at least a wire for a touch panel is manufactured.

The touch panel preferably has a transparent substrate, electrodes, and an insulating layer or protective layer.

Examples of the detection method for the touch panel include known methods such as a resistive membrane method, a capacitance method, an ultrasonic method, an electromagnetic induction method, and an optical method. Among the above, a capacitance method is preferable.

Examples of the touch panel type include a so-called in-cell type (for example, those shown in FIG. 5, FIG. 6, FIG. 7, and FIG. 8 of JP2012-517051B), a so-called on-cell type (for example, one described in FIG. 19 of JP2013-168125A and those described in FIG. 1 and FIG. 5 of JP2012-89102A), an one glass solution (OGS) type, a touch-on-lens (TOL) type (for example, one described in FIG. 2 of JP2013-54727A), various out-cell types (so-called GG, G1·G2, GFF, GF2, GF1, G1F, and the like), and other configurations (for example, those described in FIG. 6 of JP2013-164871A).

Examples of the touch panel include those described in paragraph 0229 of JP2017-120435A.

Substrate Having Conductive Pattern

The substrate having a conductive pattern according to the present disclosure includes a substrate as well as a first compartment in which a conductive pattern d containing a metal nanobody and a resin 1 is formed and a second compartment in which the conductive pattern d is not formed, on at least one surface of the substrate, in which in a case where the second compartment is observed in a thickness direction of the substrate with a scanning electron microscope, an area where voids are observed is 10% or less with respect to a total area of the second compartment.

In the second compartment, the metal nanobody is removed by, for example, an etching process, and the second compartment is in a state of substantially being free of the metal nanobody. The state of substantially being free of the metal nanobody is a state where the metal nanobody in the second compartment is removed and the inside of the compartment becomes an insulator. The presence of the first compartment and the second compartment makes it possible to constitute a conductive pattern circuit caused by the metal nanobody.

Further, the second compartment is preferably in a state where the resin in which the metal nanobody has been dispersed remains without being removed. That is, it is preferable that the resin is present in the second compartment. In this case, a film of the resin that has not been removed by etching is present, and the portion that is not the conductive pattern is the second compartment.

The second compartment may contain a substance other than the resin 1 as long as the insulating properties are not impaired. Examples of the substance other than the resin 1 include another resin, a polymerizable compound, an antioxidant, an ultraviolet absorbing agent, a polymerization initiator, and a rust inhibitor.

The substrate having a conductive pattern according to the present disclosure is preferably manufactured by the manufacturing method for a substrate having a conductive pattern according to the present disclosure.

The substrate, the metal nanobody, the resin 1, and the conductive pattern d are respectively the same as the substrate, the metal nanobody, the resin 1, and the conductive pattern d described in the manufacturing method for a substrate having a conductive pattern according to the present disclosure, and the same applies to the preferred aspects thereof respectively.

Further, the other matters are also the same as that in the preferred aspect described in the manufacturing method for a substrate having a conductive pattern according to the present disclosure.

The first compartment of the substrate having a conductive pattern according to the present disclosure is a portion where the conductive pattern d formed on the substrate is present, and the second compartment is a portion where the conductive pattern d is not present.

In the substrate having the conductive pattern according to the present disclosure, in a case where the second compartment is observed in a thickness direction of the substrate with a scanning electron microscope, the area where voids are observed is 10% or less with respect to a total area of the second compartment, and from the viewpoint of the dimensional stability of the conductive pattern after applying an electric current, it is more preferably 8% or less, still more preferably 5% or less, and particularly preferably 0% or more and 3% or less.

In a case where the layer thickness of the first compartment from the surface of the substrate is denoted by H1 and the layer thickness of the second compartment from the surface of the substrate is denoted by H2, the substrate having a conductive pattern according to the present disclosure preferably satisfies 0.90≤H1/H2≤1.11 and more preferably satisfies 0.95≤H1/H2≤1.05 from the viewpoint of the dimensional stability of the conductive pattern after applying an electric current.

Further, the number of recessed parts having a depth of 10 nm or more and present in the second compartment is preferably 10 pieces/100 μm² or less, more preferably 8 pieces/100 μm² or less, still more preferably 5 pieces/100 μm² or less, and particularly preferably 3 pieces/100 μm² or less, from the viewpoint of the dimensional stability of the conductive pattern after applying an electric current. The lower limit thereof is 0 pieces/100 μm².

Protective Film for Metal Nanobody

The protective film for a metal nanobody according to the present disclosure has a resin layer containing a resin having a glass transition temperature of 150° C. or lower.

The preferred aspect of the resin layer in the protective film for a metal nanobody according to the present disclosure is the same as the preferred aspect of the resin layer b described above.

Further, the preferred aspect of the resin having a glass transition temperature of 150° C. or lower in the protective film for a metal nanobody according to the present disclosure is the same as the preferred aspect of the resin 2 described above except for the glass transition temperature.

The glass transition temperature of the resin having a glass transition temperature of 150° C. or lower is preferably 30° C. to 140° C., more preferably 40° C. to 130° C., and particularly preferably 40° C. to 120° C., from the viewpoint of the dimensional stability of the conductive pattern after applying an electric current.

The average thickness of the resin layer in the protective film for a metal nanobody according to the present disclosure is not particularly limited; however, it is preferably 1 nm to 200 nm, more preferably 5 nm to 100 nm, and particularly preferably 15 nm to 50 nm, from the viewpoint of the dimensional stability of the conductive pattern after applying an electric current.

Further, suitable examples of the protective film for a metal nanobody according to the present disclosure include not only an aspect in which the metal nanobody is directly brought into contact, thereby being protected, but also an aspect in which a layer containing the metal nanobody is brought into contact, thereby being protected.

### EXAMPLES

Hereinafter, the embodiments of the present invention will be described more specifically with reference to Examples. The materials, using amounts, proportions, treatment content, treatment procedure, and the like disclosed in the following Examples can be modified as appropriate as long as the gist of the embodiments of the present invention is maintained. Therefore, the scope of the embodiments of the present invention is not limited to the specific examples described below. Unless otherwise specified, “parts” and “%” are based on a mass.

### Examples 1 to 14 and Comparative Example 1

Manufacturing of Conductive Base Material

A film (ClearOhm, manufactured by Cambrios Technologies Corp.) in which a conductive layer (light transmittance with respect to light having a wavelength of 380 nm to 780 nm: 92%) in which metal nanowires were dispersed in a resin was laminated on a substrate consisting of a polyethylene terephthalate film was prepared.

A composition for forming a protective layer having the composition shown in Table 1 was applied onto this film so that the film thickness after drying was 40 nanometers. After drying in an oven at 100° C., the exposure was carried out at an exposure amount of 600 mJ/cm² using an exposure machine (M-1S, manufactured by Mikasa Co., Ltd.). Further, post-baking was carried out in a convection oven at 140° C. for 30 minutes to form a protective layer (a resin layer b).

It is noted that in Example 10, Example 13, and Example 14, the exposure was not carried out after the protective layer was formed since the polymerizable compound was not contained as the composition of the protective layer.

TABLE 1

| Composition | Example | Example | Example | Example | Example | Example | Example | Example | Example |
|---|---|---|---|---|---|---|---|---|---|
| protective | 1 | 2 | 3 | 4 | 5 | 6 | 7 | 8 | 9 |
| layer | Protective | Protective | Protective | Protective | Protective | Protective | Protective | Protective | Protective |
| for forming | layer 1 | layer 2 | layer 3 | layer 4 | layer 5 | layer 6 | layer 7 | layer 8 | layer 9 |
| A-1 | 3.22 | — | — | — | — | — | — | — | — |
| A-2 | — | 3.22 | — | — | — | — | — | — | — |
| A-3 | — | — | 0.966 | — | — | — | — | — | — |
| A-4 | — | — | — | 0.966 | — | — | — | — | — |
| A-5 | — | — | — | — | 0.966 | — | — | — | — |
| A-6 | — | — | — | — | — | 0.966 | — | — | — |
| A-7 | — | — | — | — | — | — | 0.966 | — | — |
| A-8 | — | — | — | — | — | — | — | 0.966 | — |
| A-9 | — | — | — | — | — | — | — | — | 0.966 |
| A-10 | — | — | — | — | — | — | — | — | — |
| A-11 | — | — | — | — | — | — | — | — | — |
| B-1 | 0.75 | 0.75 | 0.75 | 0.75 | 0.75 | 0.75 | 0.75 | 0.75 | 0.75 |
| C-1 | 0.03 | 0.03 | 0.03 | 0.03 | 0.03 | 0.03 | 0.03 | 0.03 | 0.03 |
| D-1 | — | — | — | — | — | — | — | — | — |
| F-1 | 60.0 | 60.0 | 61.2 | 61.2 | 61.2 | 61.2 | 61.2 | 61.2 | 61.2 |
| F-2 | 36.0 | 36.0 | 37.1 | 37.1 | 37.1 | 37.1 | 37.1 | 37.1 | 37.1 |
| | | | | | | | | | Comparative |
| | | | Composition | Example | Example | Example | Example | Example | Example |
| | | | protective | 10 | 11 | 12 | 13 | 14 | 1 |
| | | | layer | Protective | Protective | Protective | Protective | Protective | Protective layer |
| | | | for forming | layer 10 | layer 11 | layer 12 | layer 13 | layer 14 | A |
| | | | A-1 | — | — | — | 5.72 | — | — |
| | | | A-2 | — | 3.13 | — | — | — | — |
| | | | A-3 | — | — | 0.95 | — | — | — |
| | | | A-4 | — | — | — | — | 1.72 | — |
| | | | A-5 | — | — | — | — | — | — |
| | | | A-6 | — | — | — | — | — | — |
| | | | A-7 | — | — | — | — | — | — |
| | | | A-8 | — | — | — | — | — | — |
| | | | A-9 | — | — | — | — | — | — |
| | | | A-10 | 1.716 | — | — | — | — | — |
| | | | A-11 | — | — | — | — | — | 0.966 |
| | | | B-1 | — | 0.72 | 0.73 | — | — | 0.75 |
| | | | C-1 | — | 0.03 | 0.03 | — | — | 0.03 |
| | | | D-1 | — | 0.085 | 0.085 | — | — | — |
| | | | F-1 | 61.2 | 60.2 | 61.2 | 59.0 | 61.2 | 61.2 |
| | | | F-2 | 37.1 | 36.2 | 37.1 | 35.5 | 37.1 | 37.1 |

The unit of the numerical value of each component shown in Table 1 is part by mass.

The details of the abbreviations shown in Table 1 are as follows.

A-1: A copolymer of benzyl methacrylate/methacrylic acid=70/30 (% by weight) (molecular weight: 30,000, propylene glycol monomethyl ether acetate 30% by weight solution), glass transition temperature: 75° C.

A-2: A copolymer of benzyl methacrylate/methacrylic acid/2-hydroxyethyl acrylate=40/30/30 (% by weight) (molecular weight: 30,000, propylene glycol monomethyl ether acetate 30% by weight solution), glass transition temperature: 41° C.

A-3: ELITEL UE-9990 (polyester resin, manufactured by UNITIKA Ltd.), glass transition temperature: 101° C.

A-4: ELITEL UE-3690 (polyester resin, manufactured by UNITIKA Ltd.), glass transition temperature: 90° C.

A-5: ELITEL UE-3980 (polyester resin, manufactured by UNITIKA Ltd.), glass transition temperature: 63° C.

A-6: DIANAL MB-2952 (acrylic resin, manufactured by Mitsubishi Chemical Corporation), glass transition temperature: 85° C.

A-7: DIANAL BR-113 (acrylic resin, manufactured by Mitsubishi Chemical Corporation), glass transition temperature: 75° C.

A-8: S-LEC KS-10 (polyvinyl acetal resin, manufactured by Sekisui Chemical Company, Limited), glass transition temperature: 105° C.

A-9: S-LEC BL-10 (polyvinyl butyral resin, manufactured by Sekisui Chemical Company, Limited), glass transition temperature” 67° C.

A-10: PHENOLITE WR-104 (phenol novolak resin, manufactured by DIC Corporation), glass transition temperature: 79° C.

A-11: CAP-504-0.2 (cellulose acetate propionate, manufactured by TOMOE Engineering Co., Ltd.), glass transition temperature: 159° C.

B-1: LIGHT ACRYLATE DPE-6A (dipentaerythritol hexaacrylate, manufactured by Kyoeisha Chemical Co., Ltd.)

C-1: Irgacure OXE02 (photopolymerization initiator, manufactured by BASF Japan Ltd.)

D-1: BT-120 (1,2,3-benzotriazole, manufactured by JOHOKU CHEMICAL Co., Ltd.)

F-1: Propylene glycol monomethyl ether acetate

F-2: Methyl ethyl ketone

Production of Photosensitive Transfer Material

On a temporary support (a polyethylene terephthalate film, thickness: 16 μm, haze: 0.12%), the surface of the temporary support was coated with the following thermoplastic resin composition using a slit-shaped nozzle so that the coating width was 1.0 m and the dry layer thickness was 3.0 μm. The formed coating film of the thermoplastic resin composition was dried at 80° C. for 40 seconds to form a thermoplastic resin layer.

The surface of the formed thermoplastic resin layer was coated with the following water-soluble resin layer composition using a slit-shaped nozzle so that the coating width was 1.0 m and the layer thickness after drying was 1.2 μm. The coating film of the water-soluble resin layer composition was dried at 80° C. for 40 seconds to form a water-soluble resin layer.

The surface of the formed water-soluble resin layer was coated with the following photosensitive resin composition using a slit-shaped nozzle so that the coating width was 1.0 m and the layer thickness after drying was 5.0 μm and dried at 100° C. for 2 minutes to form a photosensitive resin layer. A protective film (a polypropylene film, thickness: 12 μm) was bonded on the photosensitive resin layer to produce a photosensitive transfer material.

Composition of Thermoplastic Resin Composition
A propylene glycol monomethyl ether acetate solution of a copolymer of benzyl methacrylate, methacrylic acid, and acrylic acid (concentration of solid contents: 30.0%, Mw: 30,000, acid value: 153 mgKOH/g): 42.85 parts
NK Ester A-DCP (manufactured by Shin-Nakamura Chemical Co., Ltd.): 4.33 parts
8UX-015A (manufactured by Taisei Fine Chemical Co., Ltd.): 2.31 parts
ARONIX TO-2349 (manufactured by Toagosei Co., Ltd.): 0.77 parts
MEGAFACE F-552 (manufactured by DIC Corporation): 0.03 parts
Methyl ethyl ketone (manufactured by SANKYO CHEMICAL Co., Ltd.): 39.80 parts
Propylene glycol monomethyl ether acetate (manufactured by Showa Denko K.K.): 9.51 parts
A compound having the structure shown below (a photoacid generator, a compound synthesized according to the method described in paragraph 0227 of JP2013-47765A): 0.32 parts.

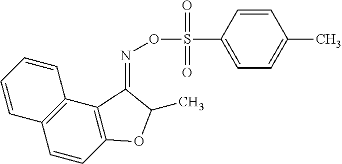 [SMILES: Cc1ccc(S(=O)(=O)O/N=C2/c3c(ccc4ccccc34)OC2C)cc1]

A compound having the structure shown below (a dye that develops color by an acid): 0.08 parts

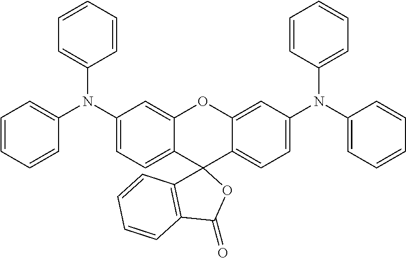 [SMILES: O=C1OC2(c3ccc(N(c4ccccc4)c4ccccc4)cc3Oc3cc(N(c4ccccc4)c4ccccc4)ccc32)c2ccccc21]

Composition of Water-Soluble Resin Layer Composition

Kuraray Poval PVA-205 (polyvinyl alcohol, manufactured by Kuraray Co., Ltd.): 3.22 parts by mass

Polyvinylpyrrolidone K-30 (manufactured by Nippon Shokubai Co., Ltd.): 1.49 parts by mass

MEGAFACE F-444 (a fluorine-based surfactant, manufactured by DIC Corporation): 0.0015 parts by mass

Ion exchange water: 38.12 parts by mass

Methanol (manufactured by Mitsubishi Gas Chemical Company, Inc.): 57.17 parts by mass

Composition of Photosensitive Resin Composition

A propylene glycol monomethyl ether acetate solution of a copolymer of styrene/methacrylic acid/methyl methacrylate (concentration of solid contents: 30.0% by mass, ratio of respective monomers: 52% by mass/29% by mass/19% by mass, Mw: 70,000): 23.4 parts by mass

BPE-500 (an ethoxylated bisphenol A dimethacrylate, manufactured by Shin-Nakamura Chemical Co., Ltd.): 4.1 parts by mass

NK Ester HD-N (1,6-hexanediol dimethacrylate, manufactured by Shin-Nakamura Chemical Co., Ltd.): 2.2 parts by mass

B-CIM (2,2′-bis(2-chlorophenyl)-4,4′,5,5′-tetraphenyl-1,2′-biimidazole, a photopolymerization initiator, manufactured by KUROGANE KASEI Co., Ltd.): 0.25 parts by mass

SB-PI 701 (4,4′-bis(diethylamino)benzophenone, a sensitizing agent, obtained from Sanyo Trading Co., Ltd.): 0.04 parts by mass

TDP-G (phenothiazine, manufactured by Kawaguchi Chemical Industry Company, Limited): 0.0175 parts by mass

1-phenyl-3-pyrazolidone (manufactured by FUJIFILM Wako Pure Chemical Corporation): 0.0011 parts by mass

Leuco crystal violet (manufactured by Tokyo Chemical Industry Co., Ltd.): 0.051 part by mass

N-phenylcarbamoylmethyl-N-carboxymethylaniline (manufactured by FUJIFILM Wako Pure Chemical Corporation): 0.02 parts by mass

1,2,4-triazole (manufactured by Tokyo Chemical Industry Co., Ltd.): 0.75 parts by mass

MEGAFACE F-552 (a fluorine-based surfactant, manufactured by DIC Corporation): 0.05 parts by mass

Methyl ethyl ketone (manufactured by SANKYO CHEMICAL Co., Ltd.): 40.4 parts by mass

Propylene glycol monomethyl ether acetate (manufactured by Showa Denko K.K.): 26.7 parts by mass

Methanol (manufactured by Mitsubishi Gas Chemical Company, Inc.): 2 parts by mass

Formation of Wiring Pattern

After the protective film was peeled off from the photosensitive transfer material produced as described above, the photosensitive transfer material from which the protective film had been peeled off was bonded to the conductive base material produced as described above, under the laminating conditions of a roll temperature of 100° C., a linear pressure of 0.8 MPa, and a linear speed of 3.0 m/min.

A glass mask having a wiring pattern of a line width of 100 μm was closely attached to the bonded photosensitive transfer material, on the temporary support without peeling off the temporary support, and the exposure was carried out using an exposure machine (M-1S, manufactured by Mikasa Co., Ltd.).

After being allowed to stand for 1 hour after exposure, the temporary support was peeled off, and the uncured portion was removed by spraying a developer (28° C., a 1.0% potassium carbonate aqueous solution) with a shower to produce a resin pattern.

An iron nitrate aqueous solution (30° C., 40.0% by mass) was sprayed with a shower on the obtained conductive base material having the resin pattern, thereby removing the metal nanowires contained in the conductive layer in the portion where the resin pattern was not present. Further, an aqueous solution of tetramethyl ammonium hydroxide (TMAH) at 40° C. (2.38% by mass) was sprayed with a shower to remove the residual resin pattern, thereby producing a conductive pattern.

The base material on which the conductive pattern was formed was subjected to the heating treatment in an infrared oven at 140° C. for 30 minutes to produce a substrate (a wiring board) having the conductive pattern (the wiring pattern).

Examination of Void

In the obtained wiring pattern, the voids present in a 100 μm square in the portion where the wiring pattern was not present (the portion where the metal nanowires were removed) were observed with a scanning electron microscope in a direction (a thickness direction) perpendicular to the surface direction of the substrate. The void portion of the observed image was binarized and the ratio of the number of pixels to the visual field of observation was defined as the void ratio. Observations were carried out at three different locations on the sample, and the average value was taken as the void ratio of the sample.

The evaluation was made from A (good) to D (bad) based on the void ratio as follows. A wiring board having an evaluation C or higher is preferable.

A: void ratio ≤3%

B: 3%<void ratio ≤5%

C: 5%<void ratio ≤10%

D: 10%<void ratio

Examination of Pattern Abnormality after Applying Electric Current (Dimensional Stability of Conductive Pattern after Applying Electric Current)

Electrodes were connected to the terminal parts of the obtained wiring pattern, installed in a constant temperature tank at 85% RH and 85° C., and a voltage of 10 V of direct current (DC) was applied for 600 minutes. After the application, the wiring pattern was observed, and the rate of change in the pattern width compared with that before the application was evaluated as A (good) to D (bad) as follows. A wiring board having an evaluation C or higher is preferable.

A: Rate of change in pattern width <15%

B: 15%<rate of change in pattern width <20%

C: 20%≤rate of change in pattern width <25%

D: 25%≤rate of change in pattern width

Examination of Void Depth

Regarding a portion of the obtained wiring pattern, where the wiring pattern was present (the portion where the metal nanowires had not been removed), the inside of a compartment of 100 μm² was subjected to the measurement by using an atomic force microscope (AFM) in a direction perpendicular to the surface direction of the substrate (a thickness direction), and Rv was determined from the obtained roughness curve. Observations were carried out at three different locations on the sample, and the average value was taken as Rv1 of the sample.

On the other hand, a portion where the wiring pattern was not present (a portion from which the metal nanowires had been removed) was similarly subjected to the roughness measurement with AFM, and a portion where Rv was larger than Rv1 by 10 nm or more was regarded as the void. The number of voids in a compartment of 100 μm² was counted, and the average value at three different locations on the sample was taken as the number of voids (voids/100 μm²) of the sample.

### Example 15

A substrate having a conductive pattern was produced and evaluated in the same manner as in Example 1 except that the protective layer was not provided.

### Example 16

A substrate having a conductive pattern was produced and evaluated in the same manner as in Example 2 except that heating was not carried out after the wiring pattern was formed.

### Example 17

Onto a polyimide film (TORMED (registered trade name) Type S, manufactured by I.S.T Corporation), an ink (DNS-0163I, manufactured by Daicel Corporation) containing silver nanoparticles and a resin was applied by an inkjet method so that the dry film thickness was 0.05 μm, and sintering was carried out at 120° C. for 30 minutes to form a conductive substrate.

The composition 1 for forming a protective layer, which was used in Example 1, was applied onto this conductive substrate so that the film thickness after drying was 40 nanometers. After drying in an oven at 100° C., the exposure was carried out at an exposure amount of 600 mJ/cm² using an exposure machine (M-1S, manufactured by Mikasa Co., Ltd.). Further, post-baking was carried out in a convection oven at 140° C. for 30 minutes to form a protective layer (a resin layer b).

After the protective film was peeled off from the same photosensitive transfer material as in Example 1, the photosensitive transfer material from which the protective film had been peeled off was bonded to the conductive base material produced as described above, under the laminating conditions of a roll temperature of 100° C., a linear pressure of 0.8 MPa, and a linear speed of 3.0 m/min.

A glass mask having a wiring pattern of a line width of 100 μm was closely attached to the bonded photosensitive transfer material, on the temporary support without peeling off the temporary support, and the exposure was carried out using an exposure machine (M-1S, manufactured by Mikasa Co., Ltd.).

After being allowed to stand for 1 hour after exposure, the temporary support was peeled off, and the uncured portion was removed by spraying a developer (28° C., a 1.0% potassium carbonate aqueous solution) with a shower to produce a resin pattern.

An iron nitrate aqueous solution (30° C., 40.0% by mass) was sprayed with a shower on the obtained conductive base material having the resin pattern, thereby removing the silver nanoparticles contained in the conductive layer in the portion where the resin pattern was not present. Further, an aqueous solution of tetramethyl ammonium hydroxide (TMAH) at 40° C. (2.38% by mass) was sprayed with a shower to remove the residual resin pattern, thereby producing a conductive pattern. Finally, heating treatment was carried out in an infrared oven at 140° C. for 30 minutes to produce a substrate (a wiring board) having the conductive pattern (the wiring pattern).

The evaluation was carried out in the same manner as in Example 1.

### Example 18

Onto a cycloolefin polymer film (Zeonor Film (registered trade name) ZB, manufactured by Zeon Corporation), an ink containing copper nanoparticles and a resin (IJ-02A, manufactured by ISHIHARA CHEMICAL Co., Ltd.) was applied so that the dry film thickness was 0.05 μm, and sintering was carried out for 30 minutes using a xenon flash lamp to form a conductive substrate.

The composition 1 for forming a protective layer, which was used in Example 1, was applied onto this conductive substrate so that the film thickness after drying was 40 nanometers. After drying in an oven at 100° C., the exposure was carried out at an exposure amount of 600 mJ/cm² using an exposure machine (M-1S, manufactured by Mikasa Co., Ltd.). Further, post-baking was carried out in a convection oven at 140° C. for 30 minutes to form a protective layer (a resin layer b).

After the protective film was peeled off from the same photosensitive transfer material as in Example 1, the photosensitive transfer material from which the protective film had been peeled off was bonded to the conductive base material produced as described above, under the laminating conditions of a roll temperature of 100° C., a linear pressure of 0.8 MPa, and a linear speed of 3.0 m/min.

A glass mask having a wiring pattern of a line width of 100 μm was closely attached to the bonded photosensitive transfer material, on the temporary support without peeling off the temporary support, and the exposure was carried out using an exposure machine (M-1S, manufactured by Mikasa Co., Ltd.).

After being allowed to stand for 1 hour after exposure, the temporary support was peeled off, and the uncured portion was removed by spraying a developer (28° C., a 1.0% potassium carbonate aqueous solution) with a shower to produce a resin pattern.

Cupric chloride dihydrate (5 g), 28% aqueous ammonia (12 g), and ammonium chloride (8 g) were dissolved in water to prepare 1 L of a copper etchant. The copper etchant was sprayed with a shower on the obtained conductive base material having the resin pattern, thereby removing the copper nanoparticles contained in the conductive layer in the portion where the resin pattern was not present. Further, an aqueous solution of tetramethyl ammonium hydroxide (TMAH) at 40° C. (2.38% by mass) was sprayed with a shower to remove the residual resin pattern, thereby producing a conductive pattern. Finally, heating treatment was carried out in an infrared oven at 140° C. for 30 minutes to produce a substrate (a wiring board) having the conductive pattern (the wiring pattern).

The evaluation was carried out in the same manner as in Example 1.

Measurement of Film Thickness

In Examples 1 to 18, the average film thickness of the conductive pattern and the average film thickness of the resin portion from which the metal nanobody had been removed were measured. In any of Examples, the relationship of the average film thicknesses was within a range of 0.90≤the average film thickness of the conductive pattern/the average film thickness of the resin portion from which the metal nanobody had been removed ≤1.11.

### Comparative Example 2

Manufacturing of Conductive Base Material

A film (ClearOhm, manufactured by Cambrios Technologies Corp.) in which a conductive layer in which metal nanowires were dispersed in a resin was laminated on a substrate consisting of a polyethylene terephthalate film was prepared.

Formation of Wiring Pattern

After the protective film was peeled off from the photosensitive transfer material described above, the photosensitive transfer material from which the protective film had been peeled off was bonded to the conductive base material described above, under the laminating conditions of a roll temperature of 100° C., a linear pressure of 0.8 MPa, and a linear speed of 3.0 m/min.

A glass mask having a wiring pattern of a line width of 100 μm was closely attached to the bonded photosensitive transfer material, on the temporary support without peeling off the temporary support, and the exposure was carried out using an exposure machine (M-1S, manufactured by Mikasa Co., Ltd.).

After being allowed to stand for 1 hour after exposure, the temporary support was peeled off, and the uncured portion was removed by spraying a developer (28° C., a 1.0% potassium carbonate aqueous solution) with a shower to produce a resin pattern.

An iron nitrate aqueous solution (30° C., 40.0% by mass) was sprayed with a shower on the obtained sample, thereby removing the metal nanowires contained in the conductive layer in the portion where the resin pattern was not present. Further, a TMAH aqueous solution at 40° C. (2.38% by mass) was sprayed with a shower to remove the residual resin pattern, thereby producing a substrate having a conductive pattern.

The evaluation was carried out in the same manner as in Example 1.

The evaluation results are summarized in Table 2.

TABLE 2

| | Example | Example | Example | Example | Example | Example | Example | Example | Example | Example |
|---|---|---|---|---|---|---|---|---|---|---|
| | 1 | 2 | 3 | 4 | 5 | 6 | 7 | 8 | 9 | 10 |
| Protective | Protective | Protective | Protective | Protective | Protective | Protective | Protective | Protective | Protective | Protective |
| layer | layer 1 | layer 2 | layer 3 | layer 4 | layer 5 | layer 6 | layer 7 | layer 8 | layer 9 | layer 10 |
| Heating after | Yes | Yes | Yes | Yes | Yes | Yes | Yes | Yes | Yes | Yes |
| etching | | | | | | | | | | |
| Void | A | A | B | A | A | A | A | B | A | A |
| Dimensional | B | B | A | A | A | A | A | A | A | A |
| stability of | | | | | | | | | | |
| conductive | | | | | | | | | | |
| pattern after | | | | | | | | | | |
| applying | | | | | | | | | | |
| electric | | | | | | | | | | |
| current | | | | | | | | | | |
| Number of | 0 | 1 | 4 | 2 | 2 | 2 | 1 | 4 | 3 | 1 |
| voids | | | | | | | | | | |
| (voids/100 | | | | | | | | | | |
| μm²) | | | | | | | | | | |
| | | | | | | | | | Comparative | |
| | Example | Example | Example | Example | Example | Example | Example | Example | Example | Comparative |
| | 11 | 12 | 13 | 14 | 15 | 16 | 17 | 18 | 1 | Example |
| Protective | Protective | Protective | Protective | Protective | Absent | Protective | Protective | Protective | Protective | 2 |
| layer | layer 11 | layer 12 | layer 13 | layer 14 | | layer 2 | layer 1 | layer 1 | layer A | Absent |
| Heating after | Yes | Yes | Yes | Yes | Yes | No | Yes | Yes | Yes | No |
| etching | | | | | | | | | | |
| Void | A | A | A | A | C | B | B | B | D | D |
| Dimensional | A | A | A | A | C | C | B | C | C | D |
| stability of | | | | | | | | | | |
| conductive | | | | | | | | | | |
| pattern after | | | | | | | | | | |
| applying | | | | | | | | | | |
| electric | | | | | | | | | | |
| current | | | | | | | | | | |
| Number of | 1 | 2 | 2 | 1 | 7 | 6 | 6 | 8 | 13 | 27 |
| voids | | | | | | | | | | |
| (voids/100 | | | | | | | | | | |
| μm²) | | | | | | | | | | |

As shown in Table 2, in Examples 1 to 14, it was possible to obtain good wiring patterns having few voids and no pattern abnormality after applying an electric current.

Although the protective layer was not provided in Example 15, the number of voids was slightly small as compared with Comparative Example 2 in which heating was not carried out, and the pattern abnormality after applying an electric current was improved. It is presumed that the resin contained in the conductive layer has been softened during heating after etching and has filled the voids.

In Example 16, although the number of voids increased and the pattern after applying an electric current deteriorated slightly as compared with Example 2, it was capable of being used as a wire forming material without heating. Although the cause of this is not clear, it is presumed to be because A-2, which is the resin used in the protective layer 2, has high hydrophilicity and a low glass transition temperature Tg, and thus A-2 swells in the etching step and/or the peeling step of the wire formation, whereby the voids are closed to some extent. That is, it is presumed that the step 5a has been carried out in the etching step and/or the peeling step of the wire formation.

In Example 17 and Example 18, the method for producing a conductive substrate was changed to prepare a substrate having a conductive pattern. The substrates having a conductive pattern in Example 17 and Example 18 were capable of being sufficiently used as a wire forming material although the number of voids increased and the pattern after applying an electric current deteriorated slightly as compared with Example 1.

### EXPLANATION OF REFERENCES

11: temporary support
12: transfer layer
13: thermoplastic resin layer
15: water-soluble resin layer
17: photosensitive resin layer
19: protective film
20: photosensitive transfer material
GR: light shielding unit (non-image area)
EX: exposed portion (image area)
DL: alignment matching frame

What is claimed is:

1. A manufacturing method for a substrate having a conductive pattern, comprising:
a step 1a of forming a conductive layer a containing a metal nanobody and a resin 1 on a substrate;
a step 1b of forming a resin layer b containing a resin 2 on the conductive layer a;
a step 2a of forming a photosensitive resin layer c on the resin layer b;
a step 3 of obtaining a resin pattern c′ of the photosensitive resin layer by exposure and development treatment on the photosensitive resin layer c;
a step 4 of removing the metal nanobody in the conductive layer a by etching to form a conductive pattern d; and
a step 5a of softening or swelling at least one of the resin 1 or the resin 2.

2. A manufacturing method for a substrate having a conductive pattern, comprising:
a step 1a of forming a conductive layer a containing a metal nanobody and a resin 1 on a substrate;
a step 2b of forming a photosensitive resin layer c on the conductive layer a;
a step 3 of obtaining a resin pattern c′ of the photosensitive resin layer by exposure and development treatment on the photosensitive resin layer c;
a step 4 of removing the metal nanobody in the conductive layer a by etching to form a conductive pattern d; and
a step 5b of softening or swelling the resin 1.

3. The manufacturing method for a substrate having a conductive pattern according to claim 1,
wherein at least one surface of the obtained substrate having a conductive pattern has a first compartment in which the conductive pattern d is formed and a second compartment in which the conductive pattern d is not formed, and
in a case where the second compartment is observed in a thickness direction of the substrate with a scanning electron microscope, an area where voids are observed is 10% or less with respect to a total area of the second compartment.

4. The manufacturing method for a substrate having a conductive pattern according to claim 3,
wherein in the case where the second compartment is observed in a thickness direction of the substrate with the scanning electron microscope, the area where voids are observed is 8% or less with respect to the total area of the second compartment.

5. The manufacturing method for a substrate having a conductive pattern according to claim 4,
wherein in a case where the second compartment is observed in the thickness direction of the substrate with the scanning electron microscope, the area where voids are observed is 5% or less with respect to the total area of the second compartment.

6. The manufacturing method for a substrate having a conductive pattern according to claim 1,
wherein the conductive layer a has a light transmittance of 70% or more with respect to light having a wavelength of 380 nm to 780 nm.

7. The manufacturing method for a substrate having a conductive pattern according to claim 1,
wherein the metal nanobody is a metal nanowire.

8. The manufacturing method for a substrate having a conductive pattern according to claim 1,
wherein the metal nanobody is a nanoparticle having an aspect ratio of 1:1 to 1:10 and a sphere equivalent diameter of 1 nm to 200 nm.

9. The manufacturing method for a substrate having a conductive pattern according to claim 1,
wherein the metal nanobody is a silver nanobody or a silver compound nanobody.

10. The manufacturing method for a substrate having a conductive pattern according to claim 1,
wherein a conductive pattern d′ is further formed on a surface of the substrate opposite to a surface on which the conductive layer a is provided.

11. The manufacturing method for a substrate having a conductive pattern according to claim 1,
wherein the resin layer b has a compound e that can be bonded or coordinated to a metal contained in the metal nanobody.

12. The manufacturing method for a substrate having a conductive pattern according to claim 11,
wherein the compound e is a compound having an unshared electron pair.

13. The manufacturing method for a substrate having a conductive pattern according to claim 12,
wherein the compound e is at least one compound selected from the group consisting of a nitrogen-containing compound having an unshared electron pair and a sulfur-containing compound having an unshared electron pair.

14. The manufacturing method for a substrate having a conductive pattern according to claim 1,
wherein the photosensitive resin layer c contains an alkali-soluble resin, a polymerizable compound, and a photopolymerization initiator.

15. The manufacturing method for a substrate having a conductive pattern according to claim 1,
wherein the step 5a is a step of softening at least one of the resin 1 or the resin 2 by a heating treatment and filling, by the etching, voids generated by removing the metal nanobody.

16. The manufacturing method for a substrate having a conductive pattern according to claim 15,
wherein the heating treatment in the step 5a is carried out at a heating temperature that satisfies Tgp <Th<Tgb,
where Th indicates a maximum temperature (° C.) during the heating treatment in the step 5a, Tgp indicates a lower glass transition temperature (° C.) between a glass transition temperature of the resin 1 and a glass transition temperature of the resin 2, and Tgb indicates a glass transition temperature (° C.) of the substrate.

17. The manufacturing method for a substrate having a conductive pattern according to claim 2,
wherein the step 5b is a step of softening the resin 1 by a heating treatment and filling, by the etching, voids generated by removing the metal nanobody.

18. The manufacturing method for a substrate having a conductive pattern according to claim 1,
wherein the step 5a is a step of swelling at least one of the resin 1 or the resin 2 and filling, by the etching, voids generated by removing the metal nanobody, during the step 4 or after the step 4.

19. The manufacturing method for a substrate having a conductive pattern according to claim 2,
wherein the step 5b is a step of swelling the resin 1 and filling, by the etching, voids generated by removing the metal nanobody, during the step 4 or after the step 4.

20. A manufacturing method for an electronic device, wherein the electronic device includes a substrate having a conductive pattern, the substrate being obtained by the manufacturing method for a substrate having a conductive pattern according to claim 1.
